(19) United States
(12) Patent Application Publication
(10) Pub. No.: US 2023/0045531 A1
(43) Pub. Date: Feb. 9, 2023

(54) NOVEL ORGANOMETALLIC COMPOUNDS AND ORGANIC LIGHT EMITTING DIODE INCLUDING SAME

(71) Applicant: SFC CO., LTD., Cheongju-si (KR)

(72) Inventors: Chun-Young Lee, Cheongju-si (KR); Hak-Kyu Kim, Cheongju-si (KR); Tae-Young Kim, Cheongju-si (KR)

(21) Appl. No.: 17/845,406

(22) Filed: Jun. 21, 2022

(30) Foreign Application Priority Data
Jun. 24, 2021 (KR) 10-2021-0082656
May 30, 2022 (KR) 10-2022-0066314

(51) Int. Cl. H01L 51/00; C07F 15/00; C09K 11/06

(52) U.S. Cl. CPC H01L 51/0087; C07F 15/0086; C09K 11/06; C09K 2211/185; C09K 2211/1044; C09K 2211/1037; C09K 2211/1033; H01L 51/5016

(57) ABSTRACT

Disclosed herein are a novel organometallic compound and an organic light-emitting diode including same. More specifically, an organometallic compound represented by [Chemical Formula 1] and an organic light-emitting diode including same are provided.

### CROSS-REFERENCE TO RELATED APPLICATIONS

This application claims the priority of the Korean Patent Applications NO 10-2021-0082656 filed on Jun. 24, 2021, and NO 10-2022-0066314 filed on May 30, 2022, in the Korean Intellectual Property Office, the disclosure of which is incorporated herein by reference.

### BACKGROUND OF THE INVENTION

### 1. Field of the Invention

The present disclosure relates to a novel organometallic compound available for organic light-emitting diodes and an organic light-emitting diode including same and, more specifically, to a novel organometallic compound that can be used as a phosphorescent dopant material in organic light-emitting diodes to allow for blue light emission of high purity, and an organic light-emitting diode including same.

### 2. Description of the Related Art

Organic light-emitting diodes (OLEDs), based on self-luminescence, are used to create digital displays with the advantage of having a wide viewing angle and being able to be made thinner and lighter than liquid crystal displays. In addition, an OLED display exhibits a very fast response time. Accordingly, OLEDs find applications in the full color display field or the illumination field.

In general, the term “organic light-emitting phenomenon” refers to a phenomenon in which electrical energy is converted to light energy by means of an organic material. An organic light-emitting diode using the organic light-emitting phenomenon has a structure usually including an anode, a cathode, and an organic material layer interposed therebetween. In this regard, the organic material layer may have, for the most part, a multilayer structure consisting of different materials, for example, a hole injection layer, a hole transport layer, a light-emitting layer, an electron transport layer, and an electron injection layer in order to enhance the efficiency and stability of the organic light-emitting diode. In the organic light-emitting diode having such a structure, application of a voltage between the two electrodes injects a hole from the anode and an electron from the cathode to the organic layer. In the luminescent zone, the hole and the electron recombine to produce an exciton. When the exciton returns to the ground state from the excited state, the molecule of the organic layer emits light. Such an organic light-emitting diode is known to have characteristics such as self-luminescence, high luminance, high efficiency, low driving voltage, a wide viewing angle, high contrast, and high-speed response.

Materials used as organic layers in OLEDs may be divided according to functions into luminescent materials and charge transport materials, for example, a hole injection material, a hole transport material, an electron transport material, and an electron injection material.

As for the luminescent materials, there are two main families according to molecular weight: those based on small molecules and those employing polymers. The light-emitting mechanism forms the basis for classification of the luminescent materials as fluorescent or phosphorescent materials, which use excitons in singlet and triplet states, respectively.

Recently, red and green phosphorescent materials are commercially used, and blue phosphorescent materials have not yet been applied due to problems with lifespan, color coordinates, and efficiency on which research is thus ongoing. Phosphorescent emission consists of the mechanism in which electrons undergo transition from ground states to excited states and then non-emissive transition through intersystem crossing to the triplet state from the singlet state, followed by the relaxation of the triplet exciton to the ground state with the concomitant emission of light. This phosphorescent emission is characterized by a longer lifetime (emission time) as the triplet excitons do not return directly to the ground state, but relax to the ground state only after intersystem crossing to another electron spin state. Whereas the duration of phosphorescent emission is merely in the order of several nanoseconds, phosphorescent materials may continue to emit an afterglow for a relatively longer time in the order of several microseconds.

When a single material is employed as the luminescent material, intermolecular actions cause the wavelength of maximum luminescence to shift toward a longer wavelength, resulting in reduced color purity and light emission efficiency due to the light attenuation. In this regard, a host-dopant system may be used as a luminescent material so as to increase the color purity and the light emission efficiency through energy transfer.

This is based on the principle whereby, when a dopant is smaller in energy band gap than a host accounting for the light-emitting layer, the addition of a small amount of the dopant to the host generates excitons from the light-emitting layer so that the excitons are transported to the dopant, emitting light at high efficiency. Here, light of desired wavelengths can be obtained depending on the kind of dopant because the wavelength of the host moves to the wavelength range of the dopant.

Recently, with many attempts to increase the luminous efficiency of phosphorescent organic light-emitting diodes (OLEDs), continuous research is being conducted to realize better physical properties. In particular, thorough research has been focused on an improvement in the layer structure of the device and new materials for the host and the dopant.

As a phosphorescent dopant compound in the light emitting layer, metal complex compounds have recently been studied. In this regard, reference may be made of U.S. Pat. No. 2005-0214576 A, which suggests as a phosphorescent dopant a metal complex (FIrpic) in a heteroleptic structure with 3-hydroxy-picolinato serving as an auxiliary ligand, and Korean Patent No. 2017-0085208 A that discloses an organic light-emitting diode including as a phosphorescent dopant a metal complex in a heteroleptic structure using a phenyl pyridine-based compound as a main ligand and 3-hydroxy-picolinato as a co-ligand.

Although various forms of luminescent materials have been prepared for use in organic light-emitting devices, there is still a continued need to develop novel organometallic compounds that are applicable for use in organic light-emitting diodes and exhibits excellent color purity, and organic light-emitting diodes including same.

### SUMMARY OF THE INVENTION

The present disclosure aims to provide an organometallic compound represented by the following Chemical Formula 1:

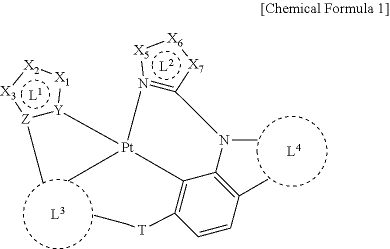

wherein,

L¹ is selected from a substituted or unsubstituted 5-membered heteroaromatic ring, a substituted or unsubstituted 5-membered heteroaliphatic ring, and a substituted or unsubstituted 5-membered N-heterocyclic carbene,

Y is C or N,

Z is C or N,

X₁ to X₃, which may be same or different, are each independently any one selected from CR₁R₂, CR₃, NR₄, N, O, S, and Se,

wherein when two or more of X1 to X3 are CR1R2, the plural CR1R2 radicals may be same or different, when two or more of X1 to X3 are CR3, the plural CR3 radicals may be same or different, and when two or more of X1 to X3 are NR4, the plural NR4 radicals may be same or different,

R₁ to R₄, which may be same or different, are each independently any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, a substituted or unsubstituted aliphatic hydrocarbon ring-fused heteroaryl of 5 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen, and

any adjacent two substituents of X₁ to X₃ may be optionally linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, or a substituted or unsubstituted heteroaliphatic ring of 3 to 30 carbon atoms,

L² is selected from a substituted or unsubstituted 5-membered heteroaromatic ring, and a substituted or unsubstituted 5-membered heteroaliphatic ring,

X₅ to X₇, which may be same or different, are each independently any one selected from CR₅R₆, CR₇, NR₈, N, O, and S,

wherein when two or more of X₅ to X₇ are CR₅R₆, the plural CR₅R₆ radicals may be same or different, when two or more of X₅ to X₇ are CR₇, the plural CR₇ radicals may be same or different, and when two or more of X₅ to X₇ are NR₈, the plural NR₈ radicals may be same or different,

R₅ to R₈, which may be same or different, are each independently as defined above for R₁ to R₄, respectively, and any adjacent two substituents of X₅ to X₇ may be optionally linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, or a substituted or unsubstituted heteroaliphatic ring of 3 to 30 carbon atoms,

L³ and L⁴, which may be same or different, are each independently selected from a substituted or unsubstituted aromatic hydrocarbon ring of 6 to 50 carbon atoms, a substituted or unsubstituted aliphatic hydrocarbon ring of 5 to 50 carbon atoms, a substituted or unsubstituted fused ring of 7 to 50 carbon atoms with an aromatic hydrocarbon ring and an aliphatic hydrocarbon ring fused to each other, a substituted or unsubstituted heteroaromatic ring of 2 to 50 carbon atoms, and a substituted or unsubstituted fused ring of 6 to 40 carbon atoms with an heteroaromatic ring and an aliphatic hydrocarbon ring fused to each other,

wherein L⁴ may be bonded to at least adjacent one of R₅ to R₈ in X₇ to form an additional condensed ring,

T is a linker selected from CR₉R₁₀, SiR₁₁R₁₂, NR₁₃, BR₁₄, PRᵢₛ, R₁₆P═O, GeR₁₇R₁₈, O, and S,

wherein R₉ to R₁₈, which may be same or different, are each independently as defined above for R₁ to R₄, respectively,

wherein the term “substituted” in the expression “substituted or unsubstituted” used for the compound of Chemical Formula 1 means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, cycloalkyl of 3 to 30 carbon atoms, an alkenyl of 2 to 24, an alkynyl of 2 to 24 carbon atoms, a heteroalkyl of 1 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an alkoxy of 1 to 24 carbon atoms, an amine of 1 to 24 carbon atoms, a silyl of 1 to 24 carbon atoms, a germyl of 1 to 24 carbon atoms, an aryloxy of 6 to 24 carbon atoms, and an arythionyl of 6 to 24 carbon atoms.

### BRIEF DESCRIPTION OF THE DRAWINGS

FIG. 1 is a photoluminescence spectrum of Compound 8 according to Example 1.

FIG. 2 is a photoluminescence spectrum of Compound 17 according to Example 2.

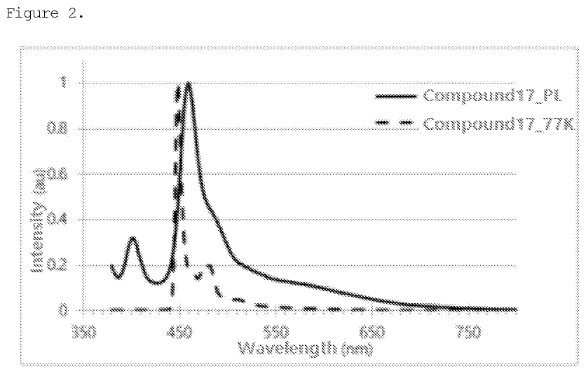

FIG. 3 is a photoluminescence spectrum of Compound 18 according to Example 3.

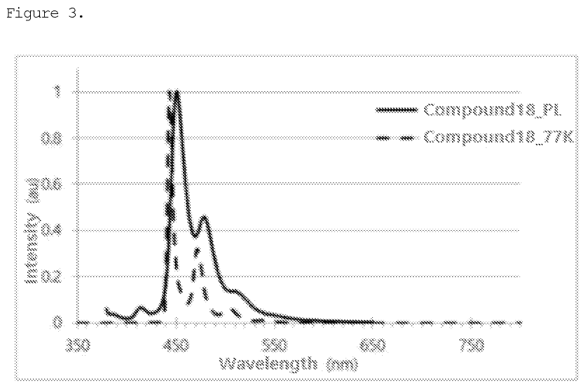

FIG. 4 is a photoluminescence spectrum of Compound 19 according to Example 4.

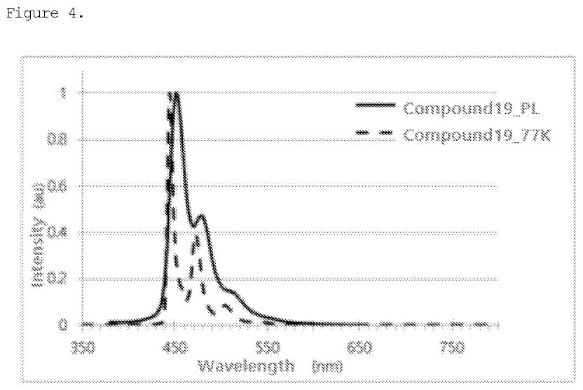

FIG. 5 is a photoluminescence spectrum of Compound 28 according to Example 5.

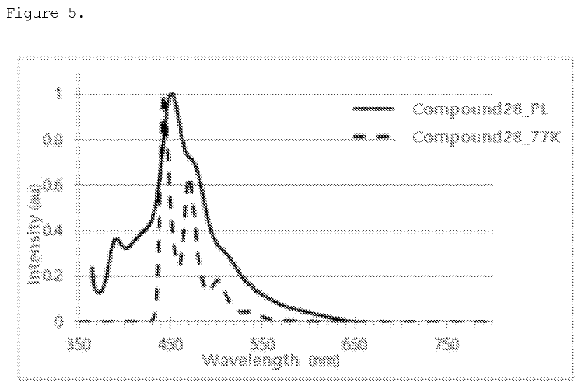

FIG. 6 is a photoluminescence spectrum of Compound 29 according to Example 6.

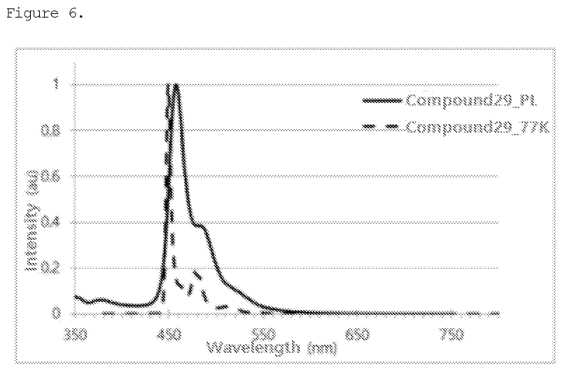

### DETAILED DESCRIPTION OF THE INVENTION

Below, a detailed description will be given of the present disclosure. In each drawing of the present disclosure, sizes or scales of components may be enlarged or reduced from their actual sizes or scales for better illustration, and known components may not be depicted therein to clearly show features of the present disclosure. Therefore, the present disclosure is not limited to the drawings. When describing the principle of the embodiments of the present disclosure in detail, details of well-known functions and features may be omitted to avoid unnecessarily obscuring the presented embodiments.

In the drawing, for convenience of description, sizes of components may be exaggerated for clarity. For example, since sizes and thicknesses of components in drawings are arbitrarily shown for convenience of description, the sizes and thicknesses are not limited thereto. Furthermore, throughout the description, the terms “on” and “over” are used to refer to the relative positioning, and mean not only that one component or layer is directly disposed on another component or layer but also that one component or layer is indirectly disposed on another component or layer with a further component or layer being interposed therebetween. Also, spatially relative terms, such as “below”, “beneath”, “lower”, and “between” may be used herein for ease of description to refer to the relative positioning.

Throughout the specification, when a portion may “include” a certain constituent element, unless explicitly described to the contrary, it may not be construed to exclude another constituent element but may be construed to further include other constituent elements. Further, throughout the specification, the word “on” means positioning on or below the object portion, but does not essentially mean positioning on the lower side of the object portion based on a gravity direction.

The present disclosure provides an organometallic compound represented by the following Chemical Formula 1:

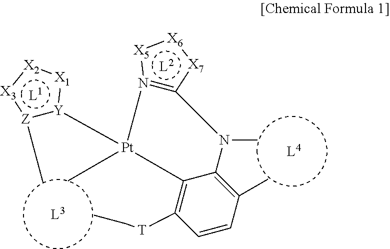

W wherein,

L¹ is selected from a substituted or unsubstituted 5-membered heteroaromatic ring, a substituted or unsubstituted 5-membered heteroaliphatic ring, and a substituted or unsubstituted 5-membered N-heterocyclic carbene,

Y is C or N,

Z is C or N,

X₁ to X₃, which may be same or different, are each independently any one selected from CR₁R₂, CR₃, NR₄, N, O, S, and Se,

wherein when two or more of X1 to X3 are CR1R2, the plural CR1R2 radicals may be same or different, when two or more of X1 to X3 are CR3, the plural CR3 radicals may be same or different, and when two or more of X1 to X3 are NR4, the plural NR4 radicals may be same or different,

R₁ to R₄, which may be same or different, are each independently any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, a substituted or unsubstituted aliphatic hydrocarbon ring-fused heteroaryl of 5 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen, and

any adjacent two substituents of X₁ to X₃ may be optionally linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, or a substituted or unsubstituted heteroaliphatic ring of 3 to 30 carbon atoms,

L² is selected from a substituted or unsubstituted 5-membered heteroaromatic ring, and a substituted or unsubstituted 5-membered heteroaliphatic ring,

X₅ to X₇, which may be same or different, are each independently any one selected from CR₅R₆, CR₇, NR₈, N, O, and S,

wherein when two or more of X₅ to X₇ are CR₅R₆, the plural CR₅R₆ radicals may be same or different, when two or more of X₅ to X₇ are CR₇, the plural CR₇ radicals may be same or different, and when two or more of X₅ to X₇ are NR₈, the plural NR₈ radicals may be same or different,

R₅ to R₈, which may be same or different, are each independently as defined above for R₁ to R₄, respectively, and

any adjacent two substituents of X₅ to X₇ may be optionally linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, or a substituted or unsubstituted heteroaliphatic ring of 3 to 30 carbon atoms,

L³ and L⁴, which may be same or different, are each independently selected from a substituted or unsubstituted aromatic hydrocarbon ring of 6 to 50 carbon atoms, a substituted or unsubstituted aliphatic hydrocarbon ring of 5 to 50 carbon atoms, a substituted or unsubstituted fused ring of 7 to 50 carbon atoms with an aromatic hydrocarbon ring and an aliphatic hydrocarbon ring fused to each other, a substituted or unsubstituted heteroaromatic ring of 2 to 50 carbon atoms, and a substituted or unsubstituted fused ring of 6 to 40 carbon atoms with an heteroaromatic ring and an aliphatic hydrocarbon ring fused to each other,

wherein L⁴ may be bonded to at least adjacent one of R₅ to R₈ in X₇ to form an additional condensed ring,

T is a linker selected from CR₉R₁₀, SiR₁₁R₁₂, NR₁₃, BR₁₄, PRᵢₛ, R₁₆P═O, GeR₁₇R₁₈, O, and S,

wherein R₉ to R₁₈, which may be same or different, are each independently as defined above for R₁ to R₄, respectively,

wherein the term “substituted” in the expression “substituted or unsubstituted” used for the compound of Chemical Formula 1 means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, cycloalkyl of 3 to 30 carbon atoms, an alkenyl of 2 to 24, an alkynyl of 2 to 24 carbon atoms, a heteroalkyl of 1 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an alkoxy of 1 to 24 carbon atoms, an amine of 1 to 24 carbon atoms, a silyl of 1 to 24 carbon atoms, a germyl of 1 to 24 carbon atoms, an aryloxy of 6 to 24 carbon atoms, and an arythionyl of 6 to 24 carbon atoms.

The expression indicating the number of carbon atoms, such as “a substituted or unsubstituted alkyl of 1 to 30 carbon atoms”, “a substituted or unsubstituted aryl of 5 to 50 carbon atoms”, etc. means the total number of carbon atoms of, for example, the alkyl or aryl radical or moiety alone, exclusive of the number of carbon atoms of substituents attached thereto. For instance, a phenyl group with a butyl at the para position falls within the scope of an aryl of 6 carbon atoms, even though it is substituted with a butyl radical of 4 carbon atoms.

As used herein, the term “aryl” means an organic radical derived from an aromatic hydrocarbon by removing one hydrogen that is bonded to the aromatic hydrocarbon. The aromatic system may include a fused ring that is formed by adjacent substituents on the aryl radical.

Concrete examples of the aryl include phenyl, o-biphenyl, m-biphenyl, p-biphenyl, o-terphenyl, m-terphenyl, p-terphenyl, naphthyl, anthryl, phenanthryl, pyrenyl, indenyl, fluorenyl, tetrahydronaphthyl, perylenyl, chrysenyl, naphthacenyl, and fluoranthenyl. At least one hydrogen atom of the aryl may be substituted by a deuterium atom, a halogen atom, a hydroxy, a nitro, a cyano, a silyl, an amino (—NH₂, —NH(R), —N(R′) (R″) wherein R′ and R″ are each independently an alkyl of 1 to 10 carbon atoms, in this case, called “alkylamino”), an amidino, a hydrazine, a hydrazone, a carboxyl, a sulfonic acid, a phosphoric acid, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 6 to 24 carbon atoms, a heteroaryl of 2 to 24 carbon atoms, or a heteroarylalkyl of 2 to 24 carbon atoms.

The substituent “heteroaryl” used in the compound of the present disclosure means a hetero aromatic radical of 2 to 24 carbon atoms, bearing one to three heteroatoms selected from among N, 0, P, Si, S, Ge, Se, and Te. In the aromatic radical, two or more rings may be fused. One or more hydrogen atoms on the heteroaryl may be substituted by the same substituents as on the aryl.

In addition, the term “heteroaromatic ring”, as used herein, refers to an aromatic hydrocarbon ring bearing at least one heteroatom as aromatic ring member. In the heteroaromatic ring, one to three carbon atoms of the aromatic hydrocarbon may be substituted by at least one selected particularly from N, O, P, Si, S, Ge, Se, and Te.

As used herein, the term “alkyl” refers to an alkane missing one hydrogen atom and includes linear or branched structures. Examples of the alkyl substituent useful in the present disclosure include methyl, ethyl, propyl, isopropyl, isobutyl, sec-butyl, tert-butyl, pentyl, iso-amyl, hexyl, and the like. At least one hydrogen atom of the alkyl may be substituted by the same substituent as in the aryl.

The term “cyclo” as used in substituents of the compounds of the present disclosure refers to a structure responsible for a mono- or polycyclic ring of saturated hydrocarbons. Concrete examples of cycloalkyl radicals include cyclopropyl, cyclobutyl, cyclopentyl, cyclohexyl, methylcyclopentyl, methylcyclohexyl, ethylcyclopentyl, ethylcyclohexyl, adamantyl, dicyclopentadienyl, decahydronaphthyl, norbornyl, bornyl, isobornyl, and so on. One or more hydrogen atoms on the cycloalkyl may be substituted by the same substituents as on the aryl.

The term “alkoxy” as used in the compounds of the present disclosure refers to an alkyl or cycloalkyl singularly bonded to oxygen. Concrete examples of the alkoxy include methoxy, ethoxy, propoxy, isobutoxy, sec-butoxy, pentoxy, iso-amyloxy, hexyloxy, cyclobutyloxy, cyclopentyloxy, adamantyloxy, dicyclopentyloxy, bornyloxy, isobornyloxy, and the like. One or more hydrogen atoms on the alkoxy may be substituted by the same substituents as on the aryl.

Concrete examples of the arylalkyl used in the compounds of the present disclosure include phenylmethyl (benzyl), phenylethyl, phenylpropyl, naphthylmethyl, naphthylethyl, and the like. One or more hydrogen atoms on the arylalkyl may be substituted by the same substituents as on the aryl.

Concrete examples of the silyl radicals used in the compounds of the present disclosure include trimethylsilyl, triethylsilyl, triphenylsilyl, trimethoxysilyl, dimethoxyphenylsilyl, diphenylmethylsilyl, diphenylvinlysilyl, methylcyclobutylsilyl, and dimethyl furylsilyl. One or more hydrogen atoms on the silyl may be substituted by the same substituents as on the aryl.

As used herein, the term “alkenyl” refers to an unsaturated hydrocarbon group that contains a carbon-carbon double bond between two carbon atoms and the term “alkynyl” refers to an unsaturated hydrocarbon group that contains a carbon-carbon triple bond between two carbon atoms.

As used herein, the term “alkylene” refers to an organic aliphatic radical regarded as derived from a linear or branched saturated hydrocarbon alkane by removal of two hydrogen atoms from different carbon atoms. Concrete examples of the alkylene include methylene, ethylene, propylene, isopropylene, isobutylene, sec-butylene, tert-butylene, pentylene, iso-amylene, hexylene, and so on. One or more hydrogen atoms on the alkylene may be substituted by the same substituents as on the aryl.

The term “amine” radical, as used herein, is intended to encompass —NH₂, an alkylamine, an arylamine, an alkylarylamine, an arylheteroarylamine, a heteroarylamine, and the like. An arylamine refers to an amine in which one or two of the hydrogen atoms in —NH₂ are substituted by aryls; an alkylamine to an amine in which one or two of the hydrogen atoms in —NH₂ are substituted by alkyls; an alkylarylamine to an amine in which two of the hydrogen atoms in —NH₂ are substituted by an alkyl and an aryl, respectively; an arylheteroarylamine to an amine in which one or two of the hydrogen atoms in —NH₂ are substituted by an aryl and a heteroaryl, respectively; a heteroarylamine to an amine in which both of the hydrogen atoms in —NH₂ are substituted by a heteroaryl. Examples of the arylamine include a substituted or unsubstituted monoarylamine and a substituted or unsubstituted diarylamine. Such nomenclatures of mono- and di-suffixes are true of the alkylamine and the heteroarylamine.

Here, the aryl in each of the arylamine, heteroarylamine, and arylheteroarylamine may be monocyclic aryl or polycyclic aryl, and the heteroaryl in each of the arylamine, the heteroarylamine, and the aylheteroarylamine may be monocyclic heteroaryl or polycyclic heteroaryl.

The term “silyl” radical, as used herein, is intended to encompass —SiH₃, an alkylsilyl, an arylsilyl, an alkyl arylsilyl, an arylheteroarylsilyl, and a heteroarylsilyl. An arylsilyl refers to a silyl in which at least one of the hydrogen atoms in —SiH₃ is substituted by an aryl. An alkylsilyl refers to a silyl in which at least one of the hydrogen atoms in —SiH₃ is substituted by an alkyl. An alkylarylsilyl refers to a silyl in which one or two of the hydrogen atoms in —SiH₃ are substituted by an alkyl while the remaining one or two hydrogen atoms are substituted by an aryl. An arylheteroarylsilyl refers to a silyl in which one or two of the hydrogen atoms in —SiH₃ are substituted by an aryl while the remaining one or two hydrogen atoms are substituted by a heteroaryl. A heteroarylsilyl refers to a silyl in which at least one of the hydrogen atoms in —SiH₃ is substituted by a heteroaryl. Examples of the arylsilyl include a substituted or unsubstituted monarylsilyl, a substituted or unsubstituted diarylsilyl, and a substituted or unsubstituted triarylsilyl. Such nomenclatures of mono- di-, a and tri-suffixes are true of the alkylsilyl and the heteroarylsilyl.

Here, the aryl in each of the arylsilyl, heteroarylsilyl, and arylheteroarylsilyl may be monocyclic aryl or polycyclic aryl, and the heteroaryl in each of the arylsilyl, the heteroarylsilyl, and the arylheteroarylsilyl may be monocyclic heteroaryl or polycyclic heteroaryl.

Concrete examples of the silyl include trimethylsilyl, triethylsilyl, triphenylsilyl, trimethoxysilyl, dimethoxyphenylsilyl, diphenylmethylsilyl, diphenylvinlysilyl, methylcyclobutylsilyl, and dimethyl furylsilyl. One or more hydrogen atoms on the silyl may be substituted by the same substituents as on the aryl.

In addition, the term “germyl” radical, as used herein, is intended to encompass —GeH₃, an alkylgermyl, an arylgermyl, a heteroarylgermyl, an alkylarylgermyl, an alkylheteroarylgermyl, and an arylheteroarylgermyl, and these germyl radicals are as defined above for the silyl, with a germanium atom (Ge) used, instead of the silicon (Si) atom, for each of the substituents.

Concrete examples of the germyl include trimethylgermyl, triethylgermyl, triphenylgermyl, trimethoxygermyl, dimethoxyphenylgermyl, diphenylmethylgermyl, diphenylvinylgermyl, methylcyclobutylgermyl, and dimethylfurylgermyl. One or more hydrogen atoms on the germyl may be substituted by the same substituents as on the aryl.

As used herein, the term “5-membered heteroaromatic ring” refers to a 5-membered aromatic hydrocarbon ring bearing at least one heteroatom selected from N, O, P, and S as a ring member. Particularly, the heteroaromatic ring bears one to three heteroatoms as ring members.

As used herein, the term “5-membered heteroaliphatic ring” refers to a 5-membered aliphatic hydrocarbon ring bearing at least one heteroatom selected from N, O, P, and S as a ring member. Particularly, the heteroaliphatic ring bears one to three heteroatoms as ring members.

As used herein, the term “5-membered N-heterocyclic carbene” refers to a 5-membered cyclic compound that bears a neutral carbon atom with two unshared valence electrons, and at least one and particularly one to three heteroatoms selected from N, O, and S as ring members, with preference for at least one nitrogen (N) atom, and particularly, refers to a 5-membered heterocyclic compound containing a divalent carbon atom bound to two nitrogen (N) atoms within the heterocycle. In the carbene, the carbon atom with two unshared valance electrons may coordinate to a transition metal.

As more particular examples accounting for the term “substituted” in the expression “substituted or unsubstituted” used for compounds of Chemical Formula 1, the compounds may be substituted by at least one substituent selected from the group consisting of a deuterium atom, a cyano, a halogen, a hydroxy, a nitro, an alkyl of 1 to 12 carbon atoms, a halogenated alkyl of 1 to 12 carbon atoms, an alkenyl of 2 to 12 carbon atoms, an alkynyl of 2 to 12 carbon atoms, a cycloalkyl of 3 to 12 carbon atoms, a heteroalkyl of 1 to 12 carbon atoms, an aryl of 6 to 18 carbon atoms, an arylalkyl of 7 to 20 carbon atoms, an alkylaryl of 7 to 20 carbon atoms, a heteroaryl of 2 to 18 carbon atoms, a heteroarylalkyl of 2 to 18 carbon atoms, an alkoxy of 1 to 12 carbon atoms, an amine of 1 to 24 carbon atoms, a silyl of 1 to 24 carbon atoms, a germyl of 1 to 24 carbon atoms, an aryloxy of 6 to 24 carbon atoms, and an arythionyl of 6 to 24 carbon atoms.

In the present disclosure, the organometallic compound represented by Chemical Formula 1 is characterized by the structure in which the L¹ ring moiety is any one selected from a substituted or unsubstituted 5-membered heteroaromatic ring, a substituted or unsubstituted 5-membered heteroaliphatic ring, and a substituted or unsubstituted 5-membered N-heterocyclic carbene; the L² ring moiety is a substituted or unsubstituted 5-membered heteroaromatic ring, or a substituted or unsubstituted 5-membered heteroaliphatic ring; the L³ ring moiety and the L⁴ ring moiety, which are same or different, are each independently selected from a substituted or unsubstituted aromatic hydrocarbon ring of 6 to 50 carbon atoms, a substituted or unsubstituted aliphatic hydrocarbon ring of 5 to 50 carbon atoms, a substituted or unsubstituted fused ring of 7 to 50 carbon atoms with an aromatic hydrocarbon ring and an aliphatic hydrocarbon ring fused to each other, a substituted or unsubstituted heteroaromatic ring of 2 to 50 carbon atoms, and a substituted or unsubstituted fused ring of 6 to 40 carbon atoms with an heteroaromatic ring and an aliphatic hydrocarbon ring fused to each other, wherein: Y within L¹ ring, the nitrogen atom within L² ring, and a carbon atom within L³ ring coordinate to a platinum (Pt) atom, the 5-membered L¹ ring moiety and the L³ ring moiety are linked to each other via a single bond; the carbon atom within the L² ring moiety and the L⁴ ring moiety are linked to each other via a nitrogen atom; the L⁴ ring moiety and the nitrogen (N) atom bonded thereto are bound to the benzene ring bonded to the platinum atom, with a coordinate covalent bond between one carbon atom within the benzene ring and the platinum atom; and a carbon atom within the benzene ring is bonded to L³ ring via a linker T, whereby the organic light-emitting diode with such a structural characteristic can achieve blue light emission with high color purity.

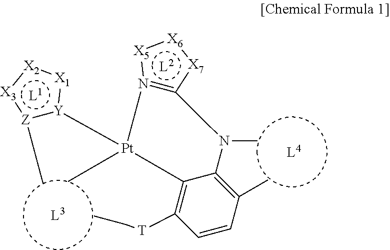

In an embodiment of the present disclosure, L¹ in Chemical Formula 1 may be a 5-membered N-heterocyclic carbene, wherein Z and Y in L¹ ring are as defined above.

In an embodiment of the present disclosure, L¹ in Chemical Formula 1 may have a structure represented by any one selected from the following Structural Formulas 1 to 4:

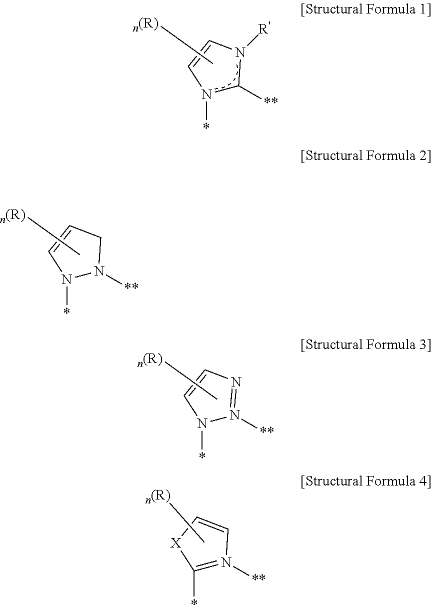

wherein,

R and R′, which may be same or different, are each independently any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, and a substituted or unsubstituted aliphatic hydrocarbon ring-fused heteroaryl of 5 to 30 carbon atoms,

n is an integer of 1 to 3 wherein when n is 2 or higher, the corresponding R's are same or different and the adjacent R's may be linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic hydrocarbon ring of to 30 carbon atoms, or a substituted or unsubstituted heteroaliphatic ring of 3 to 30 carbon atoms,

“-*” stands for a single bond to the L³ ring moiety, and “-**” stands for a bond to the platinum (Pt) atom, and

X in Structural Formula 4 is N, O, or S.

In an embodiment of the present disclosure, when L¹ in Chemical Formula 1 is represented by Structural Formula 1, it has any one selected from the structures represented by the following Structural Formulas 5 to 11:

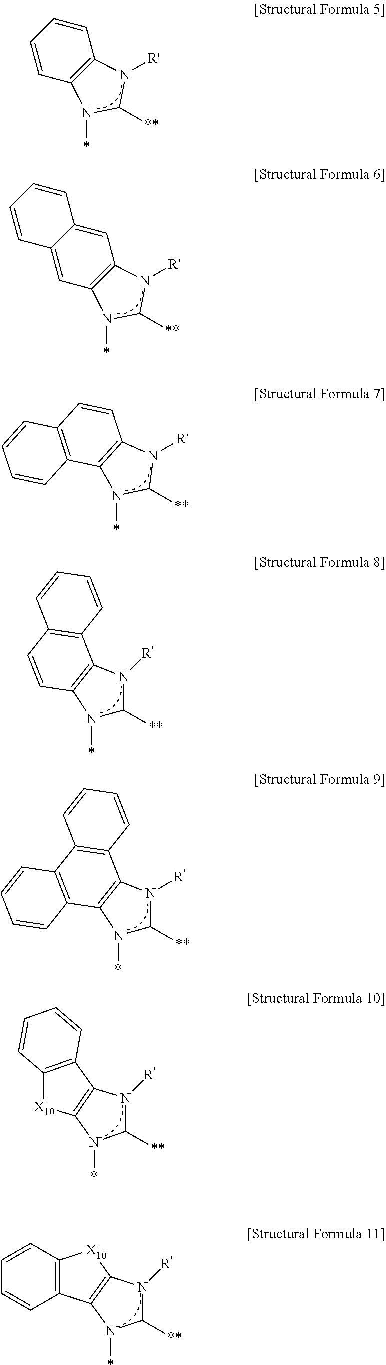

wherein,

R′, “-*”, and “-**” are as defined above in Structural Formulas 1 to 4,

X₁₀ in Structural Formulas 10 and 11 is any one selected from CR₂₁R₂₂, O, and S, wherein R₂₁ and R₂₂ are same or different and are each as defined for R in Structural Formulas 1 to 4.

According to an embodiment of the present disclosure, X⁵ and X⁶ within L² in Chemical Formula 1 are same or different and are each independently CR₇ wherein R₇ may be any one selected from a hydrogen atom, a deuterium atom, a substituted or unsubstituted alkyl of 1 to 30 carbon atoms, and a substituted or unsubstituted aryl of 6 to 50 carbon atoms, and adjacent plural R₇ may be linked to each other to additionally form a substituted or unsubstituted aromatic hydrocarbon ring of 6 to 30 carbon atoms or a substituted or unsubstituted aliphatic hydrocarbon ring of 3 to 30 carbon atoms.

In an embodiment, L² in Chemical Formula 1 may have a structure represented by the following Structural Formula 12:

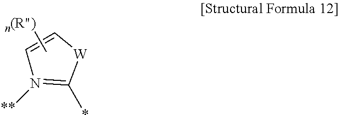

wherein

R″ is as defined for R in Structural Formulas 1 to 4 above,

n is an integer of 1 to 2 wherein when n is 2, the R's are same or different and may be linked to each other to additionally form a substituted or unsubstituted aromatic hydrocarbon ring of 6 to 50 carbon atoms, a substituted or unsubstituted heteroaromatic ring of 2 to 30 carbon atoms, a substituted or unsubstituted aliphatic hydrocarbon ring of 3 to 30 carbon atoms, or a substituted or unsubstituted heteroaliphatic ring of 3 to 30 carbon atoms,

“-*” stands for a single bond to the nitrogen (N) atom and “-**” stands for a bond to the platinum (Pt) atom, and

W is N, O, or S.

According to an embodiment, L² in Chemical Formula 1 may have a structure represented by the following Structural Formula 13:

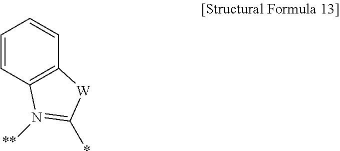

wherein,

W, “-*”, and “-**” are as defined in Structural Formula 12 above.

According to an embodiment of the present disclosure, L³ and L⁴ in Chemical Formula 1 may be same or different and are each independently a substituted or unsubstituted aromatic hydrocarbon ring of 6 to 20 carbon atoms. Particularly, L³ and L⁴ are same or different and are each independently a substituted or unsubstituted benzene ring.

In an embodiment of the present disclosure, T may be any one selected from NR₁₃, O, and S.

In an embodiment of the present disclosure, the compound represented by Chemical Formula 1 may contain at least one deuterium atom.

In an embodiment, the compound represented by Chemical Formula may an organometallic compound selected from [Compound 1] to [Compound 68]:

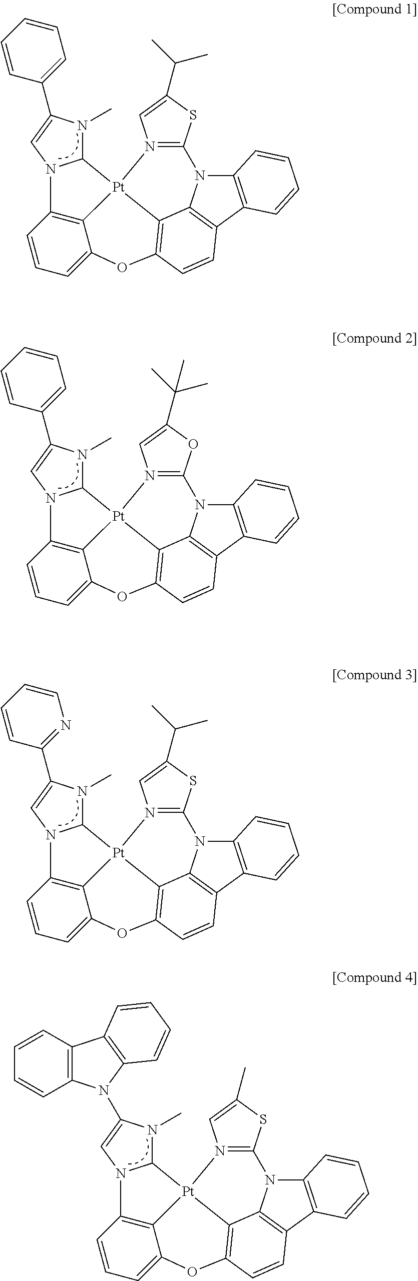

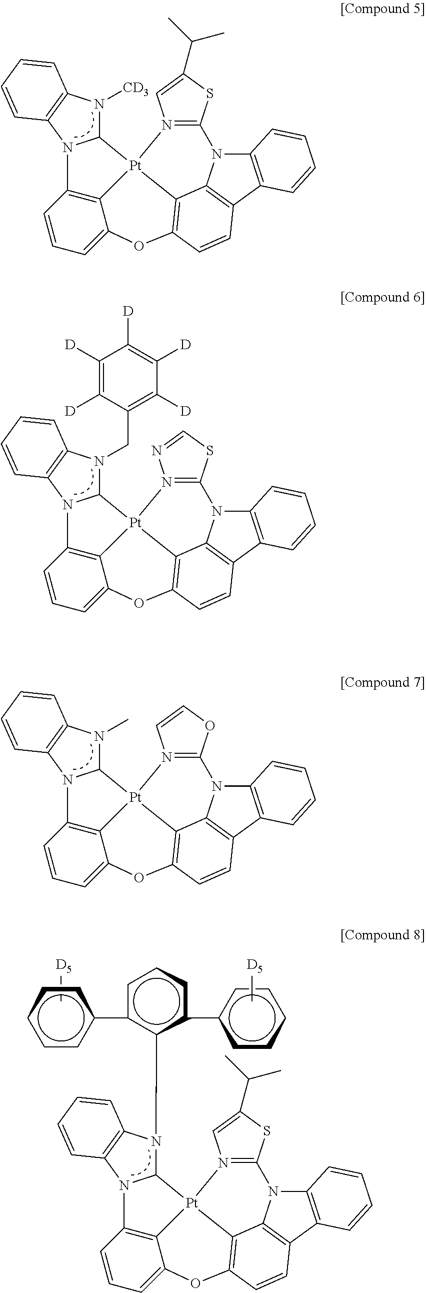

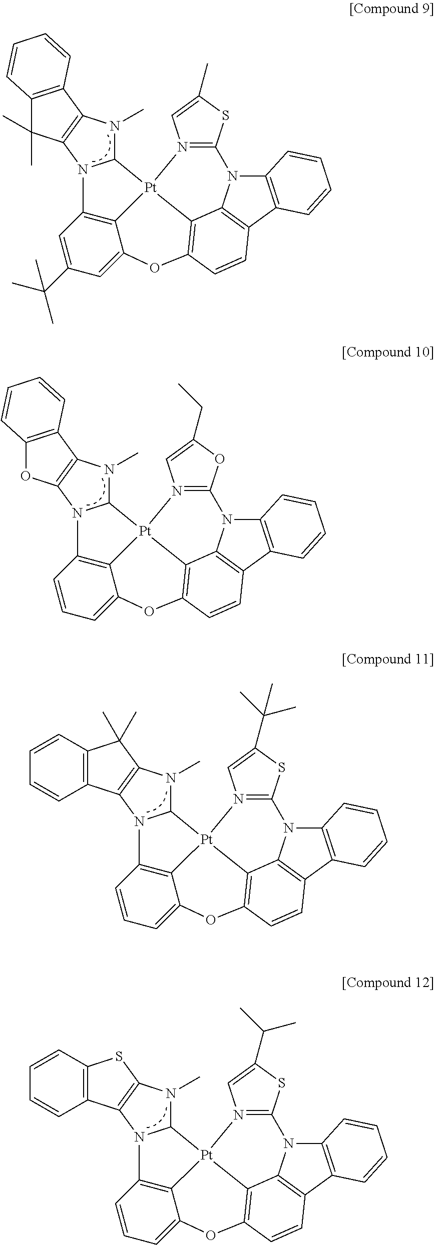

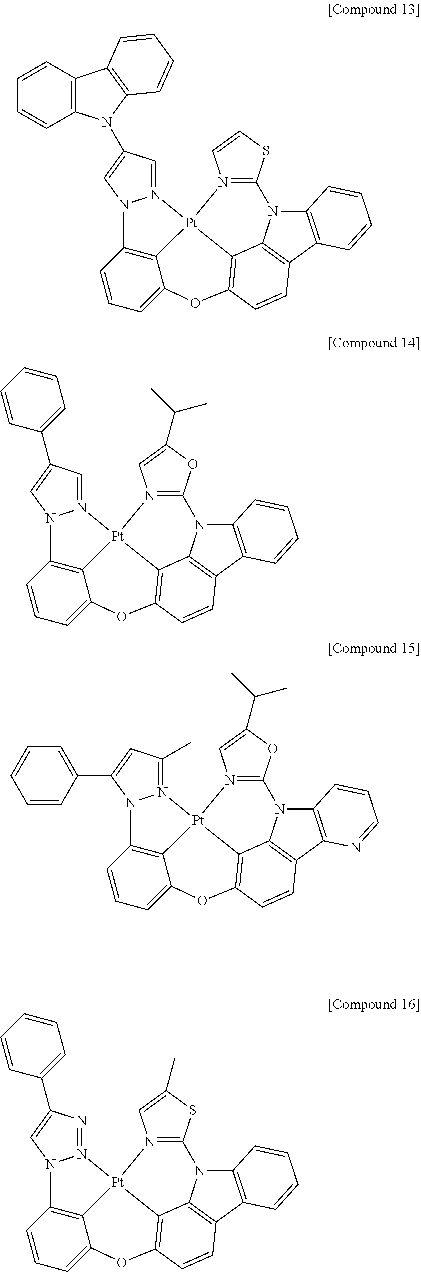

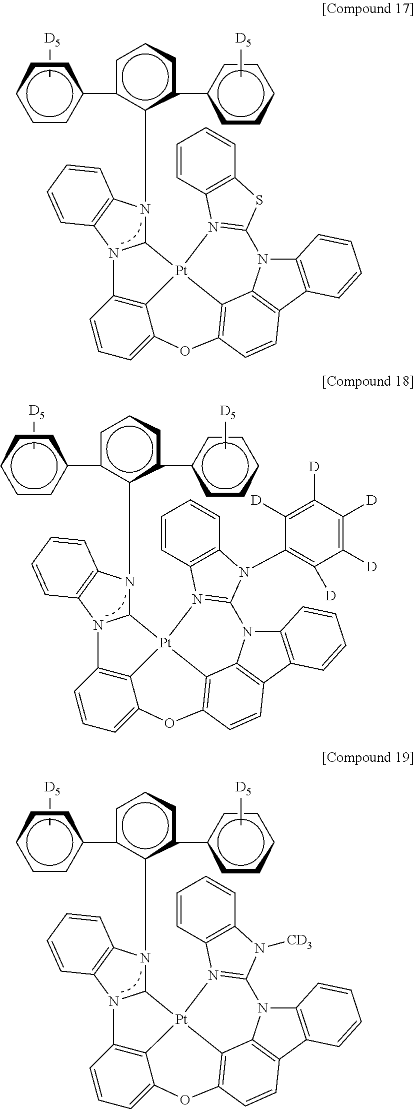

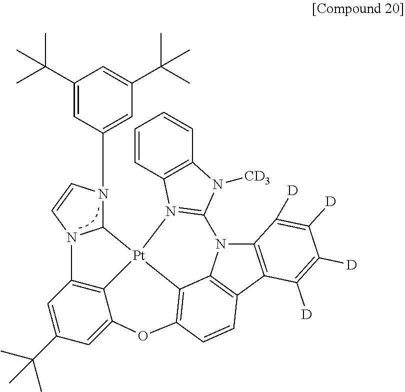

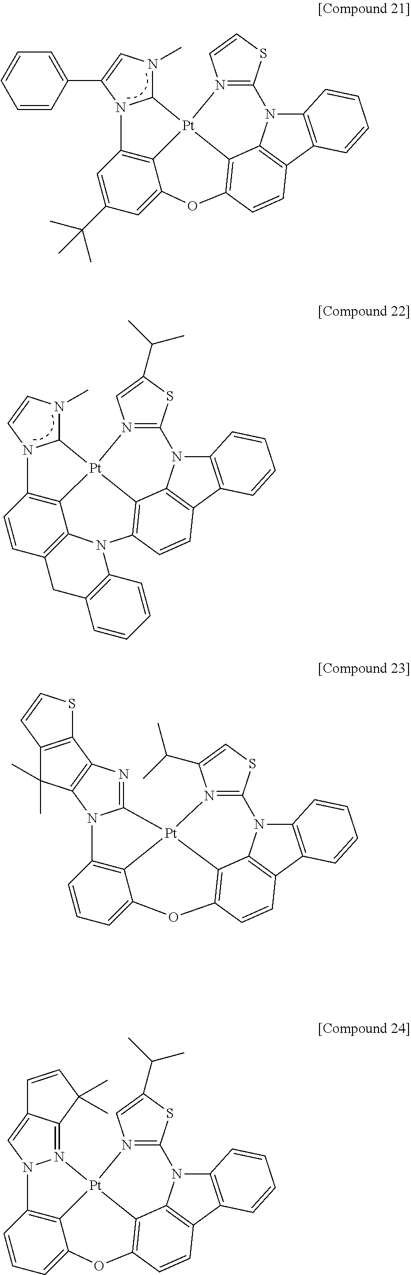

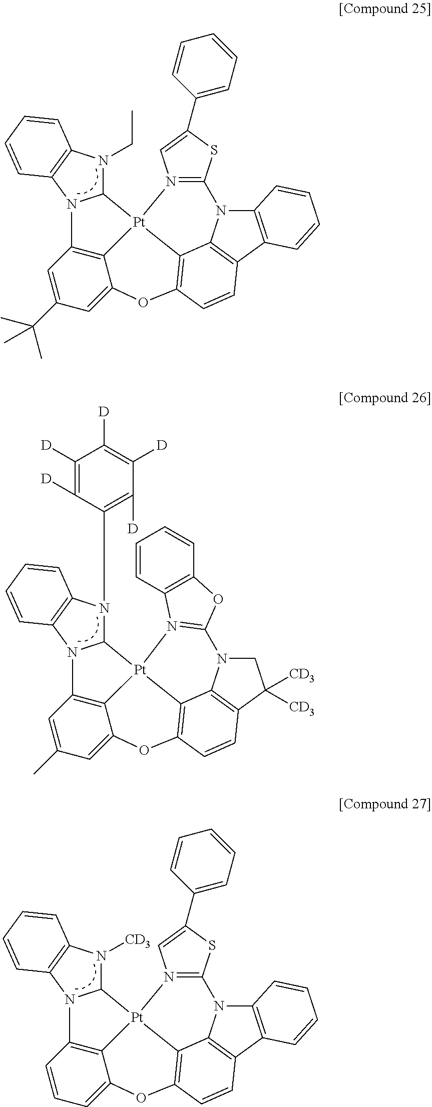

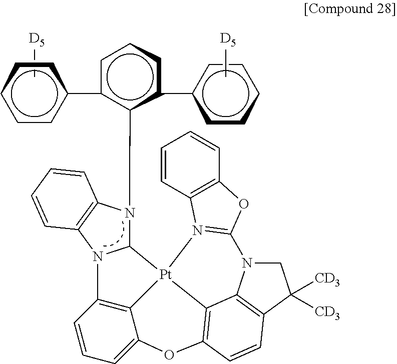

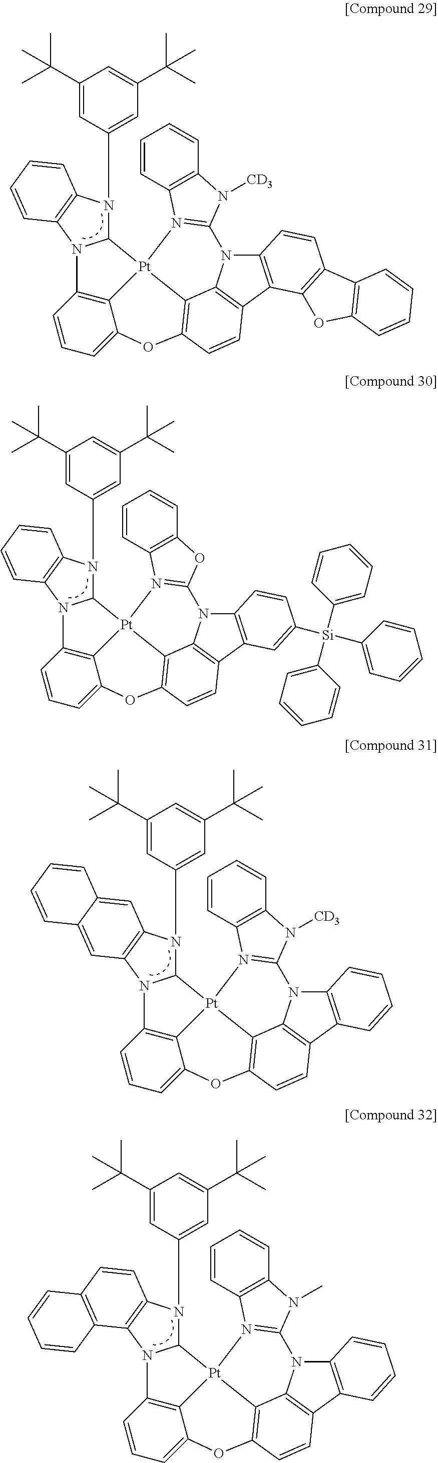

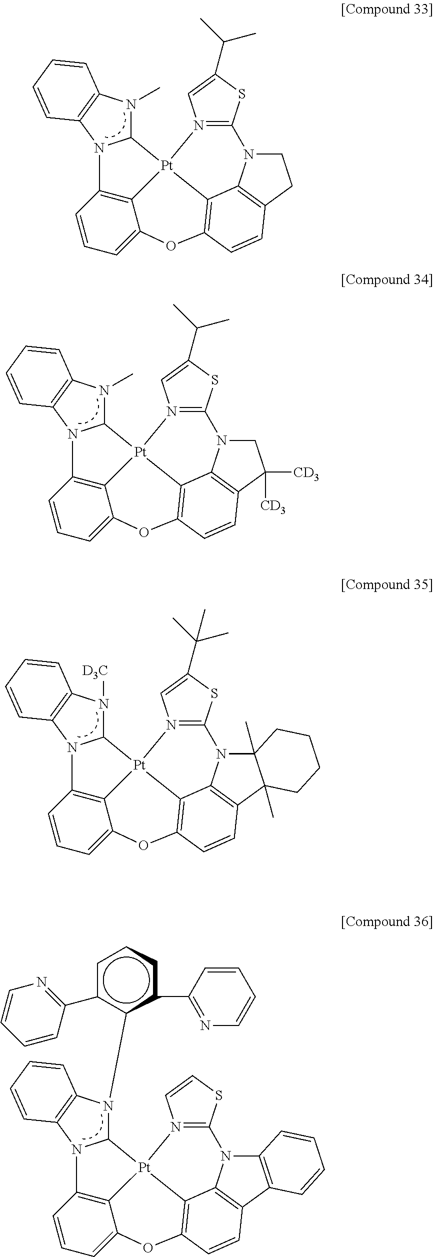

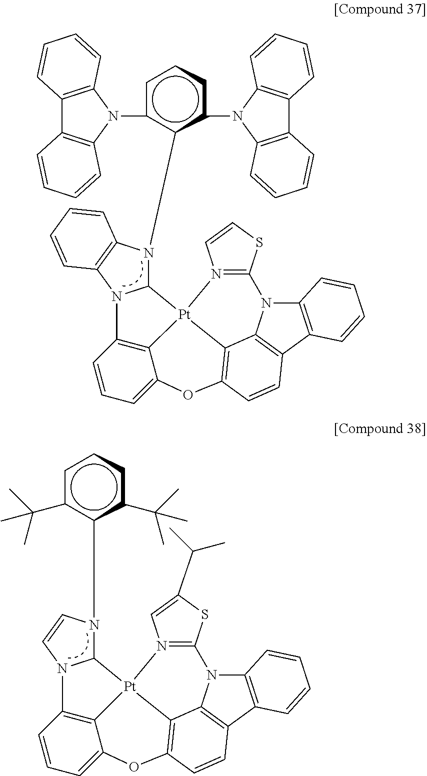

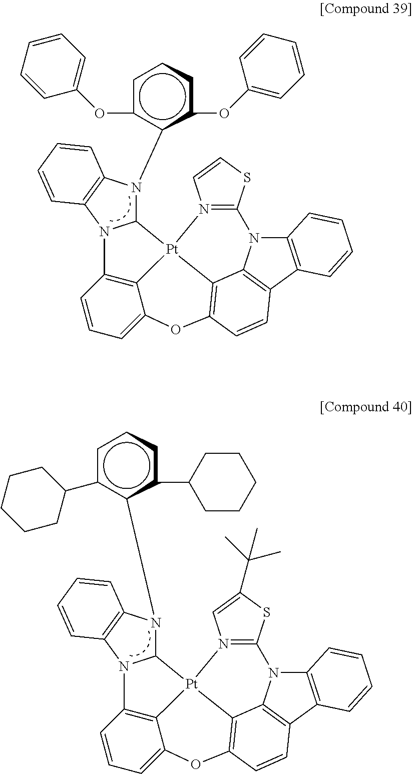

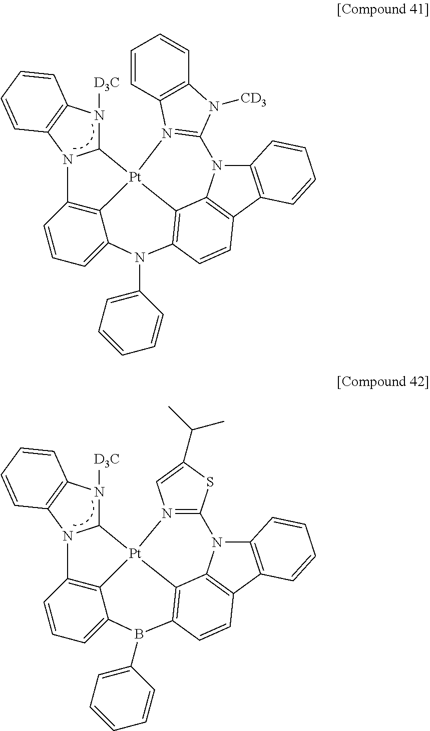

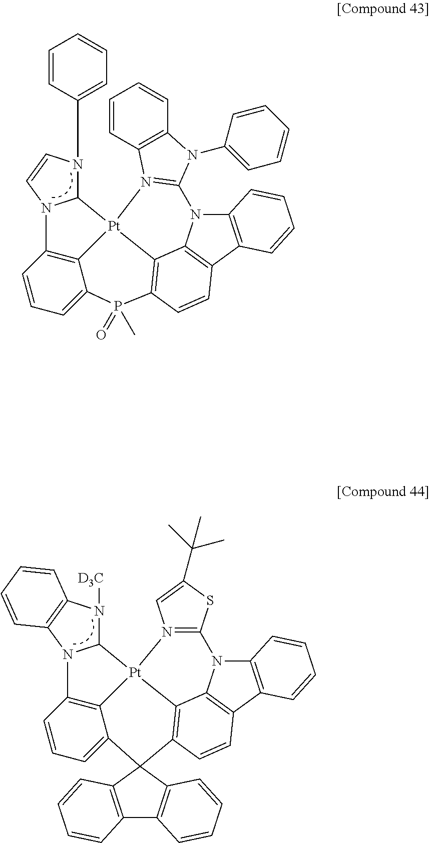

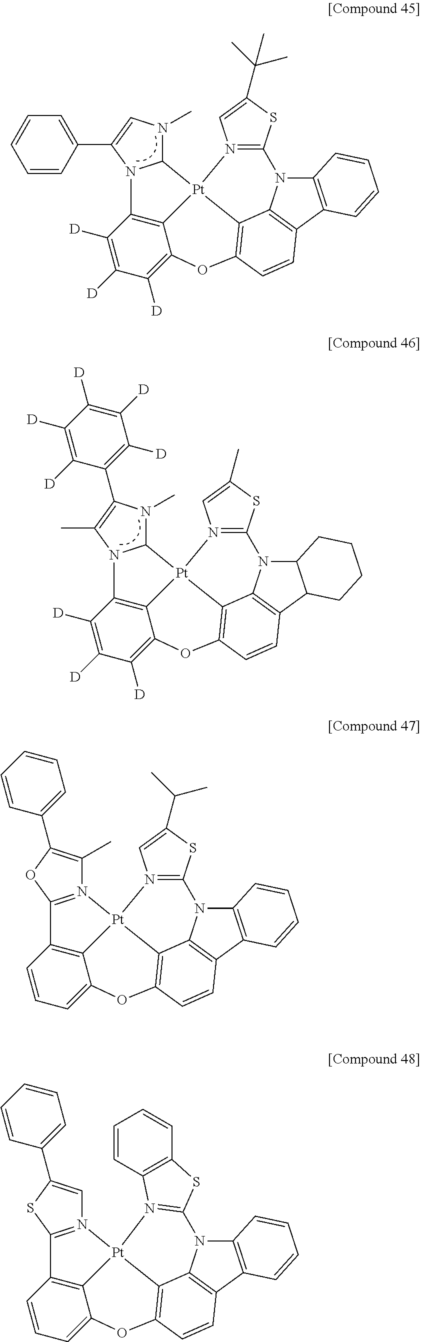

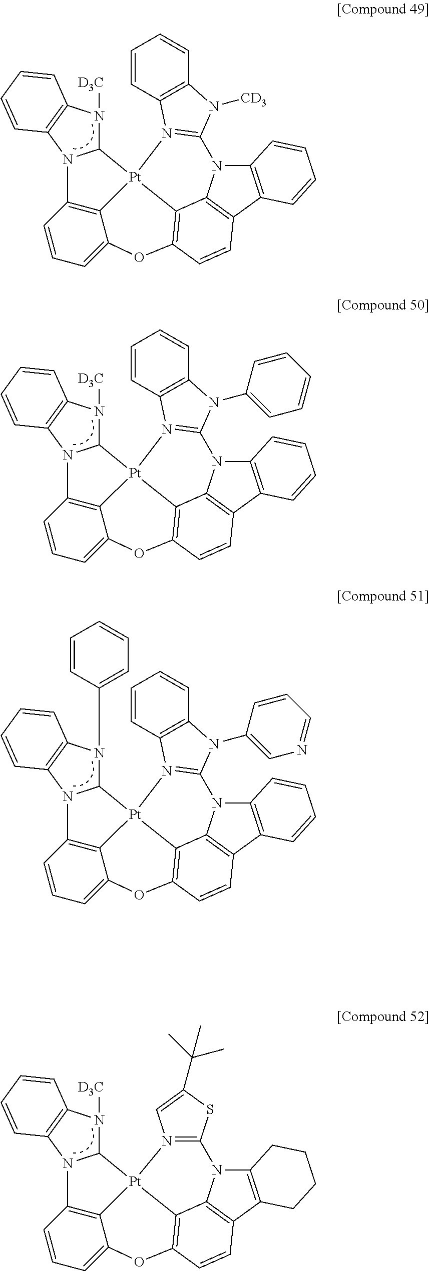

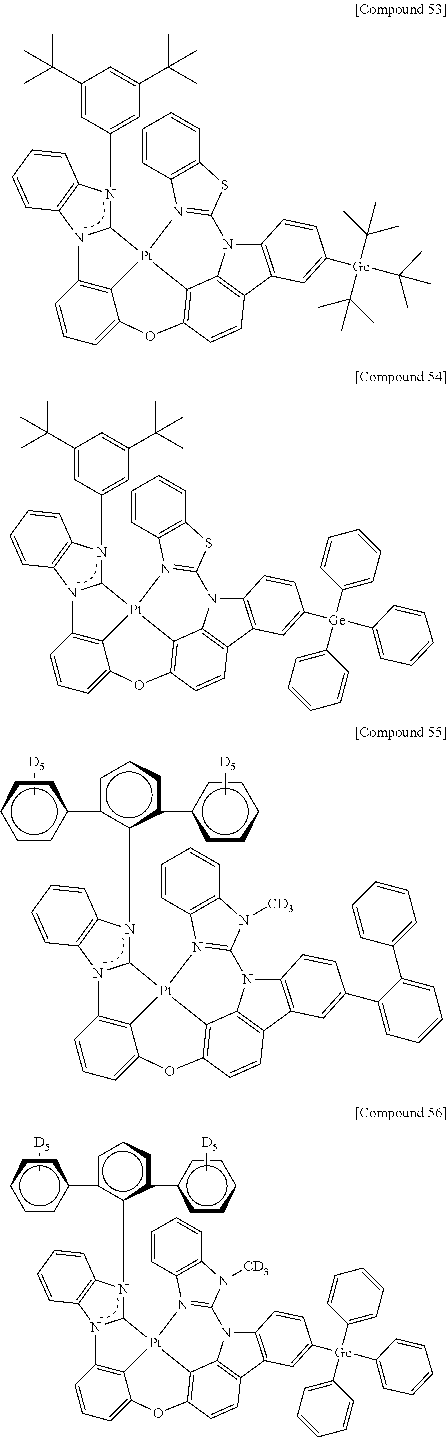

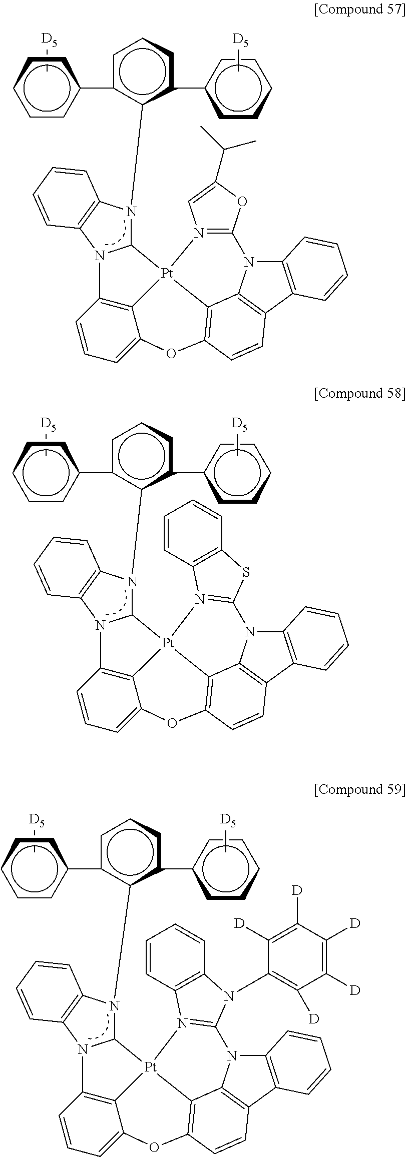

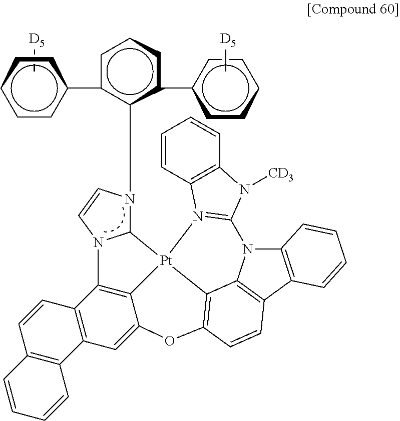

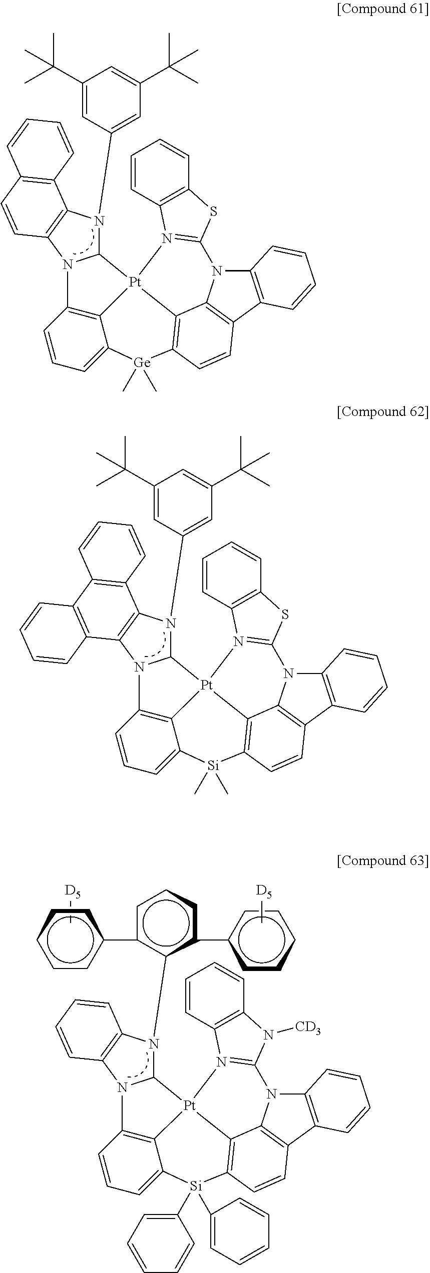

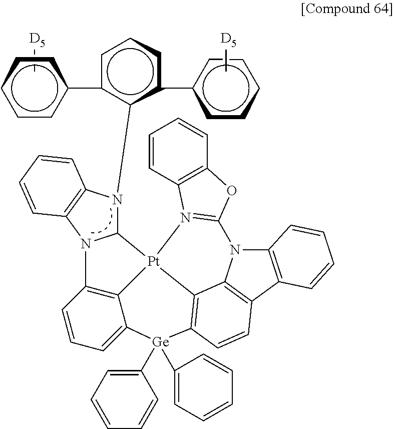

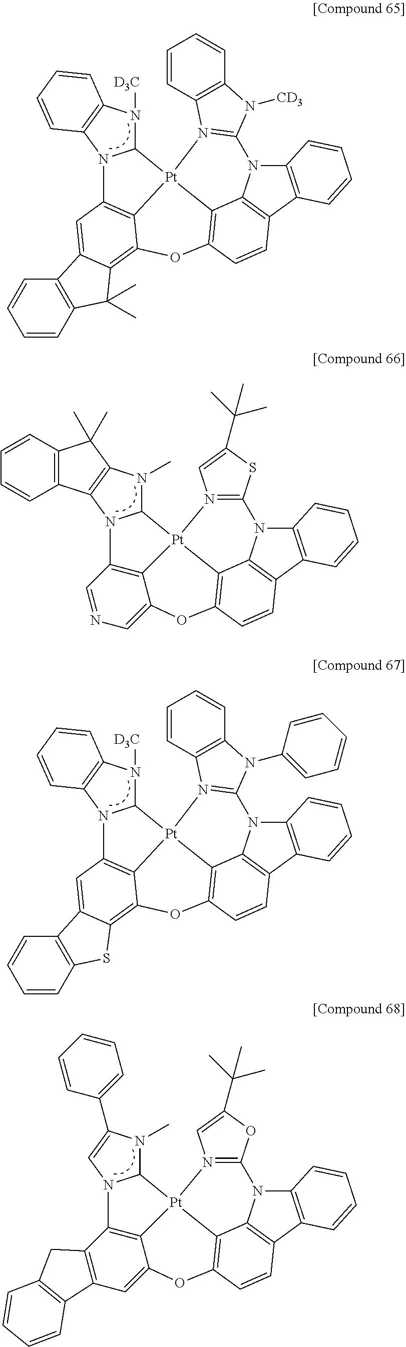

In some particular embodiments, the present disclosure provides an organic light-emitting diode comprising: a first electrode; a second electrode facing the second electrode; and an organic layer interposed between the first electrode and the second electrode, wherein the organic layer includes at least one of the organometallic compounds described above.

Throughout the description of the present disclosure, the phrase “(an organic layer) includes at least one organic compound” may be construed to mean that “(an organic layer) may include a single organic compound species or two or more difference species of organic compounds falling within the scope of the present disclosure”.

In this context, the organic layer in the organic light-emitting diode according to the present disclosure may include at least one of a hole injection layer, a hole transport layer, a functional layer capable of both hole injection and hole transport, an electron barrier layer, an electron transport layer, an electron injection layer, a functional layer capable of both electron injection and electron transport, and a hole barrier layer.

In more particular embodiments of the present disclosure, the organic layer disposed between the first electrode and the second electrode includes a light-emitting layer composed of a host and a dopant, wherein the organometallic compound of the present disclosure is used as a dopant, especially a phosphorescent dopant.

In more particular embodiments of the present disclosure, the dopant may be a combination of the organometallic compound and a different compound which are in mixture or deposited sequentially.

In this regard, the additionally used dopant different from the organometallic compound may be a compound with a TADF property.

In an embodiment, the phosphorescent host compound in the organic light-emitting diode of the present disclosure should be higher in singlet and triplet energy level than the phosphorescent dopant compound. As a rule, a blue phosphorescent host compound has a triplet energy of 2.7 eV or higher. Commercially available materials include mCP, mCPPO1, PPO2, PPO27, and mCBP.

In an embodiment, the host compound may be any one selected from the following [Chemical Formula H1] to [Chemical Formula H24].

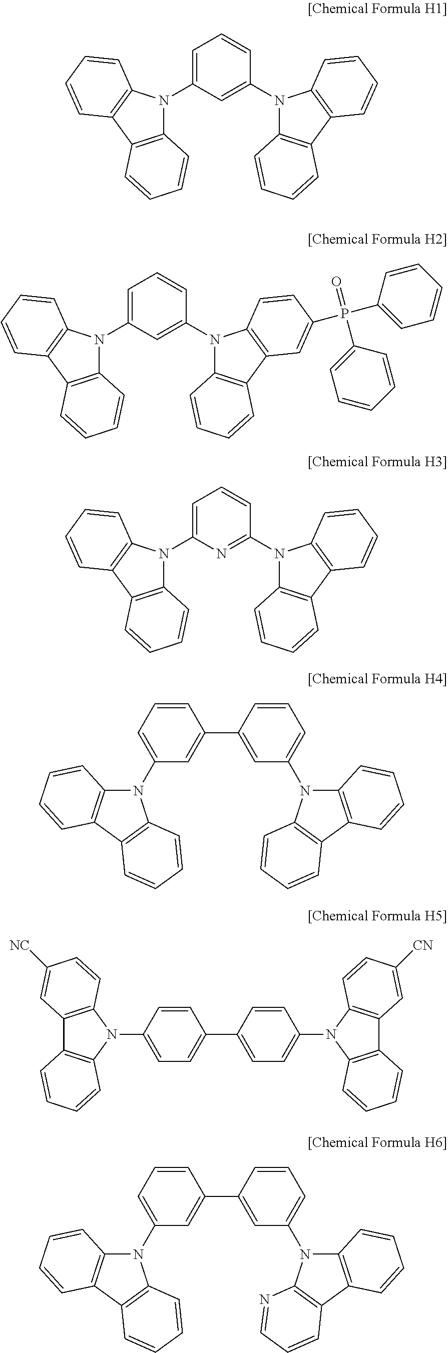 [SMILES: c1cc(-n2c3ccccc3c3ccccc32)cc(-n2c3ccccc3c3ccccc32)c1 ; O=P(c1ccccc1)(c1ccccc1)c1ccc2c(c1)c1ccccc1n2-c1cccc(-n2c3ccccc3c3ccccc32)c1 ; c1cc(-n2c3ccccc3c3ccccc32)nc(-n2c3ccccc3c3ccccc32)c1 ; c1cc(-c2cccc(-n3c4ccccc4c4ccccc43)c2)cc(-n2c3ccccc3c3ccccc32)c1 ; N#Cc1ccc2c(c1)c1ccccc1n2-c1ccc(-c2ccc(-n3c4ccccc4c4cc(C#N)ccc43)cc2)cc1 ; c1cc(-c2cccc(-n3c4ccccc4c4cccnc43)c2)cc(-n2c3ccccc3c3ccccc32)c1]

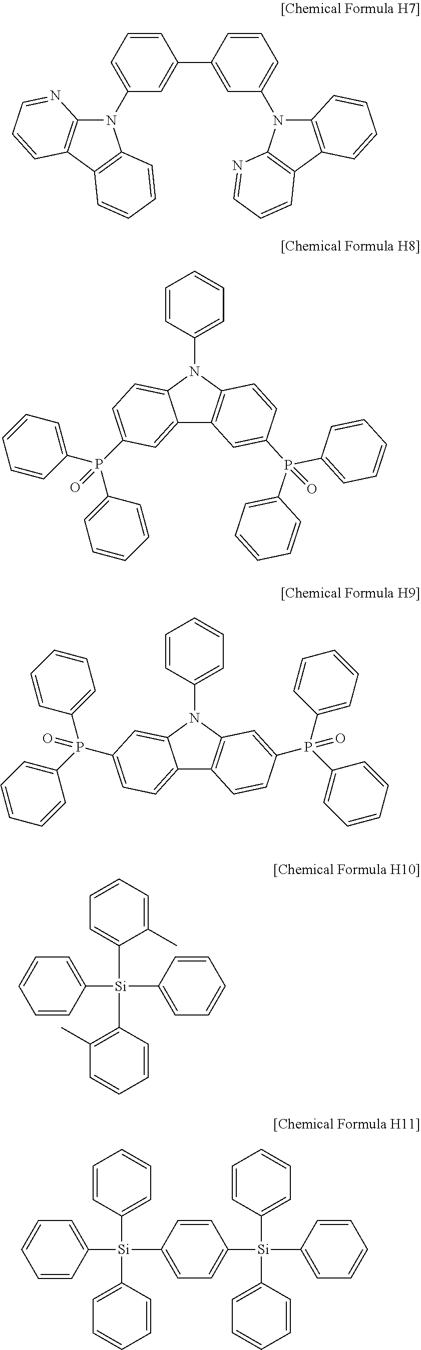 [SMILES: c1cc(-c2cccc(-n3c4ccccc4c4cccnc43)c2)cc(-n2c3ccccc3c3cccnc32)c1 ; O=P(c1ccccc1)(c1ccccc1)c1ccc2c(c1)c1cc(P(=O)(c3ccccc3)c3ccccc3)ccc1n2-c1ccccc1 ; O=P(c1ccccc1)(c1ccccc1)c1ccc2c3ccc(P(=O)(c4ccccc4)c4ccccc4)cc3n(-c3ccccc3)c2c1 ; Cc1ccccc1[Si](c1ccccc1)(c1ccccc1)c1ccccc1C ; c1ccc([Si](c2ccccc2)(c2ccccc2)c2ccc([Si](c3ccccc3)(c3ccccc3)c3ccccc3)cc2)cc1]

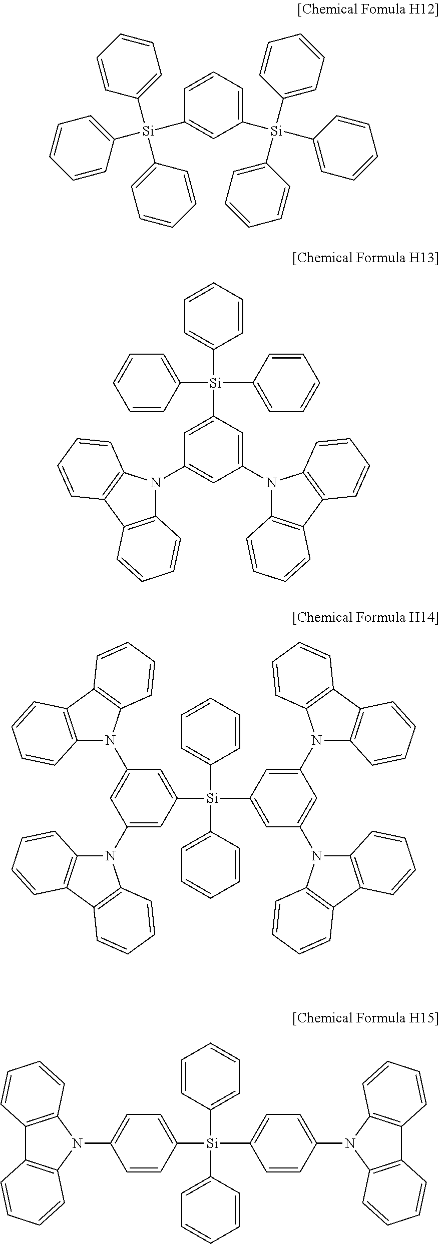 [SMILES: c1ccc([Si](c2ccccc2)(c2ccccc2)c2cccc([Si](c3ccccc3)(c3ccccc3)c3ccccc3)c2)cc1 ; c1ccc([Si](c2ccccc2)(c2ccccc2)c2cc(-n3c4ccccc4c4ccccc43)cc(-n3c4ccccc4c4ccccc43)c2)cc1 ; c1ccc([Si](c2ccccc2)(c2cc(-n3c4ccccc4c4ccccc43)cc(-n3c4ccccc4c4ccccc43)c2)c2cc(-n3c4ccccc4c4ccccc43)cc(-n3c4ccccc4c4ccccc43)c2)cc1 ; c1ccc([Si](c2ccccc2)(c2ccc(-n3c4ccccc4c4ccccc43)cc2)c2ccc(-n3c4ccccc4c4ccccc43)cc2)cc1]

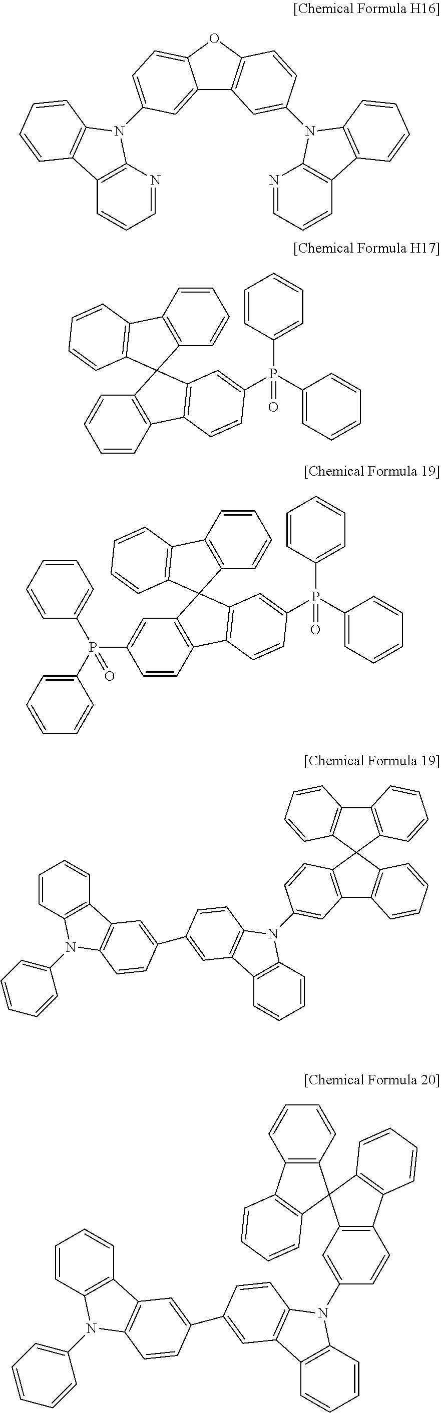 [SMILES: c1ccc2c(c1)c1cccnc1n2-c1ccc2oc3ccc(-n4c5ccccc5c5cccnc54)cc3c2c1 ; O=P(c1ccccc1)(c1ccccc1)c1ccc2c(c1)C1(c3ccccc3-c3ccccc31)c1ccccc1-2 ; O=P(c1ccccc1)(c1ccccc1)c1ccc2c(c1)C1(c3ccccc3-c3ccccc31)c1cc(P(=O)(c3ccccc3)c3ccccc3)ccc1-2 ; c1ccc(-n2c3ccccc3c3cc(-c4ccc5c(c4)c4ccccc4n5-c4ccc5c(c4)-c4ccccc4C54c5ccccc5-c5ccccc54)ccc32)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1]

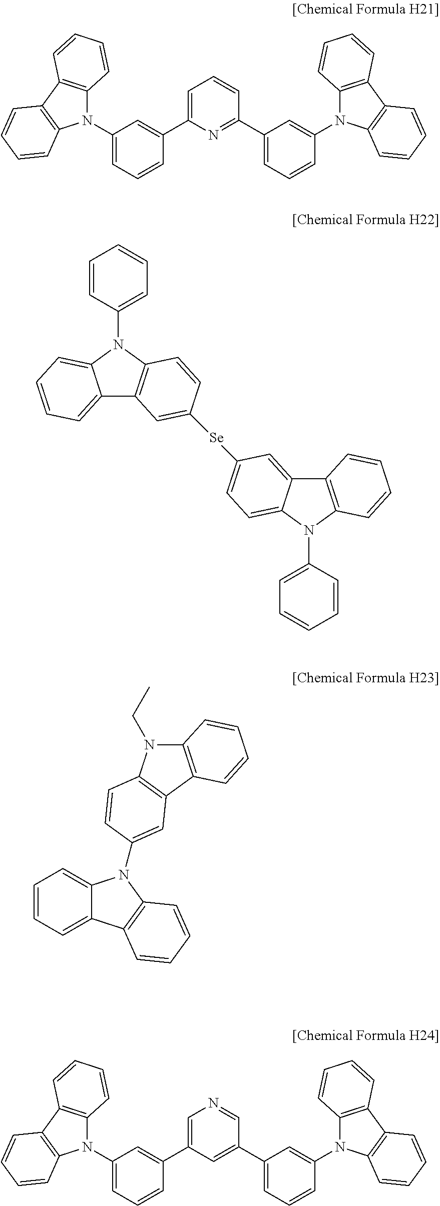 [SMILES: c1cc(-c2cccc(-c3cccc(-n4c5ccccc5c5ccccc54)c3)n2)cc(-n2c3ccccc3c3ccccc32)c1 ; c1ccc(-n2c3ccccc3c3cc([Se]c4ccc5c(c4)c4ccccc4n5-c4ccccc4)ccc32)cc1 ; CCn1c2ccccc2c2cc(-n3c4ccccc4c4ccccc43)ccc21 ; c1cc(-c2cncc(-c3cccc(-n4c5ccccc5c5ccccc54)c3)c2)cc(-n2c3ccccc3c3ccccc32)c1]

In a particular embodiment thereof, the present invention provides an organic light-emitting diode comprises: an anode as a first electrode; a cathode as a second electrode facing the first electrode; and an organic layer interposed between the anode and the cathode, wherein the organic layer includes at least one of the organometallic compounds represented by Chemical Formula 1 as a dopant. Having such structural characteristics, the organic light-emitting diode according to the present disclosure can exhibit blue light emission with high color purity.

The content of the dopant in the light-emitting layer may range from about 0.01 to 20 parts by weight, based on 100 parts by weight of the host, but is not limited thereto.

In addition to the above-mentioned dopants and hosts, the light-emitting layer may further include various hosts and dopant materials.

Below, the organic light-emitting diode of the present disclosure is explained with reference to the drawings.

The organic light-emitting diode according to an embodiment of the present disclosure comprises an anode 20, a hole transport layer 40, an organic light-emitting layer 50 containing a host and a dopant, an electron transport layer 60, and a cathode 80, wherein the anode and the cathode serve as a first electrode and a second electrode, respectively, with the interposition of the hole transport layer between the anode and the light-emitting layer, and the electron transport layer between the light-emitting layer and the cathode.

Furthermore, the organic light-emitting diode according to an embodiment of the present disclosure may comprise a hole injection layer 30 between the anode 20 and the hole transport layer 40, and an electron injection layer 70 between the electron transport layer 60 and the cathode 80.

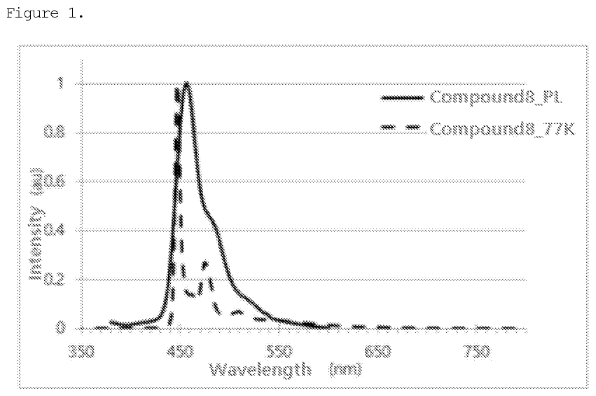

Reference is made to FIG. 1 with regard to the organic light emitting diode of the present disclosure and the fabrication method therefor.

First, a substrate 10 is coated with an anode electrode material to form an anode 20. So long as it is used in a typical organic electroluminescence device, any substrate may be used as the substrate 10. Preferable is an organic substrate or transparent plastic substrate that exhibits excellent transparency, surface smoothness, ease of handling, and waterproofness. As the anode electrode material, indium tin oxide (ITO), indium zinc oxide (IZO), tin oxide (SnO₂), or zinc oxide (ZnO), which are transparent and superb in terms of conductivity, may be used.

A hole injection layer material is applied on the anode 20 by thermal deposition in a vacuum or by spin coating to form a hole injection layer 30. Subsequently, thermal deposition in a vacuum or by spin coating may also be conducted to form a hole transport layer 40 with a hole transport layer material on the hole injection layer 30.

So long as it is typically used in the art, any material may be selected for the hole injection layer without particular limitations thereto. Examples include, but are not limited to, 2-TNATA [4,4′,4″-tris(2-naphthylphenyl-phenylamino)-triphenylamine], NPD [N,N′-di(1-naphthyl)-N,N′-diphenylbenzidine)], TPD [N,N′-diphenyl-N,N′-bis(3-methylphenyl)-1,1′-biphenyl-4,4′-diamine], DNTPD [N,N′-diphenyl-N,N′-bis-[4-(phenyl-m-tolyl-amino)-phenyl]-biphenyl-4,4′-diamine], and HAT-CN (2,3,6,7,10,11-hexacyanohexaazatriphenylene).

Any material that is typically used in the art may be selected for the hole transport layer without particular limitations thereto. Examples include, but are not limited to, N,N′-bis(3-methylphenyl)-N,N′-diphenyl-[1,1-biphenyl]-4,4′-diamine (TPD) and N,N′-di(naphthalen-1-yl)-N,N′-diphenylbenzidine (a-NPD).

In an embodiment of the present disclosure, an electron blocking layer may be additionally disposed on the hole transport layer. Functioning to prevent the electrons injected from the electron injection layer from entering the hole transport layer through the light-emitting layer, the electron blocking layer is adapted to increase the life span and luminous efficiency of the diode. The electron blocking layer may be formed of any of suitable materials or a combination thereof at a suitable position between the light emitting layer and the hole injection layer. Particularly, the electron blocking layer may be formed between the light emitting layer and the hole transport layer.

Next, the light-emitting layer 50 may be deposited on the hole transport layer 40 or the electron blocking layer by deposition in a vacuum or by spin coating.

Herein, the light-emitting layer may contain a host and a dopant and the materials are as described above.

In some embodiments of the present disclosure, the light-emitting layer particularly ranges in thickness from 50 to 2,000 Å.

Meanwhile, the electron transport layer 60 is applied on the light-emitting layer by deposition in a vacuum and spin coating.

A material for use in the electron transport layer functions to stably carry the electrons injected from the electron injection electrode (cathode), and may be an electron transport material known in the art. Examples of the electron transport material known in the art include quinoline derivatives, particularly, tris(8-quinolinolate)aluminum (Alq₃), Liq, TAZ, BAlq, beryllium bis(benzoquinolin-10-olate) (Bebq₂), Compound 201, Compound 202, BCP, and oxadiazole derivatives such as PBD, BMD, and BND, but are not limited thereto:

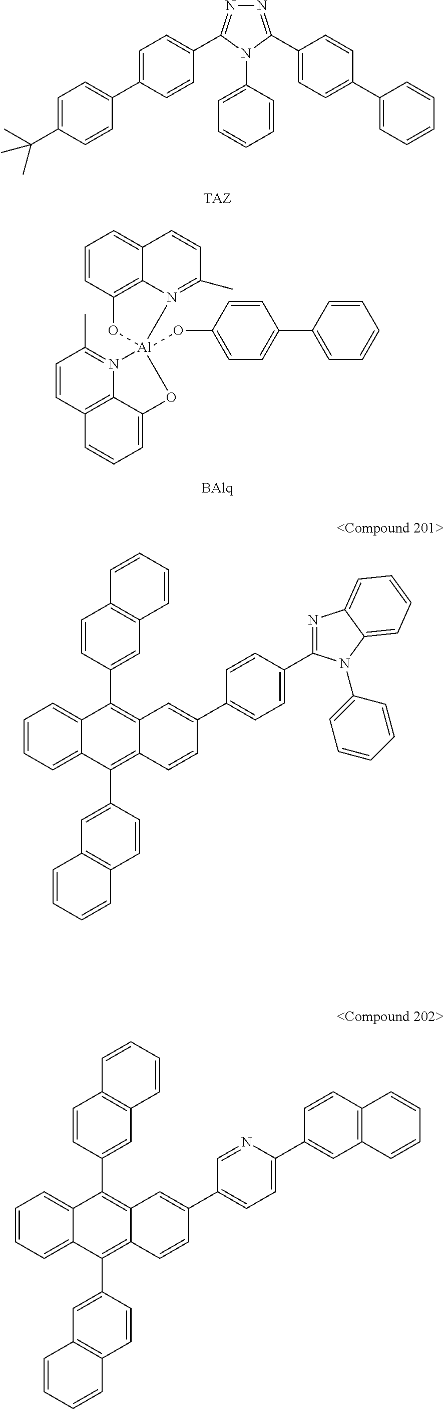

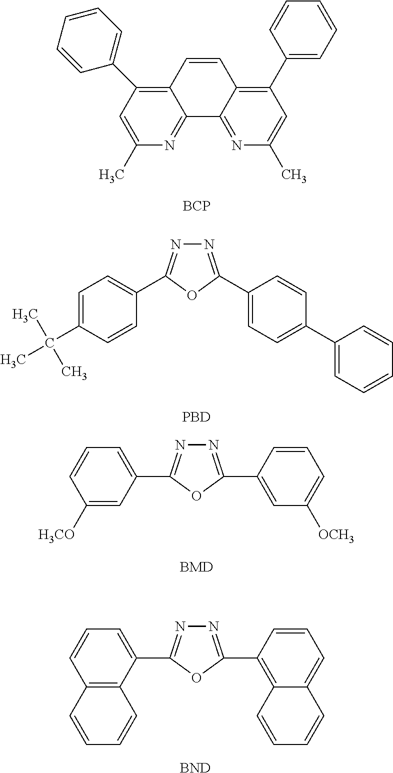

In the organic light emitting diode of the present disclosure, an electron injection layer (EIL) that functions to facilitate electron injection from the cathode may be deposited on the electron transport layer. The material for the EIL is not particularly limited.

Any material that is conventionally used in the art can be available for the electron injection layer without particular limitations. Examples include CsF, NaF, LiF, Li₂O, and BaO.

Deposition conditions for the electron injection layer may vary, depending on compounds used, but may be generally selected from condition scopes that are almost the same as for the formation of hole injection layers.

The electron injection layer may range in thickness from about 1 Å to about 100 Å, and particularly from about 3 Å to about 90 Å. Given the thickness range for the electron injection layer, the diode can exhibit satisfactory electron injection properties without actually elevating a driving voltage.

In order to facilitate electron injection, the cathode may be made of a material having a small work function, such as metal or metal alloy such as lithium (Li), magnesium (Mg), calcium (Ca), an alloy aluminum (Al) thereof, aluminum-lithium (Al—Li), magnesium-indium (Mg—In), and magnesium-silver (Mg—Ag). Alternatively, ITO or IZO may be employed to form a transparent cathode for an organic light-emitting diode.

Moreover, the organic light-emitting diode of the present disclosure may further comprise a light-emitting layer containing a blue, green, or red luminescent material that emits radiations in the wavelength range of 380 nm to 800 nm. That is, the light-emitting layer in the present disclosure has a multi-layer structure wherein the blue, green, or red luminescent material may be a fluorescent material or a phosphorescent material.

Furthermore, at least one selected from among the layers may be deposited using a single-molecule deposition process or a solution process.

Here, the deposition process is a process by which a material is vaporized in a vacuum or at a low pressure and deposited to form a layer, and the solution process is a method in which a material is dissolved in a solvent and applied for the formation of a thin film by means of inkjet printing, roll-to-roll coating, screen printing, spray coating, dip coating, spin coating, etc.

Also, the organic light-emitting diode of the present disclosure may be applied to a device selected from among flat display devices, flexible display devices, monochrome or grayscale flat illumination devices, and monochrome or grayscale flexible illumination devices.

A better understanding of the present disclosure may be obtained through the following examples which are set forth to illustrate, but are not to be construed as limiting the present invention.

### EXAMPLES

### Synthesis Example 1. Synthesis of [Compound 8]

### Synthesis Example 1-1. Synthesis of A-1

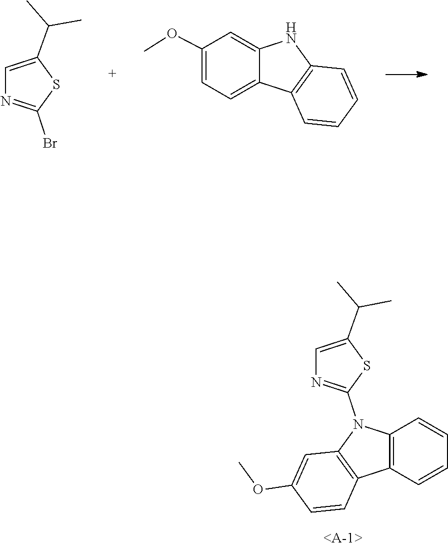

In a 1-L round-bottom flask, 2-bromo-5-isopropylthiazole (19.8 g), 2-methoxy-9H-carbazole (22.7 g), Copper(I) chloride (0.10 g), 1-methyl-1H-imidazole (0.16 g), lithium Cert-butoxide (11.5 g), and toluene (365 mL) were stirred together for 16 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Column chromatographic isolation and purification followed by drying afforded <A-1>. (28.8 g, 92.9%)

### Synthesis Example 1-2. Synthesis of <A-2>

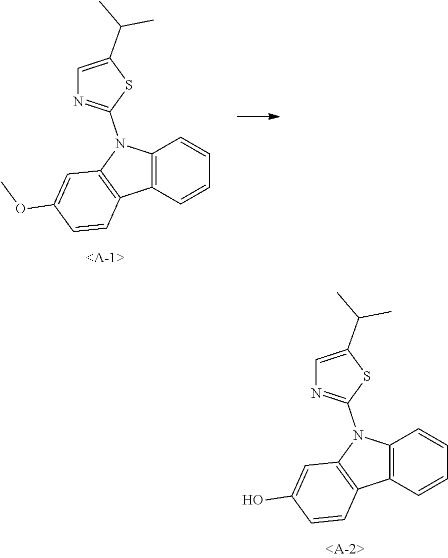 [SMILES: COc1ccc2c3ccccc3n(-c3ncc(C(C)C)s3)c2c1 ; CC(C)c1cnc(-n2c3ccccc3c3ccc(O)cc32)s1]

In a 1-L round-bottom flask, <A-1> (27.8 g), HBr (48% aqueous solution) (48.7 mL), and acetic acid (220 mL) were stirred together for 24 hours under reflux. After completion of the reaction, the reaction mixture was poured into water and neutralized with sodium hydrogen carbonate. The precipitates thus formed were filtered, isolated and purified through column chromatography, and dried to afford <A-2>. (20.5 g, 77.1%).

### Synthesis Example 1-3. Synthesis of <A-3>

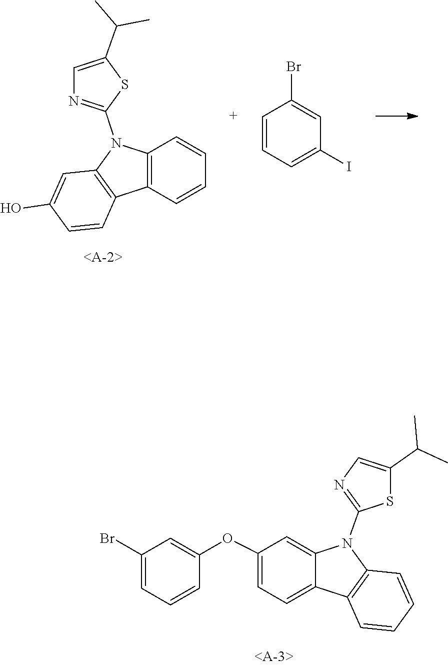 [SMILES: CC(C)c1cnc(-n2c3ccccc3c3ccc(O)cc32)s1 ; Brc1cccc(I)c1 ; CC(C)c1cnc(-n2c3ccccc3c3ccc(Oc4cccc(Br)c4)cc32)s1]

In a 1-L reactor, <A-2> (20.1 g), 1-bromo-3-iodobenzene (27.7 g), copper (I) iodide (2.49 g), 2-picolinic acid (3.2 g), tripotassium phosphate (34.6 g), and DMSO (300 mL) were stirred together at 120° C. for 16 hours. After completion of the reaction, the reaction mixture was cooled to room temperature and then subjected to extraction with ethyl acetate and water. The organic layer thus formed was isolated, dried with magnesium sulfate, and concentrated in a vacuum. Column chromatographic isolation and purification followed by drying afforded <A-3>. (28.1 g, 90.3%)

### Synthesis Example 1-4. Synthesis of <A-4>

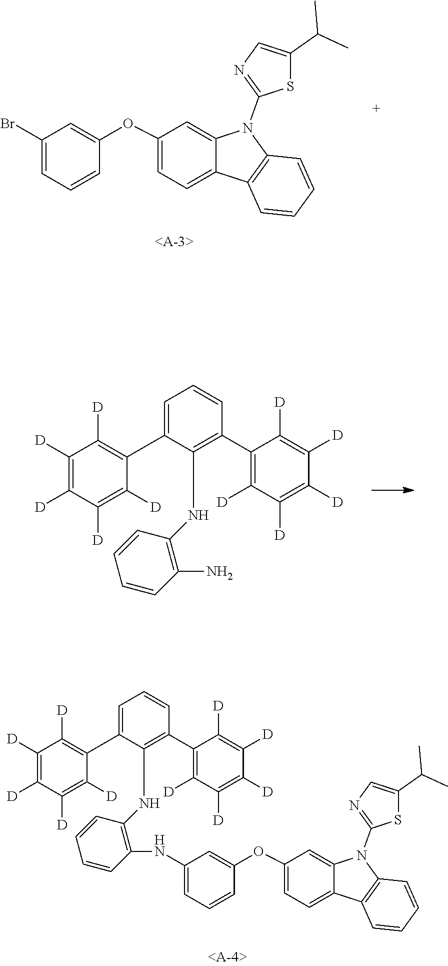 [SMILES: CC(C)c1cnc(-n2c3ccccc3c3ccc(Oc4cccc(Br)c4)cc32)s1 ; [2H]c1c([2H])c([2H])c(-c2cccc(-c3c([2H])c([2H])c([2H])c([2H])c3[2H])c2Nc2ccccc2N)c([2H])c1[2H] ; [2H]c1c([2H])c([2H])c(-c2cccc(-c3c([2H])c([2H])c([2H])c([2H])c3[2H])c2Nc2ccccc2Nc2cccc(Oc3ccc4c5ccccc5n(-c5ncc(C(C)C)s5)c4c3)c2)c([2H])c1[2H]]

In a 1-L round-bottom flask, <A-3> (28.1 g), N1-([1,1′:3′,1″-terphenyl]-2′-yl-2,2″,3,3″,4,4″,5,5″,6,6″-d10)benzene-1,2-diamine (25.2 g), SPhos (2.9 g), sodium Cert-butoxide (10.5 g), Tris(dibenzylideneacetone)dipalladium(0) (3.3 g), and toluene (365 mL) were stirred together for 16 hours under reflux. After completion of the reaction, the reaction mixture was cooled to room temperature and then subjected to ethyl acetate and water. The organic layer thus formed was isolated, dried with magnesium sulfate, and concentrated in a vacuum. Column chromatographic isolation and purification followed by drying afforded <A-4>. (30.8 g, 69.6%)

### Synthesis Example 1-5. Synthesis of <A-5>

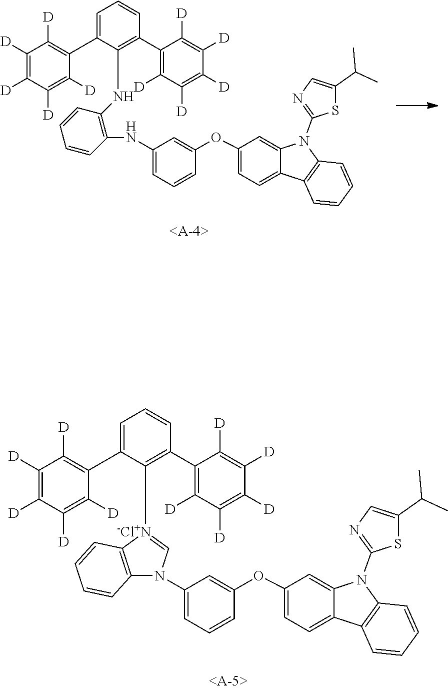

In a 1-L reactor, <A-4> (30.5 g), triethoxymethane (310 g), and hydrochloric acid (3 mL) were stirred together for 4 hours under reflux. After completion of the reaction, the reaction mixture was cooled and then concentrated in a vacuum. Column chromatographic isolation and purification followed by drying afforded <A-5>. (24 g, 74.1%)

### Synthesis Example 1-6. Synthesis of <A-6>

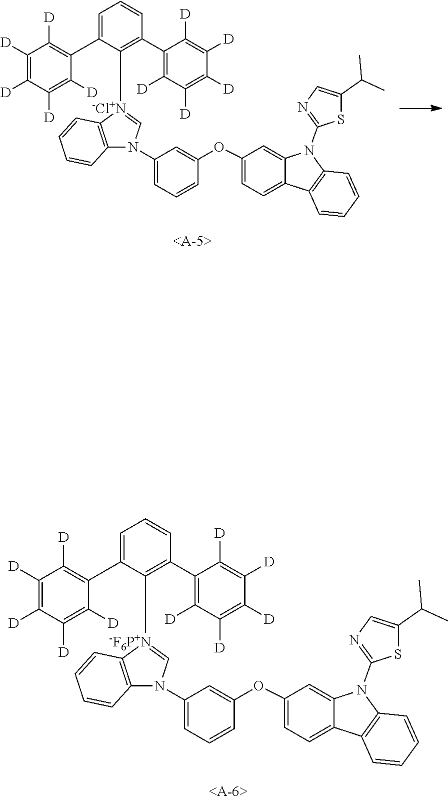

In a 1-L reactor, <A-5> (24 g) and methanol (320 mL) were stirred together at room temperature. A solution of ammonium hexafluorophosphate (7.6 g) in distilled water (240 mL) was added dropwise. After completion of the reaction, the reaction mixture was concentrated in a vacuum to remove methanol and the precipitates thus formed was filtered and washed three times with distilled water to afford <A-6>. (26.2 g, 95.6%)

### Synthesis Example 1-7. Synthesis of [Compound 8]

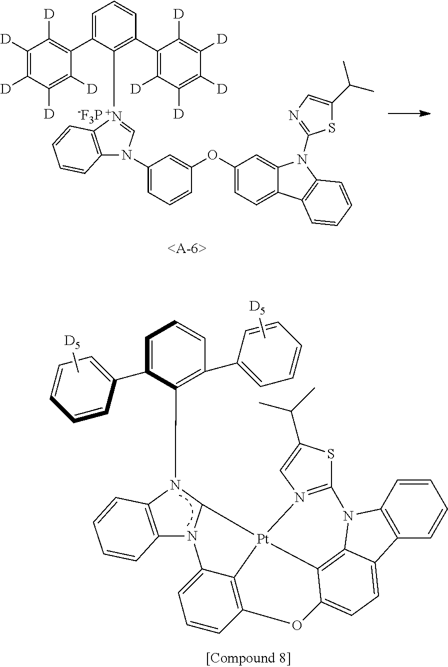

In a 1-L reactor, <A-6> (25.2 g), dichloro(1,5-cyclooctadiene) platinum(II) (15.9 g), sodium acetate (7 g), and DMF (252 mL) were stirred together for 20 hours under reflux. After completion of the reaction, the reaction mixture was cooled to room temperature and poured to water. The precipitates thus formed were filtered. Column chromatographic isolation and purification followed by recrystallization in dichloromethane and acetone afforded [Compound 8]. (9.2 g, 34.6%)

### Synthesis Example 2: Synthesis of [Compound 17]

### Synthesis Example 2-1. Synthesis of <B-1>

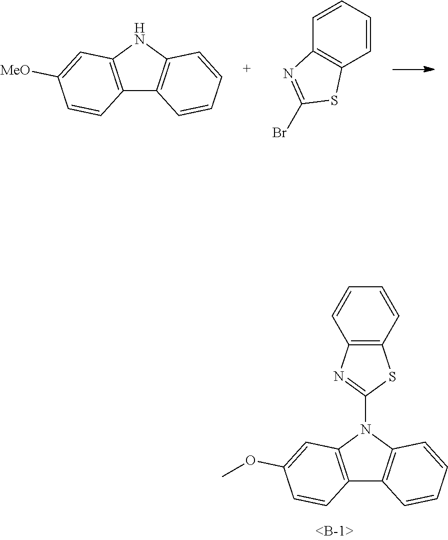 [SMILES: COc1ccc2c(c1)[nH]c1ccccc12 ; Brc1nc2ccccc2s1 ; COc1ccc2c3ccccc3n(-c3nc4ccccc4s3)c2c1]

In a 2-L round-bottom flask, 2-methoxy-9H-carbazole (38.4 g), 2-bromobenzothiazole (50.2 g), copper(I) chloride (0.2 g), 1-methyl-1H-imidazole (0.3 g), lithium Cert-butoxide (23.4 g), and toluene (592 mL) were stirred together for 17 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <B-1>. (59 g, 91.8%)

### Synthesis Example 2-2. Synthesis of <B-2>

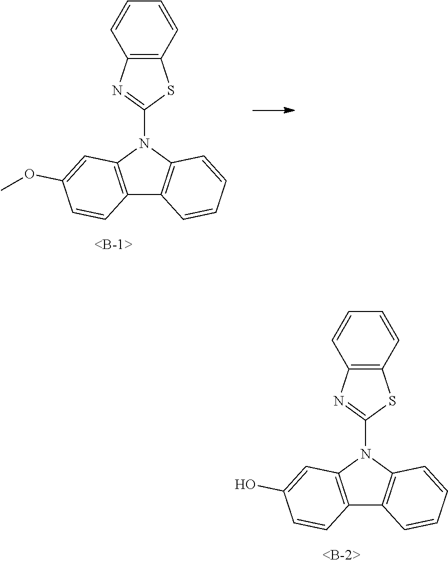 [SMILES: COc1ccc2c3ccccc3n(-c3nc4ccccc4s3)c2c1 ; Oc1ccc2c3ccccc3n(-c3nc4ccccc4s3)c2c1]

In a 1-L round-bottom flask, <B-1> (98.1 g), hydrobromic acid (241.9 mL) and acetic acid (343.4 mL) were stirred together for 17 hours under reflux. The reaction mixture was cooled to room temperature and then neutralized with drops of 1 N NaOH solution. The solid thus formed was stirred and filtered to afford <B-2>. (93.9 g, 99.9%)

### Synthesis Example 2-3. Synthesis of <B-3>

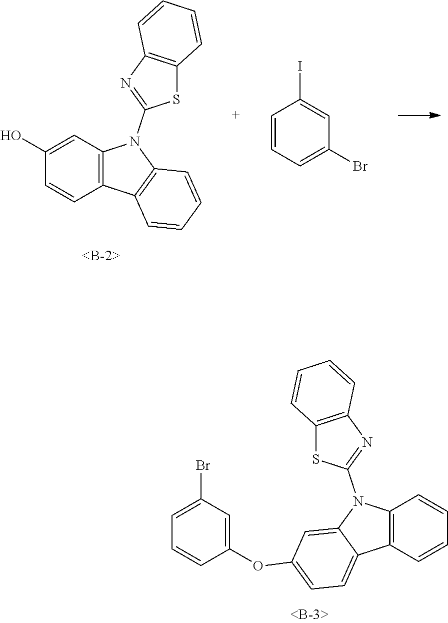 [SMILES: Oc1ccc2c3ccccc3n(-c3nc4ccccc4s3)c2c1 ; Brc1cccc(I)c1 ; Brc1cccc(Oc2ccc3c4ccccc4n(-c4nc5ccccc5s4)c3c2)c1]

In a 2-L round-bottom flask, <B-2> (105.7 g), 1-bromo-3-iodobenzene (104 g), copper(I) iodide (12.7 g), 2-picolinic acid (16.5 g), tripotassium phosphate (177.3 g), and DMSO (1057 mL) were stirred together for 17 hours at 130-140° C. under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <B-3>. (53.8 g, 34.2%)

### Synthesis Example 2-4. Synthesis of <B-4>

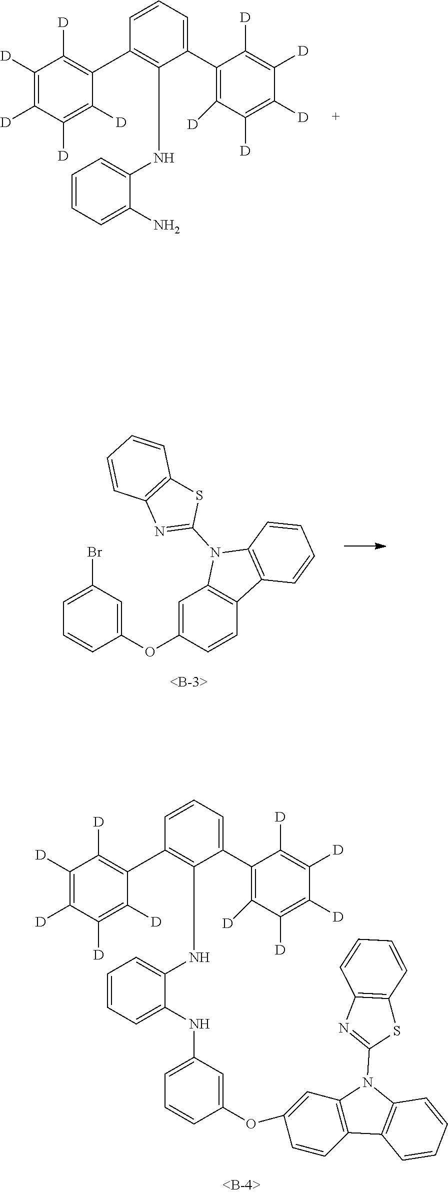 [SMILES: [2H]c1c([2H])c([2H])c(-c2cccc(-c3c([2H])c([2H])c([2H])c([2H])c3[2H])c2Nc2ccccc2N)c([2H])c1[2H] ; Brc1cccc(Oc2ccc3c4ccccc4n(-c4nc5ccccc5s4)c3c2)c1 ; [2H]c1c([2H])c([2H])c(-c2cccc(-c3c([2H])c([2H])c([2H])c([2H])c3[2H])c2Nc2ccccc2Nc2cccc(Oc3ccc4c5ccccc5n(-c5nc6ccccc6s5)c4c3)c2)c([2H])c1[2H]]

In a 500-mL round-bottom flask, N1-([1,1′:3′,1″-terphenyl]-2′-yl-2,2″,3,3″,4,4″,5,5″,6,6″-d10)benzene-1,2-diamine (11 g), <B-3> (15 g), tris(dibenzylideneacetone)dipalladium(0) (1.8 g), sodium Cert-butoxide (5.5 g), Xantphos (2.2 g), and toluene (110 mL) were stirred together for 17 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <B-4>. (15.7 g, 66.8%)

### Synthesis Example 2-5. Synthesis of <B-5>

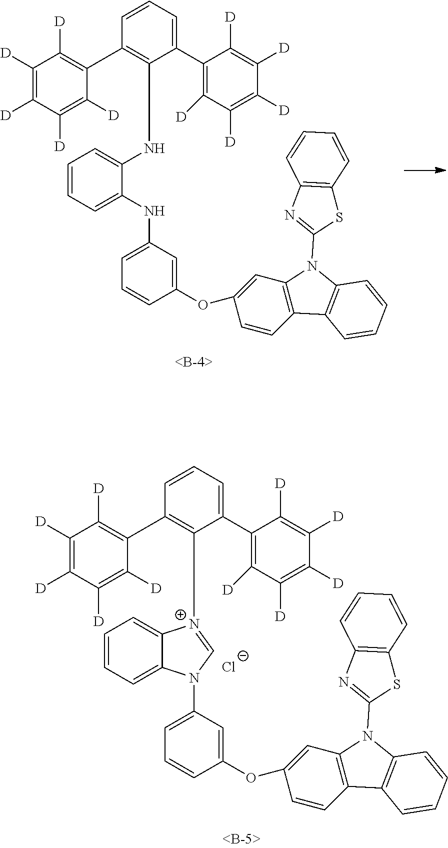 [SMILES: [2H]c1c([2H])c([2H])c(-c2cccc(-c3c([2H])c([2H])c([2H])c([2H])c3[2H])c2Nc2ccccc2Nc2cccc(Oc3ccc4c5ccccc5n(-c5nc6ccccc6s5)c4c3)c2)c([2H])c1[2H] ; [2H]c1c([2H])c([2H])c(-c2cccc(-c3c([2H])c([2H])c([2H])c([2H])c3[2H])c2-[n+]2cn(-c3cccc(Oc4ccc5c6ccccc6n(-c6nc7ccccc7s6)c5c4)c3)c3ccccc32)c([2H])c1[2H] ; [Cl-]]

In a 500 mL round-bottom flask, <B-4> (15.7 g), triethoxymethane (157.5 g), and hydrochloric acid (7.8 g) were stirred together for 4 hours under reflux. After completion of the reaction, the reaction mixture was concentrated in a vacuum to remove triethoxymethane. Isolation and purification through column chromatography followed by drying afforded <B-5>. (15.1 g, 90.5%)

### Synthesis Example 2-6. Synthesis of <B-6>

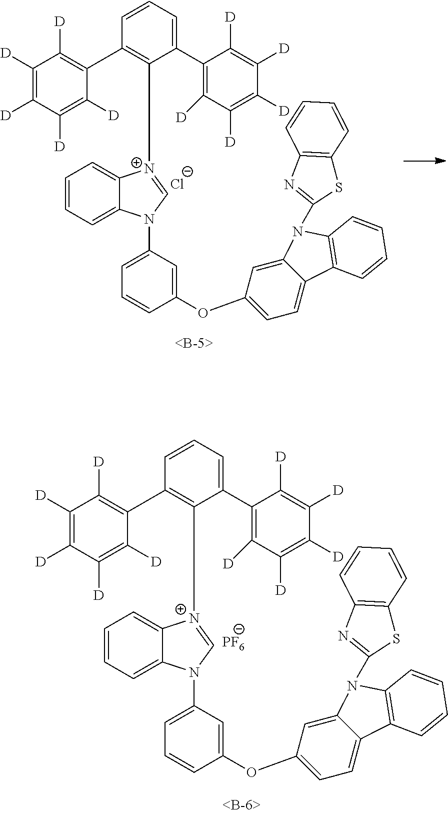

In a 2-L round-bottom flask, <B-5> (15.1 g) and methanol (300 mL) were stirred together at room temperature. A solution of ammonium hexafluorophosphate (4.7 g) in distilled water (300 mL) was dropwise added. After completion of the reaction, the reaction mixture was concentrated in a vacuum to remove methanol. The solid thus obtained was filtered, washed three times with distilled water, and dried to afford <B-6>. (17.6 g, 99.9%)

### Synthesis Example 2-7. Synthesis of [Compound 17]

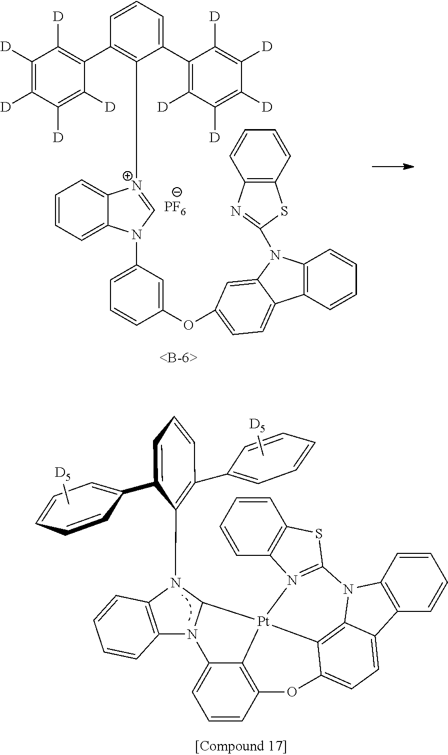

In a 500 mL round-bottom flask, <B-6> (17.6 g), dichloro(1,5-cyclooctadiene)platinum(II) (11.1 g), sodium acetate (4.9 g), and DMF (176 mL) were stirred together at 140° C. for 24 hours under reflux. After completion of the reaction, the reaction mixture was cooled to room temperature and poured to water. The precipitates thus formed were filtered, isolated and purified through column chromatography, and recyclized in dichloromethane and acetone to afford [Compound 17] (1.3 g, 6.8%).

### Synthesis Example 3: Synthesis of [Compound 18]

### Synthesis Example 3-1. Synthesis of <C-1>

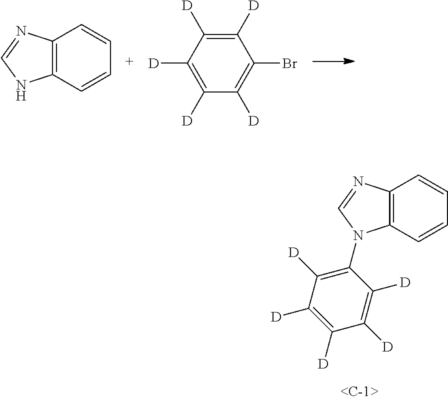

In a 3-L round-bottom flask, benzimidazole (100 g), bromobenzene-D5 (205.7 g), copper(I) iodide (16.1 g), L-proline (19.5 g), potassium carbonate (234 g), and DMSO (1 L) were stirred together for 17 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <C-1>. (164.2 g, 97.3%)

### Synthesis Example 3-2. Synthesis of <C-2>

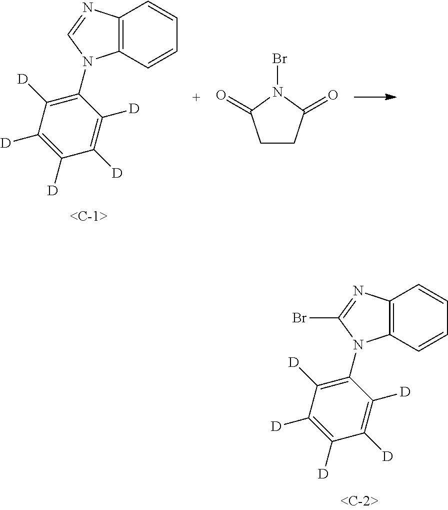 [SMILES: [2H]c1c([2H])c([2H])c(-n2cnc3ccccc32)c([2H])c1[2H] ; O=C1CCC(=O)N1Br ; [2H]c1c([2H])c([2H])c(-n2c(Br)nc3ccccc32)c([2H])c1[2H]]

In a 2-L round-bottom flask, <C-1> (50 g) and THF (750 mL) were cooled to −20° C. and then, drops of LiHMDS (1M) (752.8 mL) were added. After 30 minutes, a solution of N-bromosuccinimide (178.6 g) in THF (750 mL) was dropwise added. The resulting mixture was stirred at room temperature for 17 hours. The reaction was terminated with an aqueous ammonium chloride solution, followed by extraction with ethyl acetate, sodium bisulfite, water, and brine. The organic layer thus formed was isolated, dried with magnesium sulfate, and concentrated in a vacuum. Isolation and purification through column chromatography followed by drying afforded <C-2>. (41.4 g, 59.3%)

### Synthesis Example 3-3. Synthesis of <C-3>

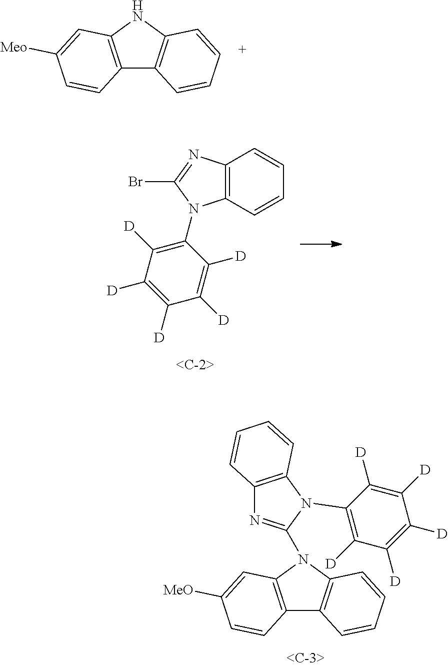

In a 2-L round-bottom flask, 2-methoxy-9H-carbazole (23.9 g), <C-2> (40.4 g), copper(I) chloride (0.1 g), 1-methyl-1H-imidazole (0.2 g), lithium Cert-butoxide (14.5 g), and toluene (367 mL) were stirred together for 17 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <C-3>. (27.2 g, 57%)

### Synthesis Example 3-4. Synthesis of <C-4>

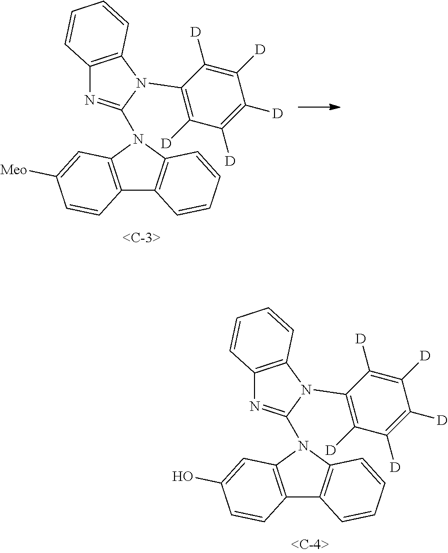

In a 1-L round-bottom flask, <C-3> (27 g), hydrobromic acid (55.8 mL), and acetic acid (94.5 mL) were stirred together for 17 hours under reflux. The reaction mixture was cooled to room temperature and then neutralized with drops of 1 N NaOH. The solid thus formed was stirred for 1 hour and filtered to afford <C-4>. (26.5 g, 99.9%)

### Synthesis Example 3-5. Synthesis of <C-5>

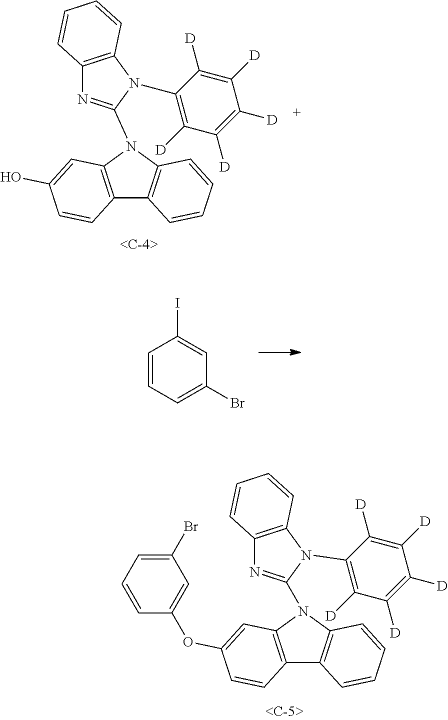 [SMILES: [2H]c1c([2H])c([2H])c(-n2c(-n3c4ccccc4c4ccc(O)cc43)nc3ccccc32)c([2H])c1[2H] ; Brc1cccc(I)c1 ; [2H]c1c([2H])c([2H])c(-n2c(-n3c4ccccc4c4ccc(Oc5cccc(Br)c5)cc43)nc3ccccc32)c([2H])c1[2H]]

In a 1-L round-bottom flask, <C-4> (26 g), 1-bromo-3-iodobenzene (23.2 g), copper(I) iodide (2.6 g), 2-picolinic acid (3.4 g), tripotassium phosphate (36.3 g), and DMSO (260 mL) were stirred together at 130-140° C. for 17 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <C-5>. (24.3 g, 66.4%)

### Synthesis Example 3-6. Synthesis of <C-6>

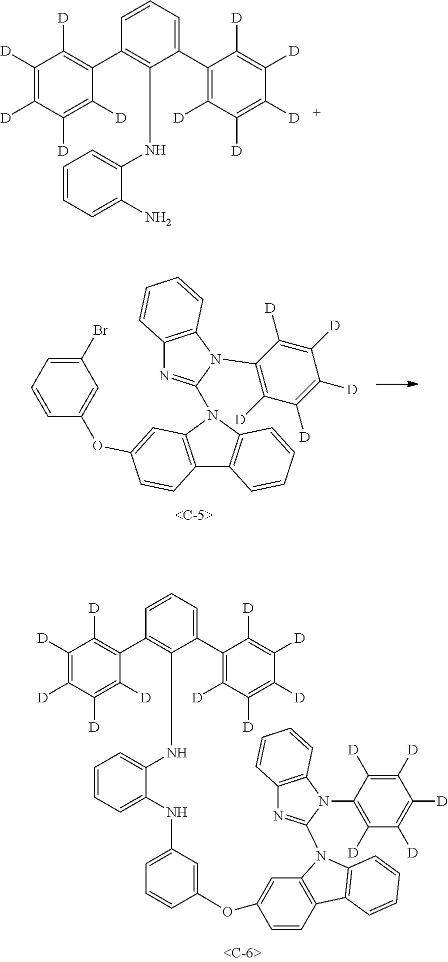 [SMILES: [2H]c1c([2H])c([2H])c(-c2cccc(-c3c([2H])c([2H])c([2H])c([2H])c3[2H])c2Nc2ccccc2N)c([2H])c1[2H] ; [2H]c1c([2H])c([2H])c(-n2c(-n3c4ccccc4c4ccc(Oc5cccc(Br)c5)cc43)nc3ccccc32)c([2H])c1[2H] ; [2H]c1c([2H])c([2H])c(-c2cccc(-c3c([2H])c([2H])c([2H])c([2H])c3[2H])c2Nc2ccccc2Nc2cccc(Oc3ccc4c5ccccc5n(-c5nc6ccccc6n5-c5c([2H])c([2H])c([2H])c([2H])c5[2H])c4c3)c2)c([2H])c1[2H]]

In a 1-L round-bottom flask, <C-6> (23.3 g), SPhos (1.8 g), N1-([1,1′:3′,1″-terphenyl]-2′-yl-2,2″,3,3″,4,4″,5,5″,6,6″-d10)benzene-1,2-diamine (12.6 g), tris(dibenzylideneacetone)dipalladium(0) (2 g), and toluene (110 mL) were stirred together for 17 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <C-6>. (20 g, 68.7%)

### Synthesis Example 3-7. Synthesis of <C-7>

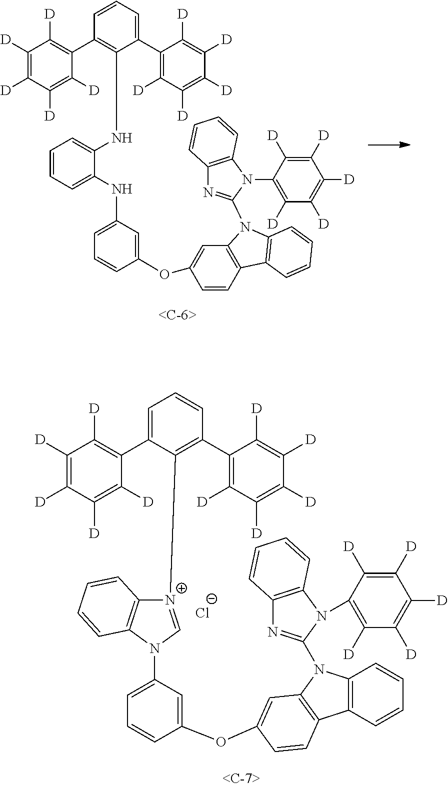 [SMILES: [2H]c1c([2H])c([2H])c(-c2cccc(-c3c([2H])c([2H])c([2H])c([2H])c3[2H])c2Nc2ccccc2Nc2cccc(Oc3ccc4c5ccccc5n(-c5nc6ccccc6n5-c5c([2H])c([2H])c([2H])c([2H])c5[2H])c4c3)c2)c([2H])c1[2H] ; [2H]c1c([2H])c([2H])c(-c2cccc(-c3c([2H])c([2H])c([2H])c([2H])c3[2H])c2-[n+]2cn(-c3cccc(Oc4ccc5c6ccccc6n(-c6nc7ccccc7n6-c6c([2H])c([2H])c([2H])c([2H])c6[2H])c5c4)c3)c3ccccc32)c([2H])c1[2H] ; [Cl-]]

In a 500 mL round-bottom flask, <C-6> (19.5 g), triethoxymethane (180 g), and hydrochloric acid (8.9 g) were stirred together for 4 hours under reflux. After completion of the reaction, the reaction mixture was concentrated in a vacuum to remove triethoxymethane. Isolation and purification through column chromatography followed by drying afforded <C-7>. (17.1 g, 82.9%)

### Synthesis Example 3-8. Synthesis of <C-8>

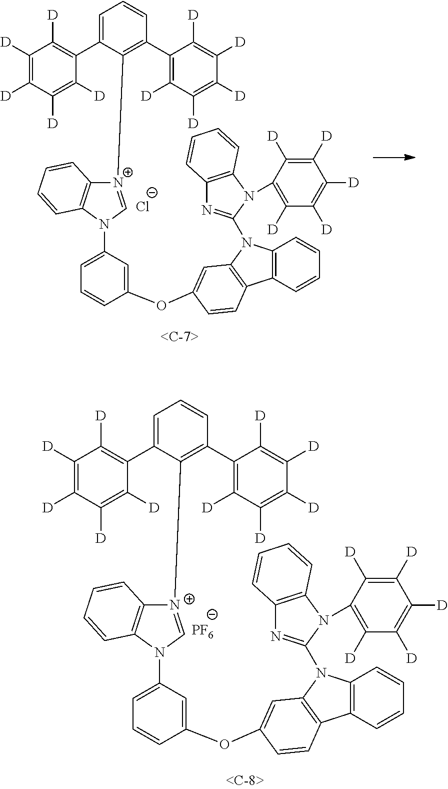

In a 2-L reactor, <C-7> (17.1 g) and methanol (300 mL) were stirred together at room temperature. A solution of ammonium hexafluorophosphate (4.9 g) in distilled water (300 mL) was then dropwise added. After completion of the reaction, the reaction mixture was concentrated in a vacuum to remove methanol. The solid thus formed was filtered, washed three times with distilled water, and dried to afford <C-8>. (17.8 g, 92.3%).

### Synthesis Example 3-9. Synthesis of [Compound 18]

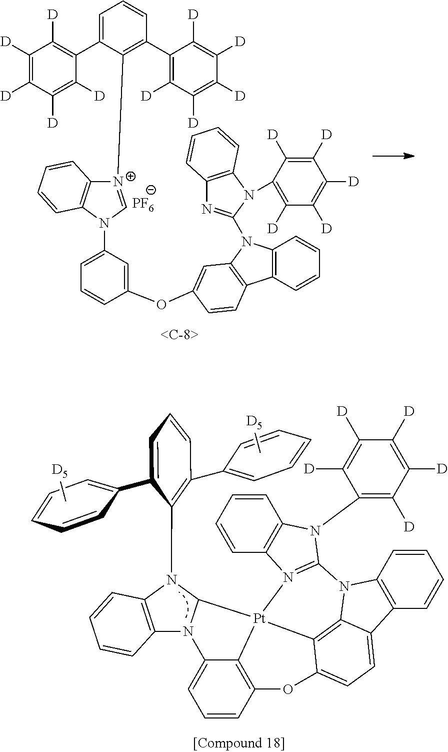

In a 500 mL round-bottom flask <C-8> (17.6 g), dichloro(1,5-cyclooctadiene)platinum(II) (10.3 g), sodium acetate (4.5 g), and DMF (176 mL) were stirred together at 140° C. for 24 hours under reflux. After completion of the reaction, the reaction mixture was cooled to room temperature and poured to water. The precipitates W thus formed were filtered, isolated and purified through column chromatography, and recyclized in dichloromethane and acetone to afford [Compound 18]. (4.3 g, 23.3%)

### Synthesis Example 4: Synthesis of [Compound 19]

### Synthesis Example 4-1. Synthesis of <D-1>

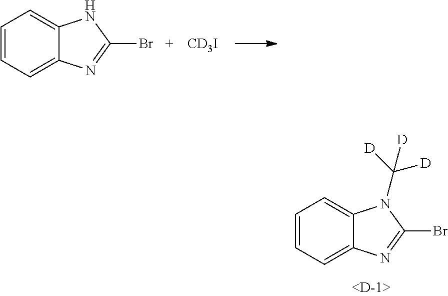

In a 1-L round-bottom flask, a solution of 2-bromo-1H-benzo[d]imidazole (50 g) in DMF (500 mL) was added at 0° C. with sodium hydride (60%) (18.2 g) and stirred for 15 minutes. Then, iodomethane-D3 (38.6 g) was added at 0° C. before stirring again for 1 hour. After completion of the reaction, water was added. The precipitates thus formed were filtered, washed three times with distilled water, and dried to afford <D-1>. (51.2 g, 94.3%)

### Synthesis Example 4-2. Synthesis of <D-2>

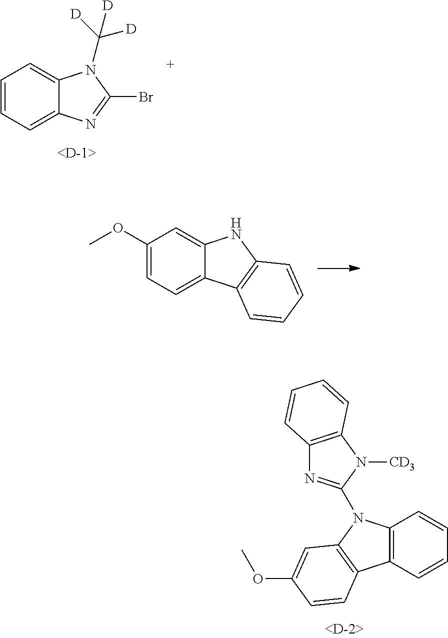 [SMILES: [2H]C([2H])([2H])n1c(Br)nc2ccccc21 ; COc1ccc2c(c1)[nH]c1ccccc12 ; [2H]C([2H])([2H])n1c(-n2c3ccccc3c3ccc(OC)cc32)nc2ccccc21]

In a 1-L round-bottom flask, <D-1> (51.2 g), 2-methoxy-9H-carbazole (56.6 g), copper(I) chloride (1.2 g), 1-methyl-1H-imidazole (0.98 g), lithium Cert-butoxide (57.4 g), and toluene (900 mL) were stirred together for 16 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation and purification through column chromatography followed by drying afforded <D-2>. (64.7 g, 81.8%)

### Synthesis Example 4-3. Synthesis of <D-3>

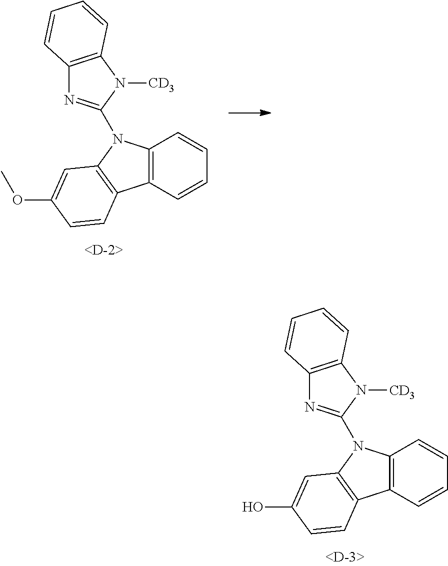 [SMILES: [2H]C([2H])([2H])n1c(-n2c3ccccc3c3ccc(OC)cc32)nc2ccccc21 ; [2H]C([2H])([2H])n1c(-n2c3ccccc3c3ccc(O)cc32)nc2ccccc21]

In a 1-L round-bottom flask, <D-2> (64.7 g), HBr (48% aqueous solution) (109 mL), and acetic acid (520 mL) were stirred together for 24 hours under reflux. After completion of the reaction, the reaction mixture was cooled to room temperature, poured to water, and neutralized with an aqueous sodium hydrogen carbonate solution.

The precipitates thus formed were filtered, isolated and purified through column chromatography, and dried to afford <D-3>. (42.5 g, 69.6%).

### Synthesis Example 4-4. Synthesis of <D-4>

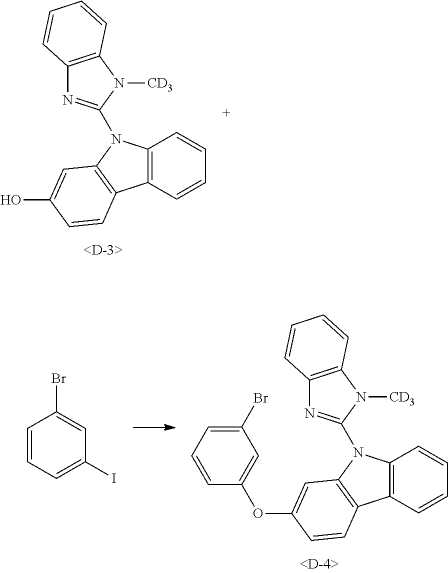 [SMILES: [2H]C([2H])([2H])n1c(-n2c3ccccc3c3ccc(O)cc32)nc2ccccc21 ; Brc1cccc(I)c1 ; [2H]C([2H])([2H])n1c(-n2c3ccccc3c3ccc(Oc4cccc(Br)c4)cc32)nc2ccccc21]

In a 1-L round-bottom flask, <D-3> (42.3 g), 1-bromo-3-iodobenzene (56.7 g), copper(I) chloride (2.6 g), 2-picolinic acid (6.58 g), tripotassium phosphate (70.9 g), and DMSO (420 mL) were stirred together for 16 hours at 130° C. After completion of the reaction, the reaction mixture was cooled to room temperature and then subjected to extraction with ethyl acetate and water. The organic layer thus formed was isolated, dried with magnesium sulfate, and concentrated in a vacuum. Isolation and purification through column chromatography followed by drying afforded <D-4>. (41.5 g, 65.8%)

### Synthesis Example 4-5. Synthesis of <D-5>

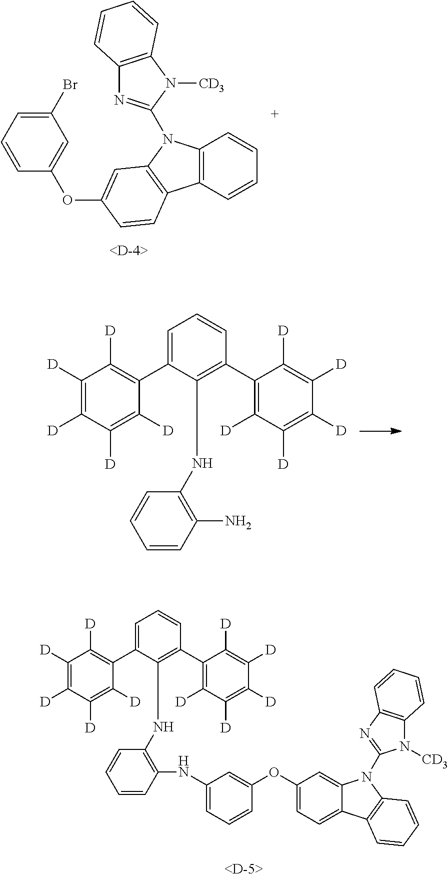 [SMILES: [2H]C([2H])([2H])n1c(-n2c3ccccc3c3ccc(Oc4cccc(Br)c4)cc32)nc2ccccc21 ; [2H]c1c([2H])c([2H])c(-c2cccc(-c3c([2H])c([2H])c([2H])c([2H])c3[2H])c2Nc2ccccc2N)c([2H])c1[2H] ; [2H]c1c([2H])c([2H])c(-c2cccc(-c3c([2H])c([2H])c([2H])c([2H])c3[2H])c2Nc2ccccc2Nc2cccc(Oc3ccc4c5ccccc5n(-c5nc6ccccc6n5C([2H])([2H])[2H])c4c3)c2)c([2H])c1[2H]]

In a 1-L round-bottom flask, <D-4> (41.3 g), SPhos (4.3 g), N1-([1,1′:3′,1″-terphenyl]-2′-yl-2,2″,3,3″,4,4″,5,5″,6,6″-d10)benzene-1,2-diamine (31.8 g), sodium tert-butoxide (15.1 g), tris(dibenzylideneacetone)dipalladium(0) (4.81 g), and toluene (400 mL) were stirred together for 16 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <D-5>. (48.9 g, 75.8%)

### Synthesis Example 4-6. Synthesis of <D-6>

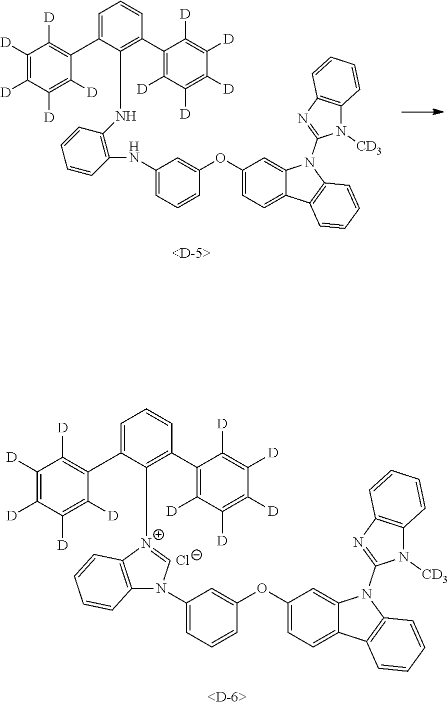 [SMILES: [2H]c1c([2H])c([2H])c(-c2cccc(-c3c([2H])c([2H])c([2H])c([2H])c3[2H])c2Nc2ccccc2Nc2cccc(Oc3ccc4c5ccccc5n(-c5nc6ccccc6n5C([2H])([2H])[2H])c4c3)c2)c([2H])c1[2H] ; [2H]c1c([2H])c([2H])c(-c2cccc(-c3c([2H])c([2H])c([2H])c([2H])c3[2H])c2-[n+]2cn(-c3cccc(Oc4ccc5c6ccccc6n(-c6nc7ccccc7n6C([2H])([2H])[2H])c5c4)c3)c3ccccc32)c([2H])c1[2H] ; [Cl-]]

In a 1 L round-bottom flask, <D-5> (48.9 g), triethoxymethane (491.7 g), and hydrochloric acid (4.9 mL) were stirred together for hours under reflux. After completion of the reaction, the reaction mixture was cooled to room temperature and concentrated in a vacuum. Isolation and purification through column chromatography followed by drying afforded <D-6>. (23.8 g, 45.8%)

### Synthesis Example 4-7. Synthesis of <D-7>

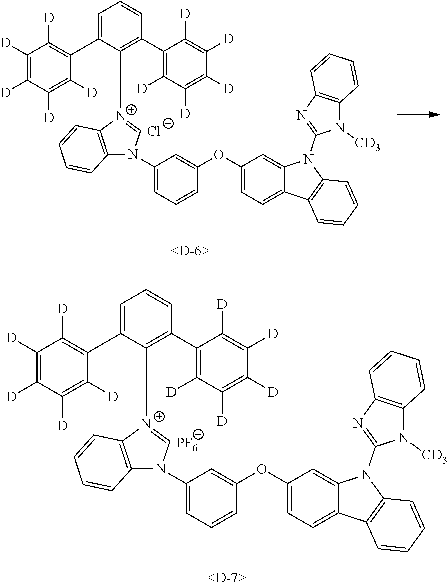

In a 1-L round-bottom flask, <D-6> (12 g) was completely dissolved in methanol (160 mL). A solution of ammonium hexafluorophosphate (3.7 g) in distilled water (120 mL) was then dropwise added. After completion of the reaction, the reaction mixture was concentrated in a vacuum to remove methanol. The solid thus formed was filtered, washed three times with distilled water, and dried to afford <D-7>. (12.8 g, 93.5%)

### Synthesis Example 4-8. Synthesis of [Compound 19]

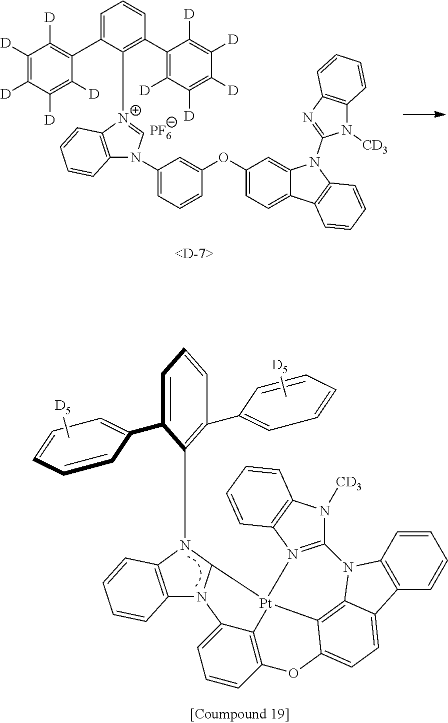

In a 500-mL round-bottom flask, <D-7> (12.8 g), sodium acetate (3.5 g), dichloro(1,5-cyclooctadiene)platinum(II) (8 g), and DMF (128 mL) were stirred together for 24 hours under reflux. After completion of the reaction, the reaction mixture was cooled to room temperature and poured to water. The precipitates thus formed were filtered, isolated and purified through column chromatography, and recyclized in dichloromethane and acetone to afford [Compound 19]. (3.3 g, 24.5%)

### SYNTHESIS EXAMPLE 5: Synthesis of [Compound 28]

### Synthesis Example 5-1. Synthesis of <E-1>

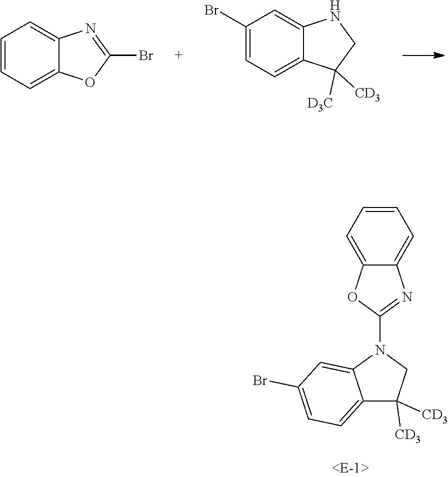 [SMILES: Brc1nc2ccccc2o1 ; [2H]C([2H])([2H])C1(C([2H])([2H])[2H])CNc2cc(Br)ccc21 ; [2H]C([2H])([2H])C1(C([2H])([2H])[2H])CN(c2nc3ccccc3o2)c2cc(Br)ccc21]

In a 1-L round-bottom flask, 6-bromo-3,3-bis(methyl-d3)indoline (25 g), 2-bromo-1,3-benzoxazole (27.7 g), copper(I) iodide (0.2 g), 1-methyl-1H-imidazole (0.2 g), Lithium Cert-butoxide (12.9 g), and toluene (125 mL) were stirred together for 17 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <E-1>. (23 g, 61.2%)

### Synthesis Example 5-2. Synthesis of <E-2>

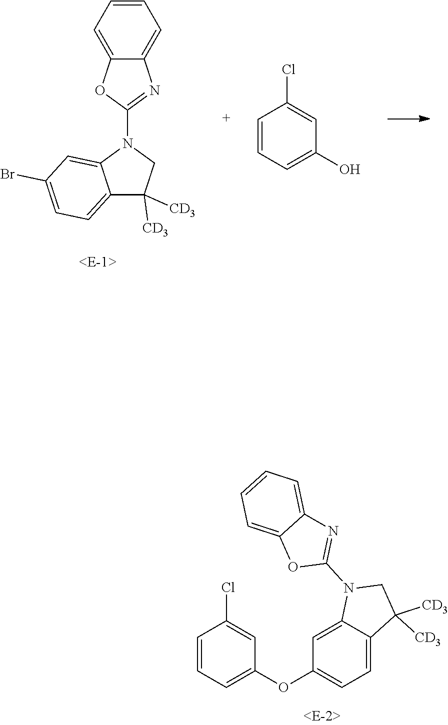 [SMILES: [2H]C([2H])([2H])C1(C([2H])([2H])[2H])CN(c2nc3ccccc3o2)c2cc(Br)ccc21 ; Oc1cccc(Cl)c1 ; [2H]C([2H])([2H])C1(C([2H])([2H])[2H])CN(c2nc3ccccc3o2)c2cc(Oc3cccc(Cl)c3)ccc21]

In a 1-L round-bottom flask, <E-1> (23 g), 3-chlorophenol (8.5 g), copper(I) iodide (2.5 g), 2-picolinic acid (3.2 g), tripotassium phosphate (34.9 g), and DMSO (230 mL) were stirred together for 17 hours at 130-140° C. under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation through column chromatography afforded <E-2>. (17 g, 65%)

### Synthesis Example 5-3. Synthesis of <E-3>

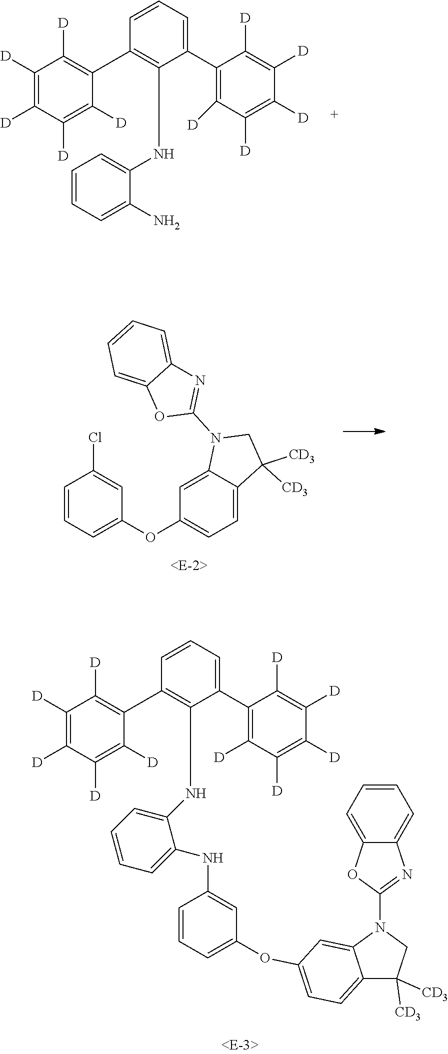 [SMILES: [2H]c1c([2H])c([2H])c(-c2cccc(-c3c([2H])c([2H])c([2H])c([2H])c3[2H])c2Nc2ccccc2N)c([2H])c1[2H] ; [2H]C([2H])([2H])C1(C([2H])([2H])[2H])CN(c2nc3ccccc3o2)c2cc(Oc3cccc(Cl)c3)ccc21 ; [2H]c1c([2H])c([2H])c(-c2cccc(-c3c([2H])c([2H])c([2H])c([2H])c3[2H])c2Nc2ccccc2Nc2cccc(Oc3ccc4c(c3)N(c3nc5ccccc5o3)CC4(C([2H])([2H])[2H])C([2H])([2H])[2H])c2)c([2H])c1[2H]]

In a 1-L round-bottom flask, <E-2> (16.7 g), Xantphos (2.4 g), N1-([1,1′:3′,1″-terphenyl]-2′-yl-2,2″,3,3″,4,4″,5,5″,6,6″-d10)benzene-1,2-diamine (12.1 g), tris(dibenzylideneacetone)dipalladium(0) (1.9 g), sodium tert-butoxide (6.1 g), and toluene (120 mL) were stirred together for 17 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation and purification through column chromatography followed by drying afforded <E-3>. (12 g, 40.4%)

### Synthesis Example 5-4. Synthesis of <E-4>

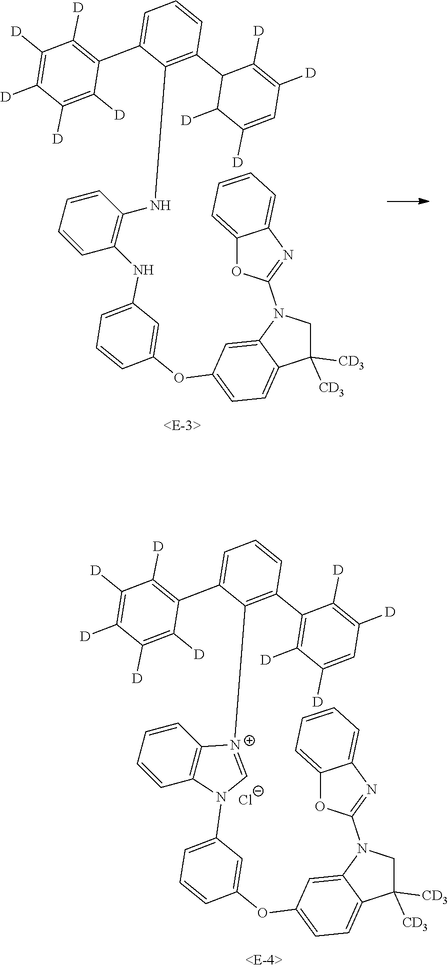 [SMILES: [2H]C1=CC([2H])=C([2H])C(c2cccc(-c3c([2H])c([2H])c([2H])c([2H])c3[2H])c2Nc2ccccc2Nc2cccc(Oc3ccc4c(c3)N(c3nc5ccccc5o3)CC4(C([2H])([2H])[2H])C([2H])([2H])[2H])c2)C1[2H] ; [2H]c1cc([2H])c([2H])c(-c2cccc(-c3c([2H])c([2H])c([2H])c([2H])c3[2H])c2-[n+]2cn(-c3cccc(Oc4ccc5c(c4)N(c4nc6ccccc6o4)CC5(C([2H])([2H])[2H])C([2H])([2H])[2H])c3)c3ccccc32)c1[2H] ; [Cl-]]

In a 500-mL round-bottom flask, <E-3> (12 g), triethoxymethane (125.8 g), and hydrochloric acid (6.2 g) were stirred together for 3 hours under reflux. After completion of the reaction, the reaction mixture was concentrated in a vacuum to remove triethoxymethane.

Isolation and purification through column chromatography followed by drying afforded <E-4>. (12.5 g, 97.7%)

### Synthesis Example 5-5. Synthesis of <E-5>

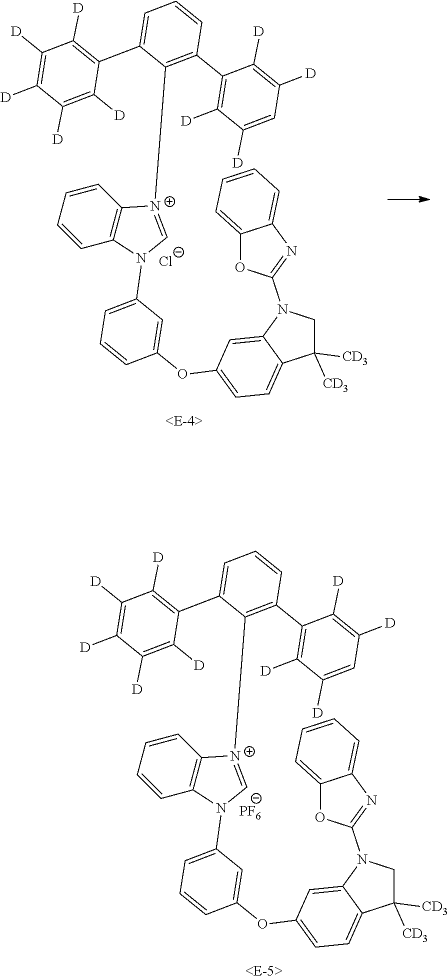

In a 1-L round-bottom flask, <E-4> (12.5 g) was completely dissolved in methanol (250 mL). A solution of ammonium hexafluorophosphate (4.1 g) in distilled water (250 mL) was then dropwise added. After completion of the reaction, the reaction mixture was concentrated in a vacuum to remove methanol. The solid thus formed was filtered, washed three times with distilled water, and dried to afford <E-5>. (13.5 g, 94.4%)

### Synthesis Example 5-6. Synthesis of [Compound 28]

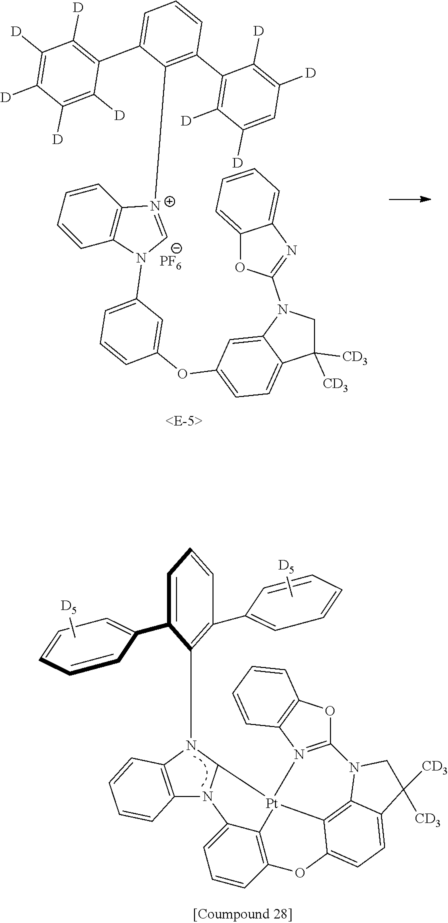

In a 500-mL round-bottom flask, <E-5> (12.3 g), dichloro(1,5-cyclooctadiene)platinum(II) (8 g), sodium acetate (3.5 g), and DMF (176 mL) were stirred together at 140° C. for 24 hours under reflux. After completion of the reaction, the reaction mixture was cooled to room temperature and poured to water. The precipitates thus formed were filtered, isolated and purified through column chromatography, and recyclized in dichloromethane and acetone to afford [Compound 28]. (1.3 g, 10%)

### Syntheis Example 6: Synthesis of [Compound 29]

### Synthesis Example 6-1. Synthesis of <F-1>

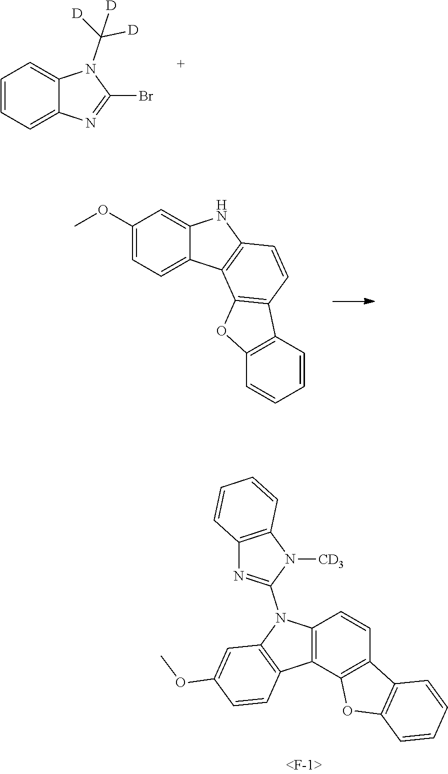 [SMILES: [2H]C([2H])([2H])n1c(Br)nc2ccccc21 ; COc1ccc2c(c1)[nH]c1ccc3c4ccccc4oc3c12 ; [2H]C([2H])([2H])n1c(-n2c3cc(OC)ccc3c3c4oc5ccccc5c4ccc32)nc2ccccc21]

In a 1-L round-bottom flask, <F-1> (25 g), 3-methoxy-5H-benzofuro[3,2-c]carbazole (40.3 g), copper(I) chloride (0.58 g), 1-methyl-1H-imidazole (0.48 g), lithium Cert-butoxide (28 g), and toluene (450 mL) were stirred together for 16 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation and purification through column chromatography followed by drying afforded <F-1>. (19.7 g, 40.1%)

### Synthesis Example 6-2. Synthesis of <F-2>

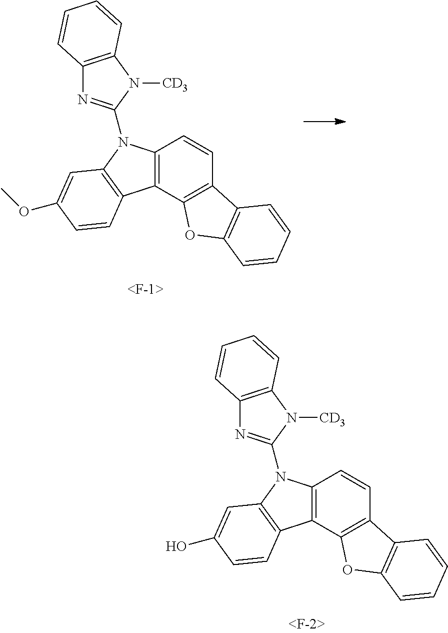 [SMILES: [2H]C([2H])([2H])n1c(-n2c3cc(OC)ccc3c3c4oc5ccccc5c4ccc32)nc2ccccc21 ; [2H]C([2H])([2H])n1c(-n2c3cc(O)ccc3c3c4oc5ccccc5c4ccc32)nc2ccccc21]

In a 1-L round-bottom flask, <F-1> (19.7 g), HBr (48% aqueous solution) (26.5 mL), and acetic acid (157 mL) were stirred together for 24 hours under reflux. After completion of the reaction, the reaction mixture was cooled to room temperature, poured to water, and neutralized with an aqueous sodium hydrogen carbonate solution. The precipitates thus formed were filtered, isolated and purified through column chromatography, and dried to afford <F-2>. (17.8 g, 93.6%).

### Synthesis Example 6-3. Synthesis of <F-3>

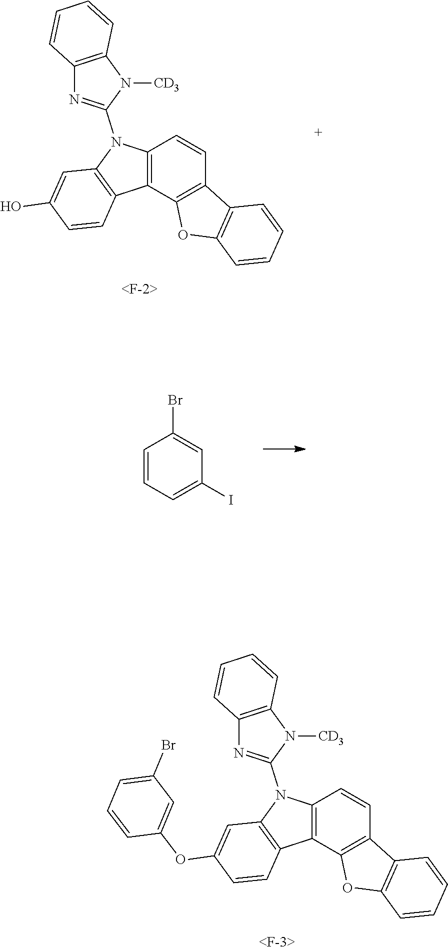 [SMILES: [2H]C([2H])([2H])n1c(-n2c3cc(O)ccc3c3c4oc5ccccc5c4ccc32)nc2ccccc21 ; Brc1cccc(I)c1 ; [2H]C([2H])([2H])n1c(-n2c3cc(Oc4cccc(Br)c4)ccc3c3c4oc5ccccc5c4ccc32)nc2ccccc21]

In a 1-L round-bottom flask, <F-2> (17.7 g), 1-bromo-3-(38.3 g), copper(I) iodide (1.6 g), 2-picolinic acid (2.1 g), tripotassium phosphate (23.1 g), and DMSO (180 mL) were stirred together for 16 hours at 130° C. After completion of the reaction, the reaction mixture was cooled to room temperature and then subjected to extraction with ethyl acetate and water. The organic layer thus formed was isolated, dried with magnesium sulfate, and concentrated in a vacuum. Isolation and purification through column chromatography followed by afforded <F-3>. (15.2 g, 62.3%)

### Synthesis Example 6-4. Synthesis of <F-4>

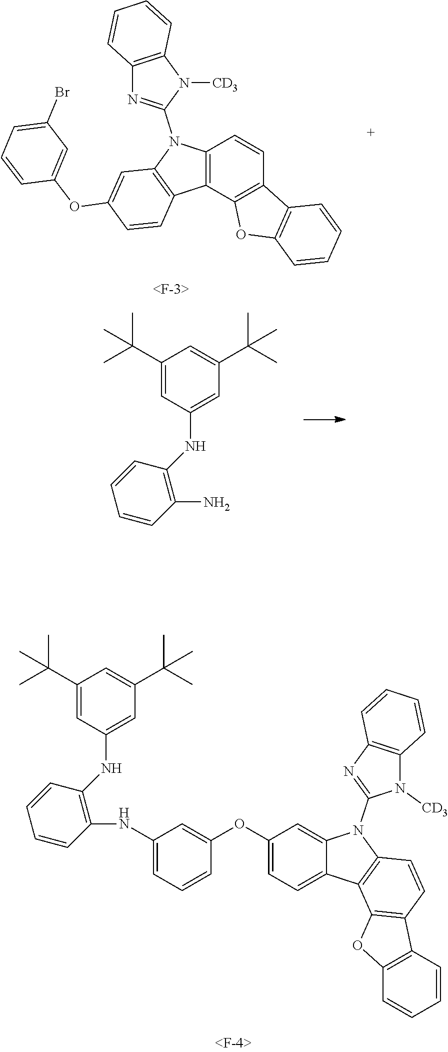 [SMILES: [2H]C([2H])([2H])n1c(-n2c3cc(Oc4cccc(Br)c4)ccc3c3c4oc5ccccc5c4ccc32)nc2ccccc21 ; CC(C)(C)c1cc(Nc2ccccc2N)cc(C(C)(C)C)c1 ; [2H]C([2H])([2H])n1c(-n2c3cc(Oc4cccc(Nc5ccccc5Nc5cc(C(C)(C)C)cc(C(C)(C)C)c5)c4)ccc3c3c4oc5ccccc5c4ccc32)nc2ccccc21]

In a 1-L round-bottom flask, <F-3> (15.1 g), N¹-(3,5-di-tert-butylphenyl)benzene-1,2-diamine (8.4 g), tris(dibenzylideneacetone)dipalladium(0) (1.4 g), Xantphos (1.9 g), sodium Cert-butoxide (4.6 g), and toluene (150 mL) were stirred together for 16 hours under reflux. After completion of the reaction, the reaction mixture was cooled to room temperature and then subjected to extraction with ethyl acetate and water. The organic layer thus formed was isolated, dried with magnesium sulfate, and concentrated in a vacuum. Isolation and purification through column chromatography followed by drying afforded <F-4>. (17.9 g, 85.6%)

### Synthesis Example 6-5. Synthesis of <F-5>

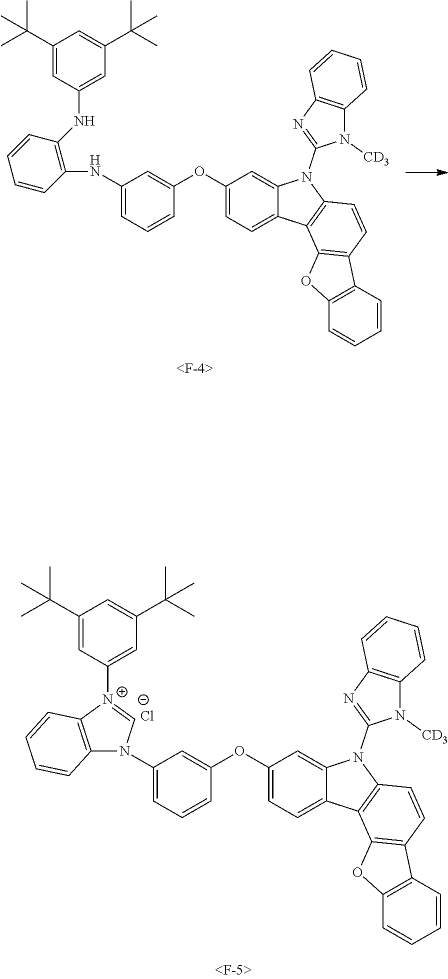 [SMILES: [2H]C([2H])([2H])n1c(-n2c3cc(Oc4cccc(Nc5ccccc5Nc5cc(C(C)(C)C)cc(C(C)(C)C)c5)c4)ccc3c3c4oc5ccccc5c4ccc32)nc2ccccc21 ; [2H]C([2H])([2H])n1c(-n2c3cc(Oc4cccc(-n5c[n+](-c6cc(C(C)(C)C)cc(C(C)(C)C)c6)c6ccccc65)c4)ccc3c3c4oc5ccccc5c4ccc32)nc2ccccc21 ; [Cl-]]

In a 1-L round-bottom flask, <F-4> (17.9 g), triethoxymethane (170.7 g), and hydrochloric acid (1.8 mL) were stirred together for 4 hours under reflux. After completion of the reaction, the reaction mixture was cooled to room temperature and concentrated in a vacuum. Isolation and purification through column chromatography followed by drying afforded <F-5>. (16.7 g, 88.3%)

### Synthesis Example 6-6. Synthesis of <F-6>

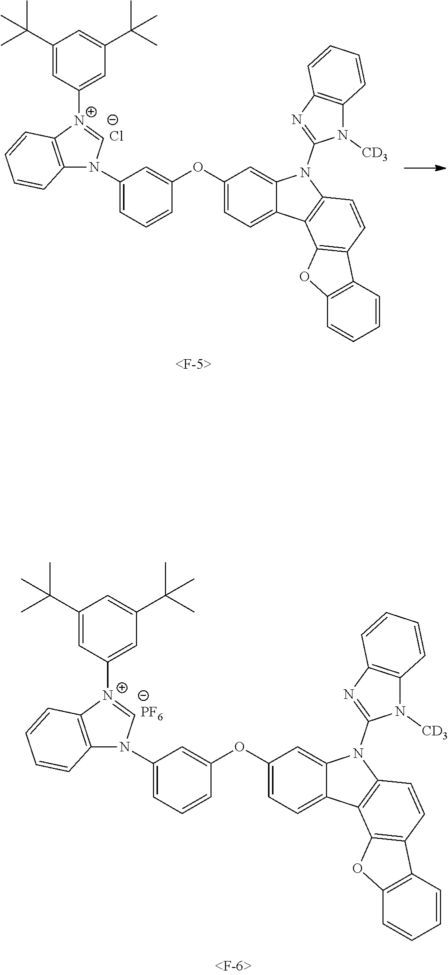

In a 1-L round-bottom flask, <F-5> (16.3 g) was completely dissolved in methanol (220 mL). A solution of ammonium hexafluorophosphate (4.8 g) in distilled water (160 mL) was then dropwise added. After completion of the reaction, the reaction mixture was cooled to room temperature and concentrated in a vacuum to remove methanol. The solid thus formed was filtered, washed three times with distilled water, and dried to afford <F-6>. (17.4 g, 94.2%)

### Synthesis Example 6-7. Synthesis of [Compound 29]

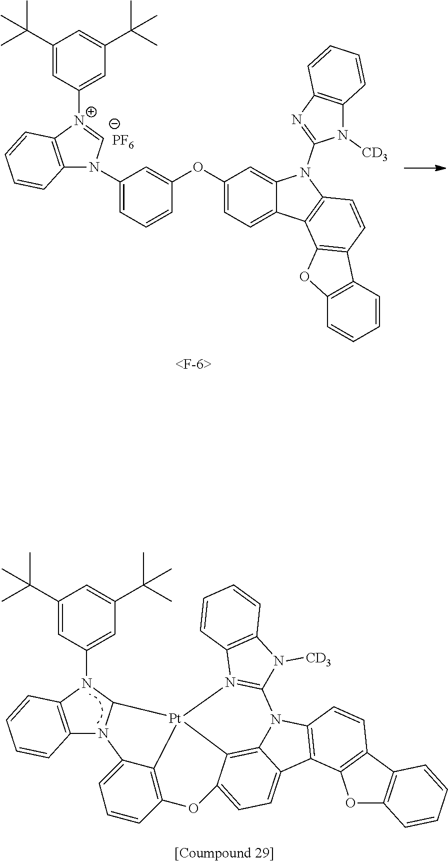

In a 500-mL round-bottom flask, <F-6> (17.4 g), sodium acetate (4.6 g), dichloro(1,5-cyclooctadiene)platinum(II) (10.6 g), and DMF (174 mL) were stirred together for 24 hours under reflux. After completion of the reaction, the reaction mixture was cooled to room temperature and poured to water. The precipitates thus formed were filtered, isolated and purified through column chromatography, and recyclized in dichloromethane and acetone to afford [Compound 29]. (6.7 g, 36.2%)

### Evaluation Example 1: Evaluation for Maximum Photoluminescence Wavelength (PL Max)

Each of the following compounds according to the present disclosure was diluted at a concentration of 5.0×10⁻⁶ moles in toluene (10 mL) and measured at room temperature for a photoluminescence spectrum, using a spectrofluorometer equipped with a xenon lamp. The same experiment was carried out for comparative compound 1. The results are summarized in Table 1, below.

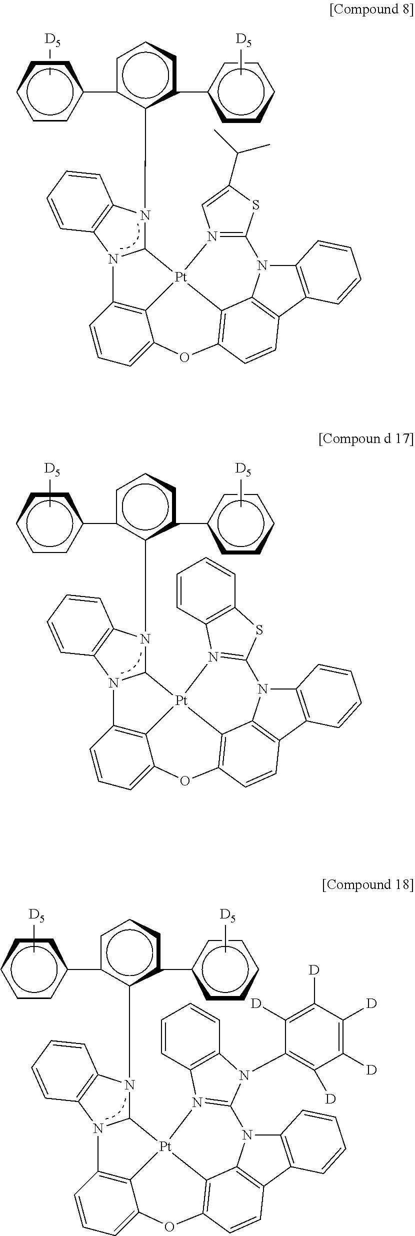

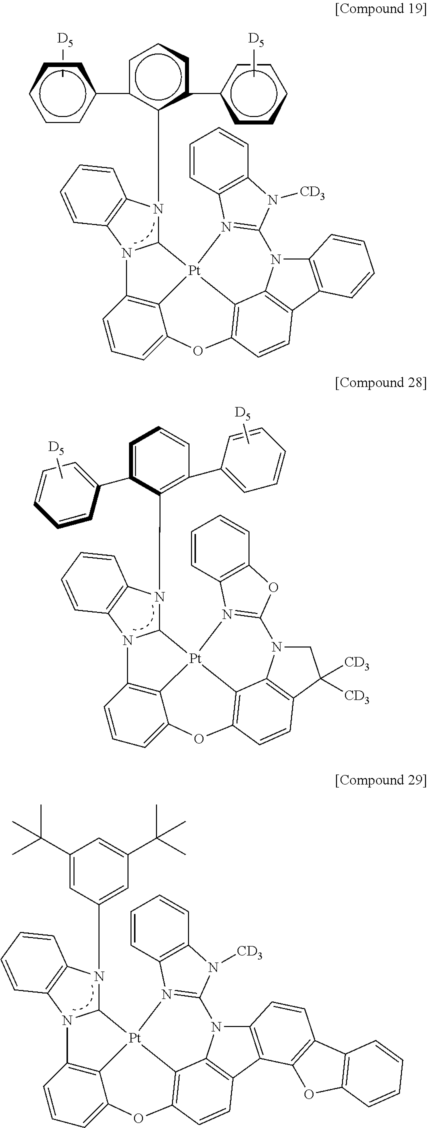

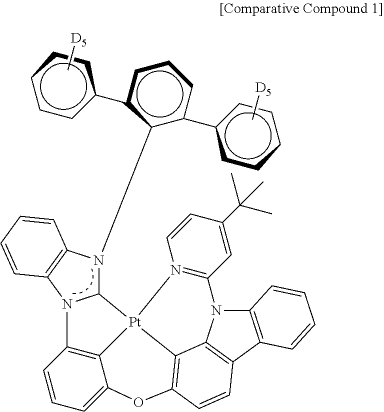

TABLE 1

| | | PL max |
|---|---|---|
| | Compound | (nm) |
| Ex. 1 | Compound 8 | 456 |
| Ex. 2 | Compound 17 | 459 |
| Ex. 3 | Compound 18 | 451 |
| Ex. 4 | Compound 19 | 451 |
| Ex. 5 | Compound 28 | 451 |
| Ex. 6 | Compound 29 | 458 |
| C. Ex. 1 | Comparative Compound 1 | 460 |

As understood from the data of Table 1, the organometallic compounds according to the present disclosure exhibited blueshift as their PL max peaks appeared at shorter wavelengths, compared to the conventional compounds. The results indicate that given as a dopant in a light-emitting layer of an organic light-emitting diode, the compounds of the present disclosure can ensure blue photoluminescence with improved color purity.

### Evaluation Example 2: Molecular Energy Level Evaluation

In order to obtain information about molecular energy levels of the compounds prepared according to the present disclosure, each of the compounds was measured for HOMO energy level and LUMO energy level by cyclic voltammetry and for T₁ energy level by low-temperature PL. The results are summarized in Table 2, below.

TABLE 2

| | Compound | HOMO (eV) | LUMO (eV) | T₁ (eV) |
|---|---|---|---|---|
| Ex. 1 | Compound8 | −5.763 | −2.893 | 2.774 |
| Ex. 2 | Compound 17 | −5.778 | −2.874 | 2.768 |
| Ex. 3 | Compound 18 | −5.729 | −2.852 | 2.793 |
| Ex. 4 | Compound 19 | −5.683 | −2.779 | 2.774 |
| Ex. 5 | Compound 28 | −5.648 | −2.771 | 2.737 |
| Ex. 6 | Compound 29 | −5.760 | −2.870 | 2.756 |

As can be seen in Table 2, the organometallic compounds of the present disclosure are observed to have electric properties suitable for use as dopants in light-emitting layers of organic light-emitting diodes.

1. The present disclosure aims to provide an organometallic compound represented by the following Chemical Formula 1: 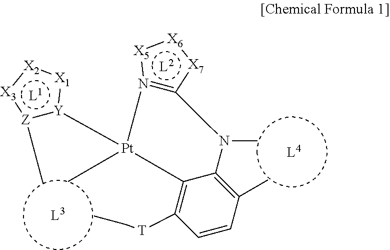
wherein,
L¹ is selected from a substituted or unsubstituted 5-membered heteroaromatic ring, a substituted or unsubstituted 5-membered heteroaliphatic ring, and a substituted or unsubstituted 5-membered N-heterocyclic carbene,
Y is C or N,
Z is C or N,
X₁ to X₃, which are same or different, are each independently any one selected from CR₁R₂, CR₃, NR₄, N, O, S, and Se,
wherein when two or more of X1 to X3 are CR1R2, the plural CR1R2 radicals may be same or different, when two or more of X1 to X3 are CR3, the plural CR3 radicals may be same or different, and when two or more of X1 to X3 are NR4, the plural NR4 radicals may be same or different,
R₁ to R₄, which are same or different, are each independently any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, a substituted or unsubstituted aliphatic hydrocarbon ring-fused heteroaryl of 5 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted amine of 0 to 30 carbon atoms, a substituted or unsubstituted silyl of 0 to 30 carbon atoms, a substituted or unsubstituted germyl of 0 to 30 carbon atoms, a nitro, a cyano, and a halogen, and
any adjacent two substituents of X₁ to X₃ can be optionally linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, or a substituted or unsubstituted heteroaliphatic ring of 3 to 30 carbon atoms,
L² is selected from a substituted or unsubstituted 5-membered heteroaromatic ring, and a substituted or unsubstituted 5-membered heteroaliphatic ring,
X₅ to X₇, which are same or different, are each independently any one selected from CR₅R₆, CR₇, NR₈, N, O, and S,
wherein when two or more of X₅ to X₇ are CR₅R₆, the plural CR₅R₆ radicals may be same or different, when two or more of X₅ to X₇ are CR₇, the plural CR₇ radicals may be same or different, and when two or more of X₅ to X₇ are NR₈, the plural NR₈ radicals may be same or different,
R₅ to R₈, which are same or different, are each independently as defined above for R₁ to R₄, respectively, and
any adjacent two substituents of X₅ to X₇ can be optionally linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, or a substituted or unsubstituted heteroaliphatic ring of 3 to 30 carbon atoms,
L³ and L⁴, which are same or different, are each independently selected from a substituted or unsubstituted aromatic hydrocarbon ring of 6 to 50 carbon atoms, a substituted or unsubstituted aliphatic hydrocarbon ring of 5 to 50 carbon atoms, a substituted or unsubstituted fused ring of 7 to 50 carbon atoms with an aromatic hydrocarbon ring and an aliphatic hydrocarbon ring fused to each other, a substituted or unsubstituted heteroaromatic ring of 2 to 50 carbon atoms, and a substituted or unsubstituted fused ring of 6 to carbon atoms with an heteroaromatic ring and an aliphatic hydrocarbon ring fused to each other,
wherein L⁴ can be bonded to at least adjacent one of R₅ to R₈ in X₇ to form an additional condensed ring,
T is a linker selected from CR₉R₁₀, SiR₁₁R₁₂, NR₁₃, BR₁₄, PRᵢₛ, R₁₆P═O, GeR₁₇R₁₈, O, and S,
wherein R₉ to R₁₈, which are same or different, are each independently as defined above for R₁ to R₄, respectively,
wherein the term “substituted” in the expression “substituted or unsubstituted” used for the compound of Chemical Formula 1 means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, cycloalkyl of 3 to 30 carbon atoms, an alkenyl of 2 to 24, an alkynyl of 2 to 24 carbon atoms, a heteroalkyl of 1 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an alkoxy of 1 to 24 carbon atoms, an amine of 1 to 24 carbon atoms, a silyl of 1 to 24 carbon atoms, a germyl of 1 to 24 carbon atoms, an aryloxy of 6 to 24 carbon atoms, and an arythionyl of 6 to 24 carbon atoms.

2. The organometallic compound of claim 1, wherein the L¹ is a substituted or unsubstituted 5-membered N-heterocyclic carbene.

3. The organometallic compound of claim 1, wherein
L¹ in Chemical Formula 1 may have a structure represented by any one selected from the following Structural Formulas 1 to 4: 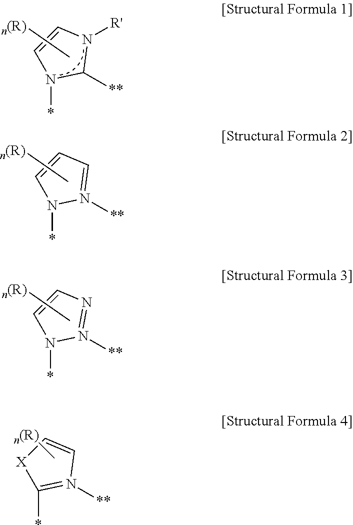
wherein,
R and R′, which are same or different, are each independently any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, and a substituted or unsubstituted aliphatic hydrocarbon ring-fused heteroaryl of 5 to 30 carbon atoms,
n is an integer of 1 to 3 wherein when n is 2 or higher, the corresponding R's are same or different and the adjacent R's can be linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic hydrocarbon ring of to 30 carbon atoms, or a substituted or unsubstituted heteroaliphatic ring of 3 to 30 carbon atoms,
“-*” stands for a single bond to the L³ ring moiety, and “-**” stands for a bond to the platinum (Pt) atom, and
X in Structural Formula 4 is N, O, or S.

4. The organometallic compound of claim 3, wherein the L¹ has any one selected from the structures represented by the following Structural Formulas 5 to 11: 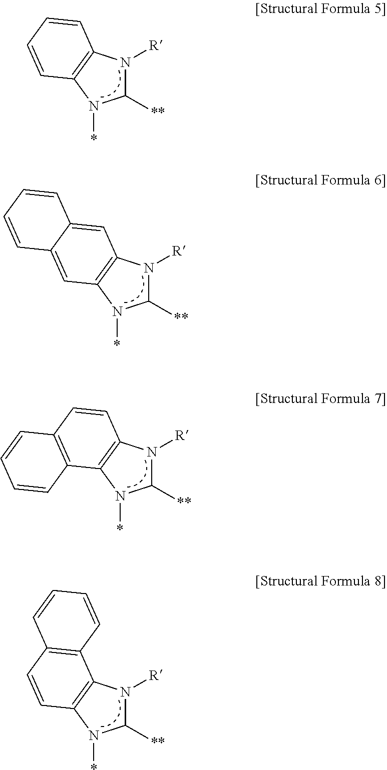 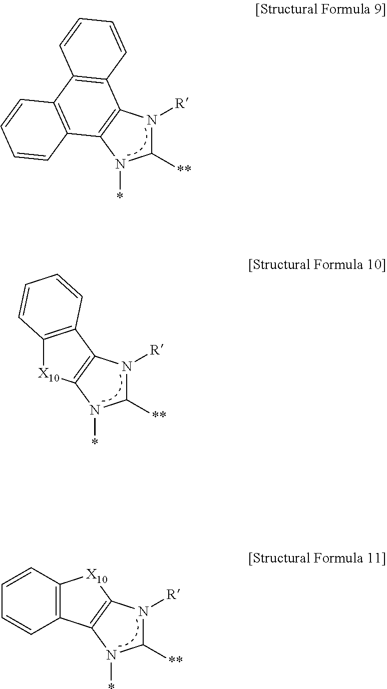
wherein,
R′ is any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, and a substituted or unsubstituted aliphatic hydrocarbon ring-fused heteroaryl of 5 to 30 carbon atoms,
“-*” stands for a single bond to the L³ ring moiety, and
“-**” stands for a bond to the platinum (Pt) atom,
X₁₀ in Structural Formulas 10 and 11 is any one selected from CR₂₁R₂₂, O, and S,
wherein R₂₁ and R₂₂, which are same or different, are each independently any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, and a substituted or unsubstituted aliphatic hydrocarbon ring-fused heteroaryl of 5 to 30 carbon atoms.

5. The organometallic compound of claim 1, wherein X⁵ and X⁶ are same or different and are each independently CR₇.

6. The organometallic compound of claim 1, wherein
L² have a structure represented by the following Structural Formula 12: 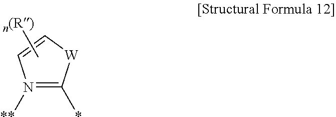
wherein
R″ is any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, and a substituted or unsubstituted aliphatic hydrocarbon ring-fused heteroaryl of 5 to 30 carbon atoms,
n is an integer of 1 to 2 wherein when n is 2, the R's are same or different and can be linked to each other to additionally form a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic hydrocarbon ring of 3 to 30 carbon atoms, or a substituted or unsubstituted heteroaliphatic ring of 3 to 30 carbon atoms,
“-*” stands for a single bond to the nitrogen (N) atom and “-**” stands for a bond to the platinum (Pt) atom, and
W is N, O, or S.

7. The organometallic compound of claim 1, wherein L² has a structure represented by the following Structural Formula 13: 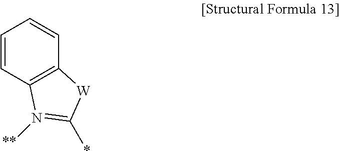
wherein,
“-*” stands for a single bond to the nitrogen (N) atom and “-**” stands for a bond to the platinum (Pt) atom, and
W is N, O, or S.

8. The organometallic compound of claim 1, wherein L³ and L⁴ in Chemical Formula 1 are same or different and are each independently a substituted or unsubstituted aromatic hydrocarbon ring of 6 to 20 carbon atoms.

9. The organometallic compound of claim 8, wherein L³ and L⁴ are each independently a substituted or unsubstituted benzene ring.

10. The organometallic compound of claim 1, wherein the compound represented by Chemical Formula 1 contains at least one deuterium atom.

11. The organometallic compound of claim 1, wherein the compound represented by Chemical Formula 1 may an organometallic compound selected from [Compound 1] to [Compound 68]:

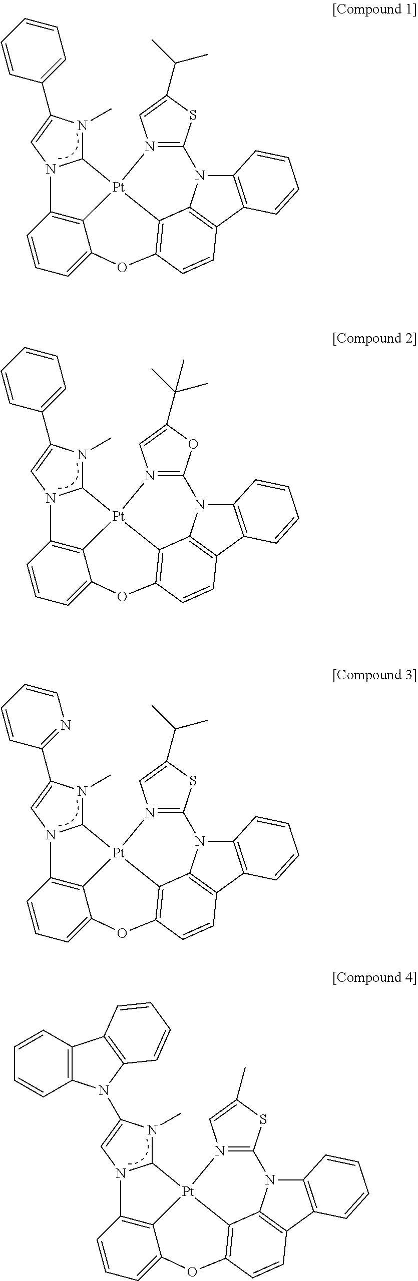

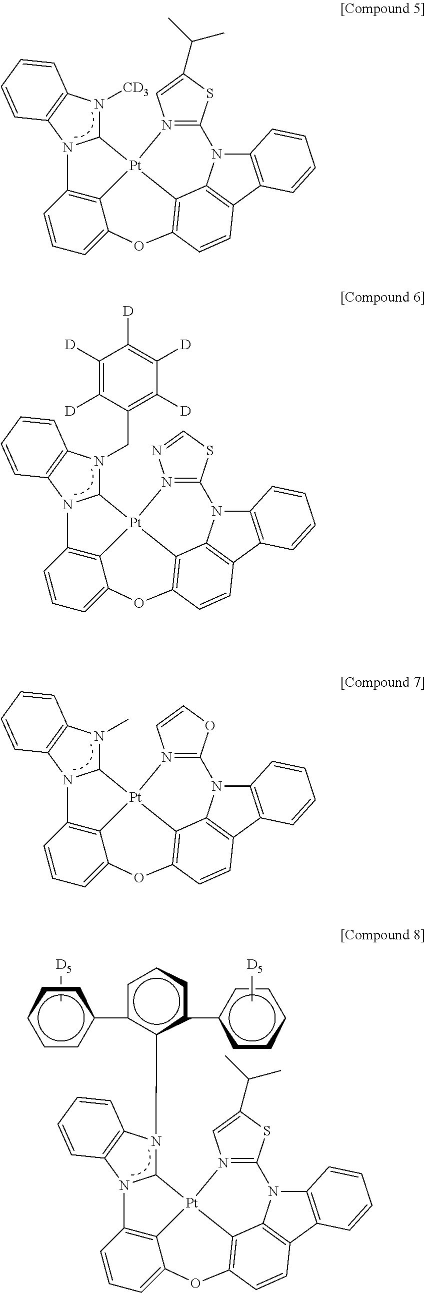

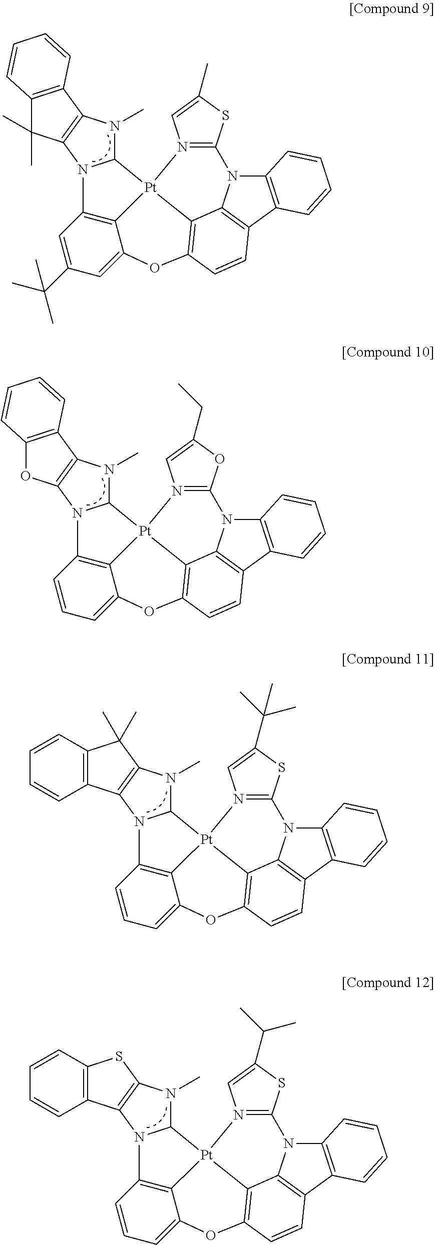

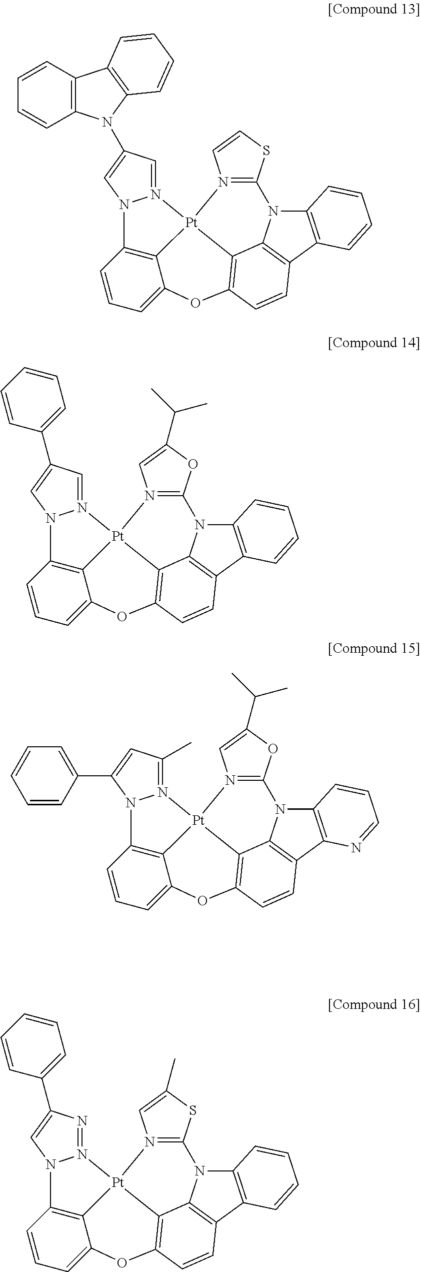

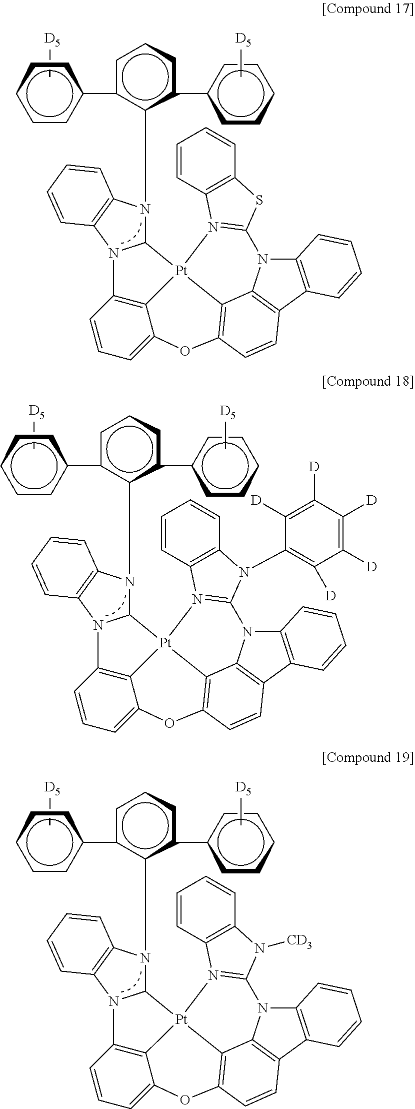

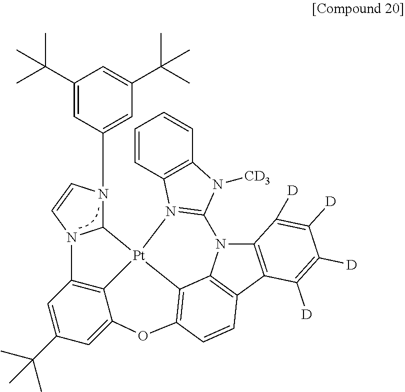

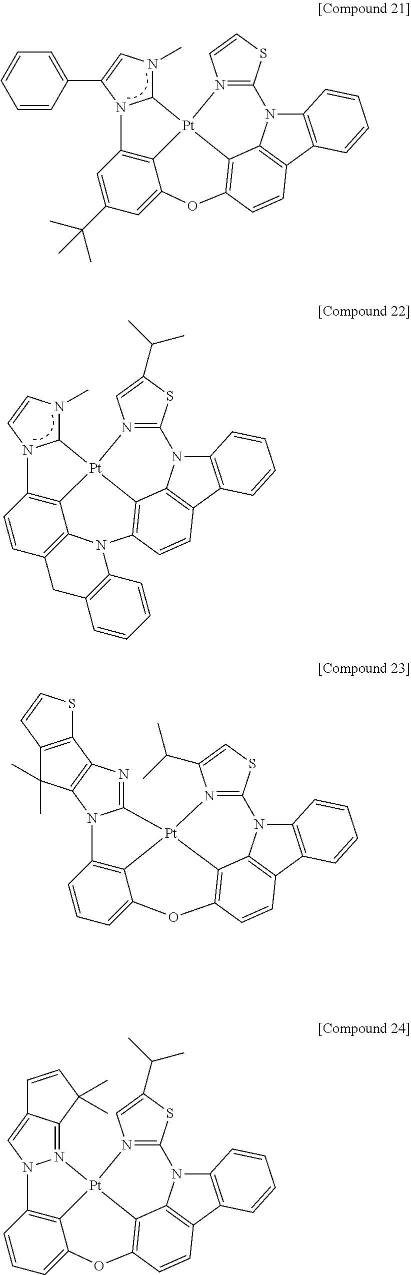

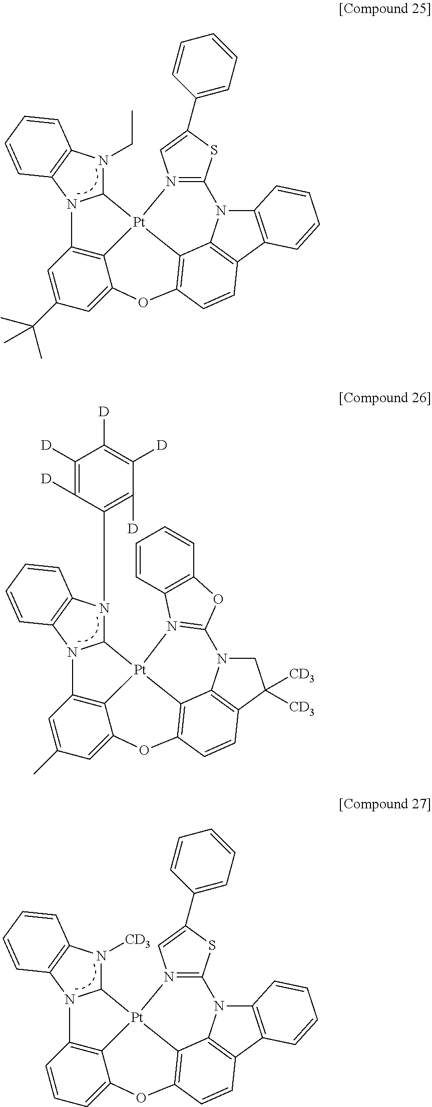

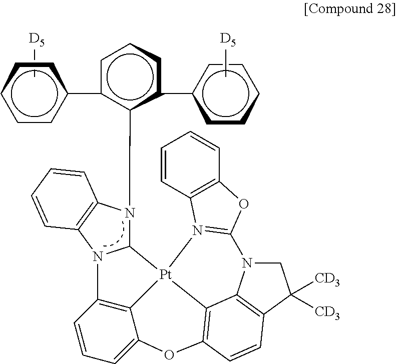

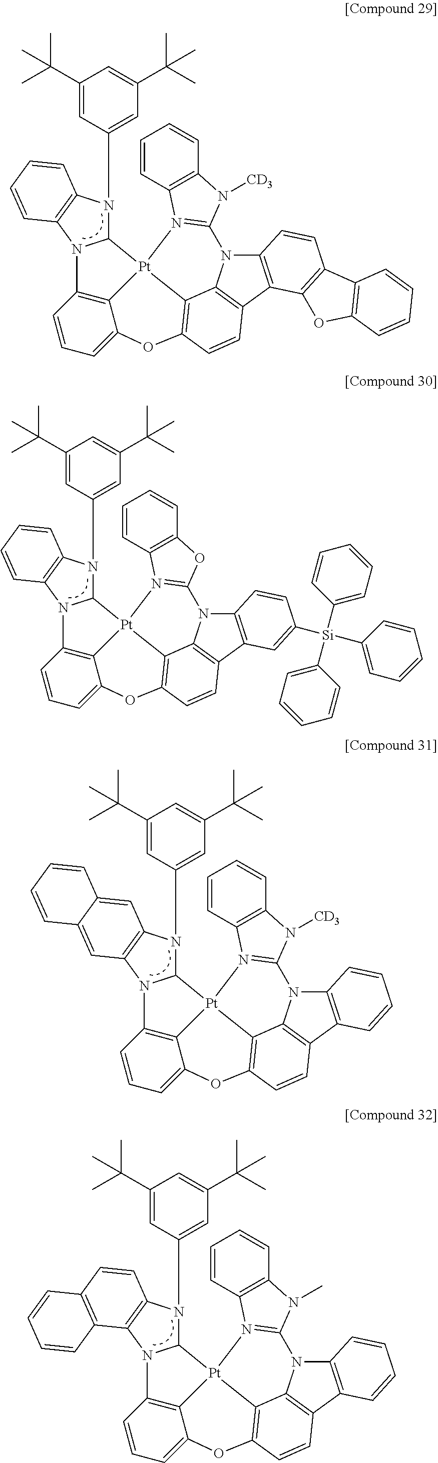

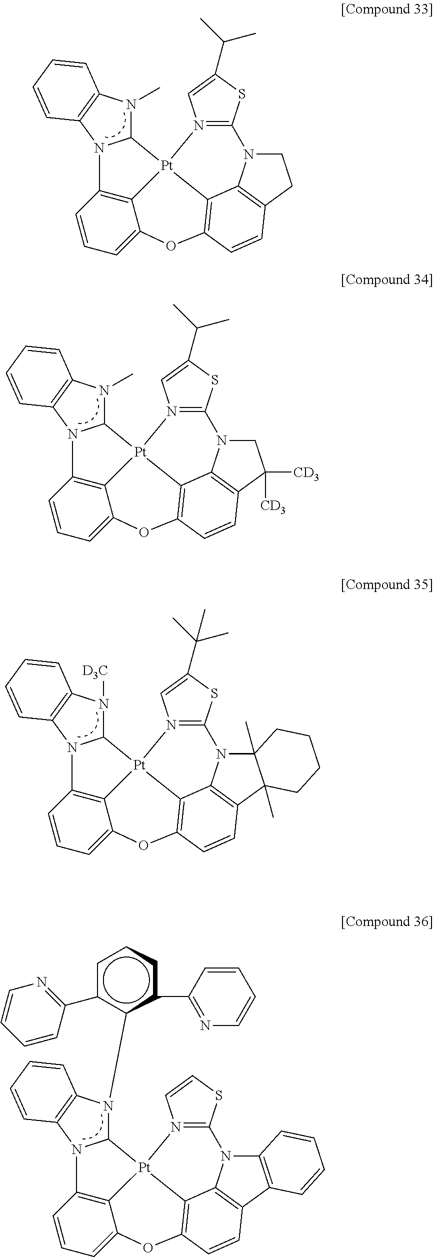

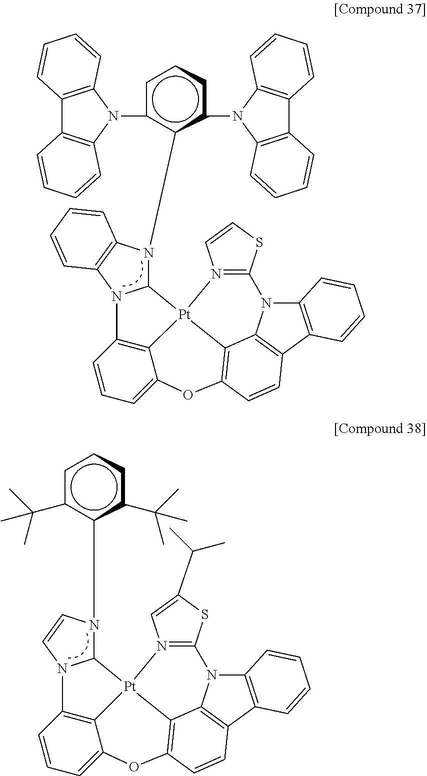

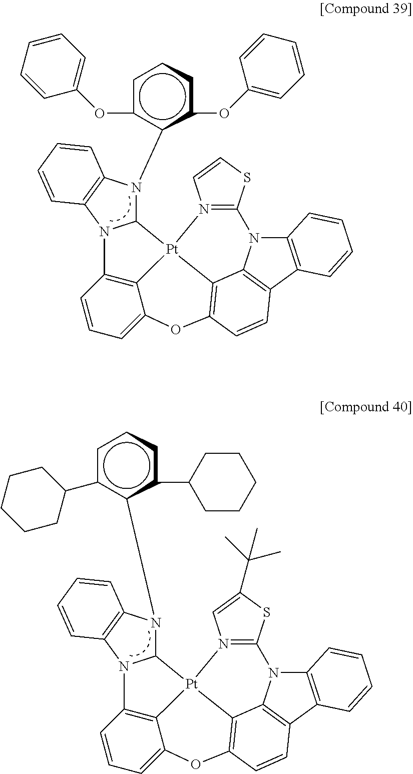

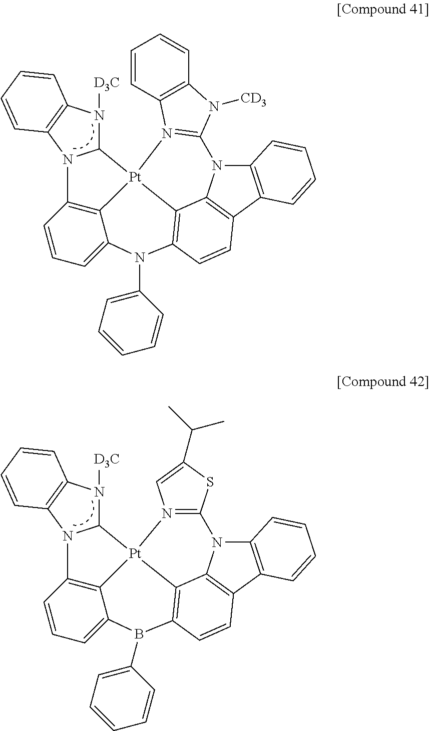

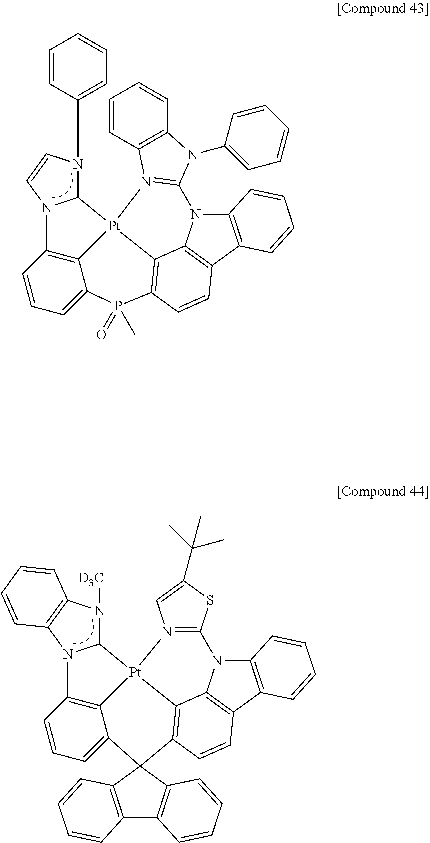

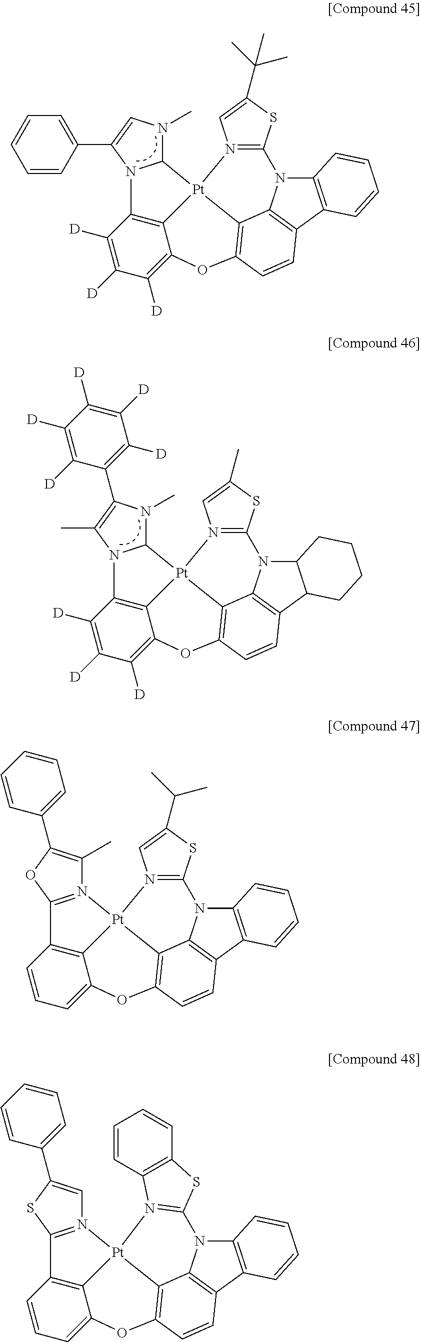

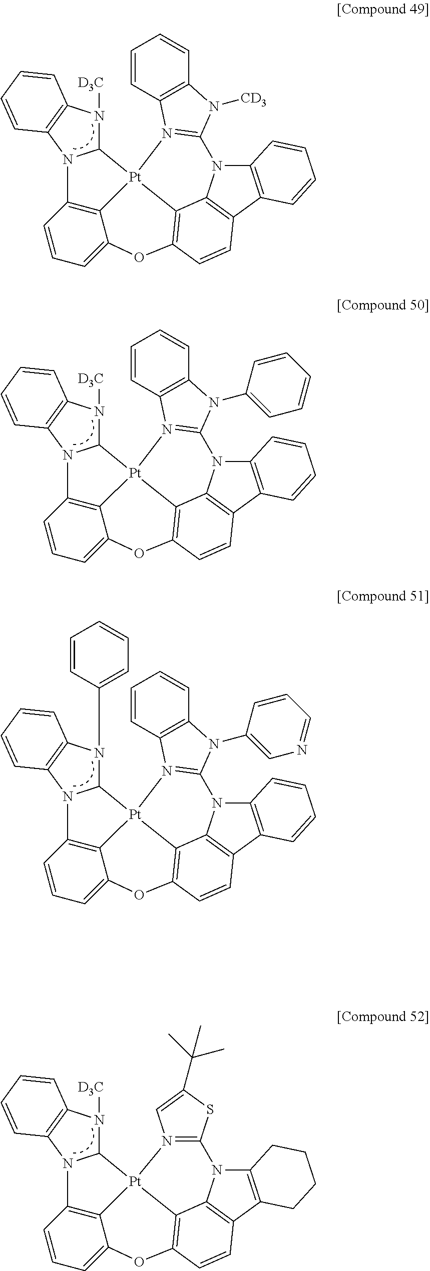

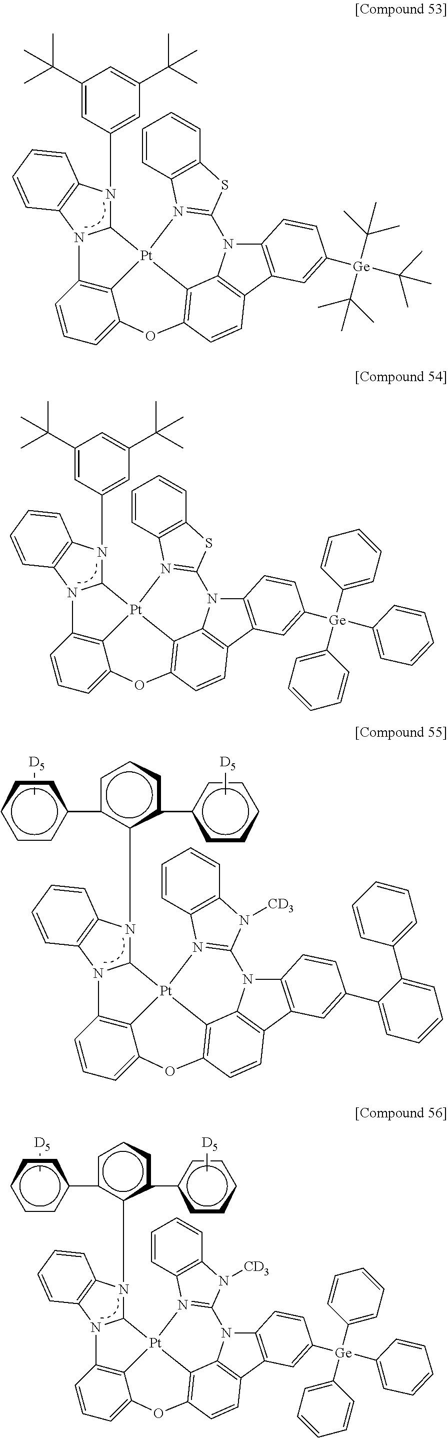

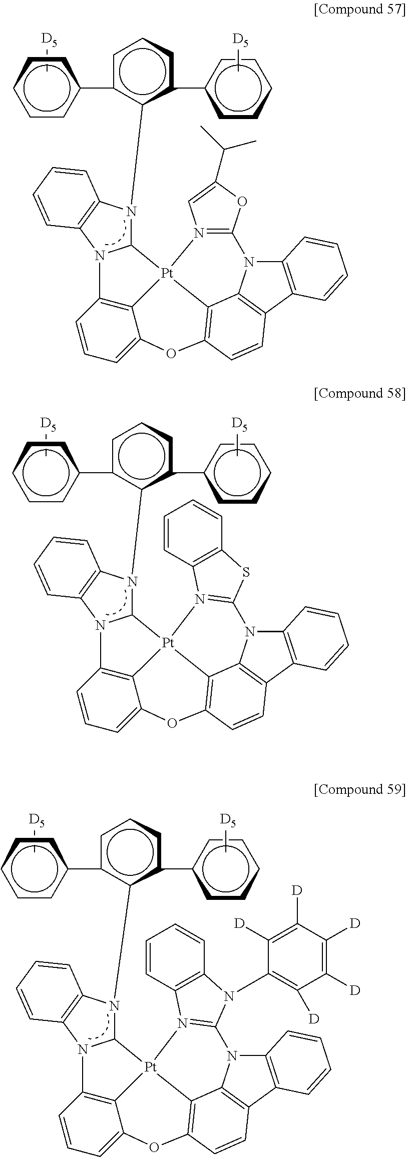

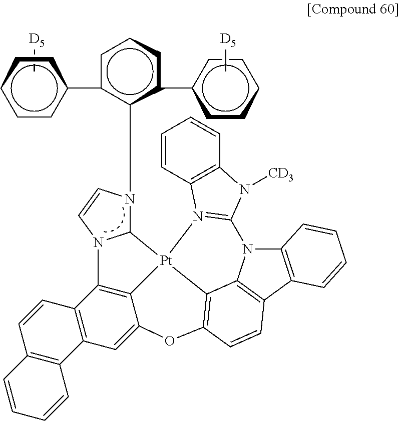

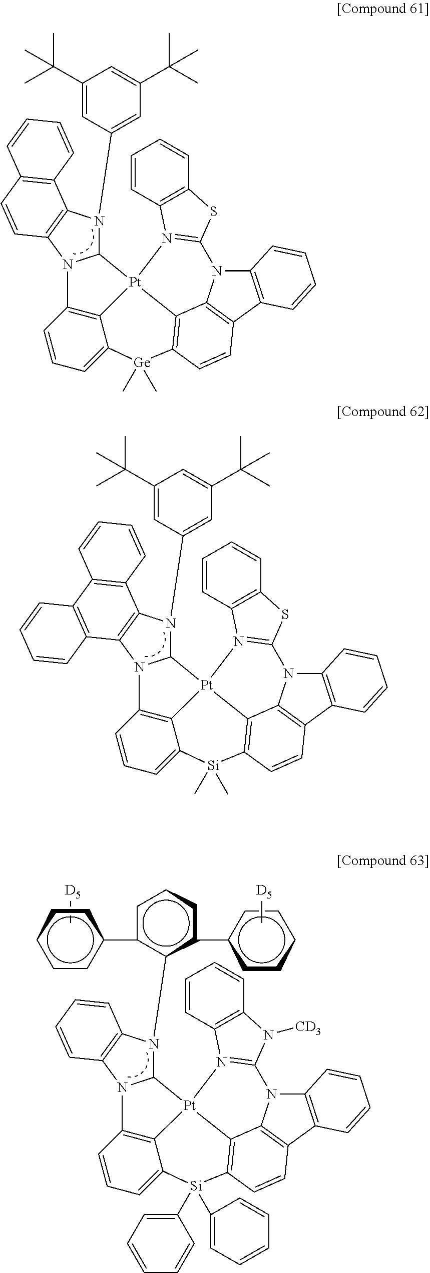

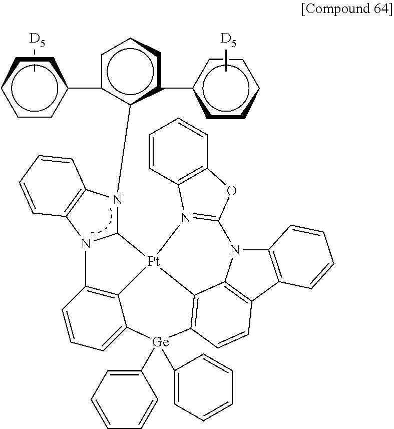

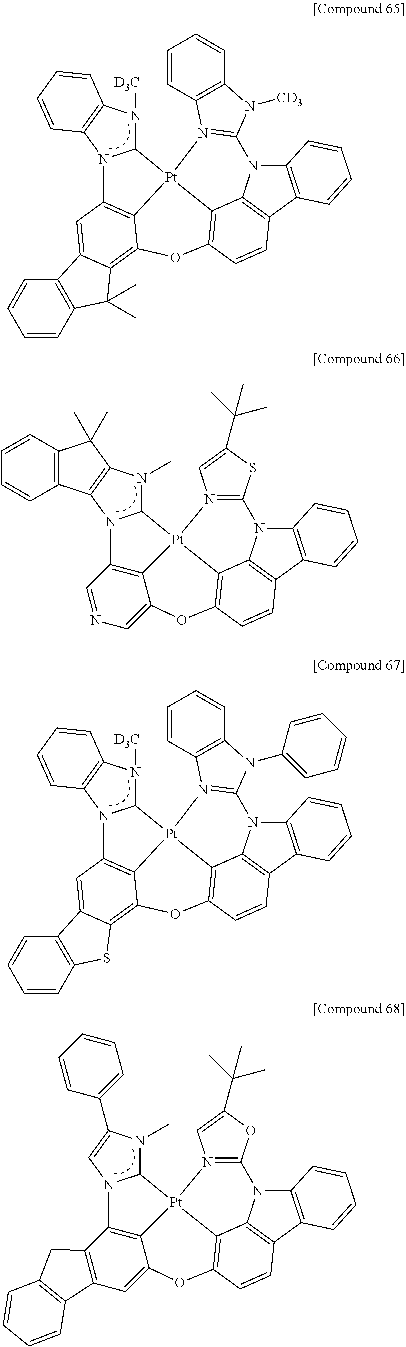

12. An organic light-emitting diode, comprising:
a first electrode;
a second electrode facing the second electrode; and
an organic layer interposed between the first electrode and the second electrode,
wherein the organic layer includes at least one of the organometallic compounds claimed by claim 1.

13. The organic light-emitting diode of claim 12, wherein the organic layer comprises at least one of a hole injection layer, a hole transport layer, a functional layer capable of both hole injection and hole transport, an electron barrier layer, an electron transport layer, an electron injection layer, a functional layer capable of both electron injection and electron transport, and a hole barrier layer.

14. The organic light-emitting diode of claim 13, wherein the light-emitting layer comprises a host and a dopant, wherein the organometallic compound is used as the dopant.

15. The organic light-emitting diode of claim 14, wherein the dopant is a combination of the organometallic compound and a different compound which are in mixture or deposited sequentially.

16. The organic light-emitting diode of claim 15, wherein the different compound used as a member of the dopant is a compound with a TADF property.

17. The organic light-emitting diode of claim 13, wherein at least one selected from among the layers is deposited using a deposition process or a solution process.

18. The organic light-emitting diode of claim 12, wherein the organic light-emitting diode is used for a device selected from among a flat display device; a flexible display device; a monochrome or grayscale flat illumination; a monochrome or grayscale flexible illumination; a display device for automobiles, and a display device for virtual or augmented reality.
